(19) United States
(12) Patent Application Publication
(10) Pub. No.: US 2025/0046301 A1
(43) Pub. Date: Feb. 6, 2025

(54) DESIGN AND LAYOUT STRUCTURE OF PIXELS FOR HIGH RESOLUTION DISPLAYS

(71) Applicant: Meta Platforms Technologies, LLC, Menlo Park, CA (US)

(72) Inventors: Balasubramanian Sivakumar, San Diego, CA (US); Min Hyuk Choi, San Jose, CA (US); Gang Chen, San Jose, CA (US); Gyungmin Kim, Santa Clara, CA (US); Ahmet Tura, Redmond, WA (US); Hai Jung In, San Jose, CA (US); Weiwei Wang, Cupertino, CA (US); Suhui Lee, Santa Clara, CA (US); Woong Hwang, Ansan-si (KR); Wanyue Song, San Jose, CA (US); Wai Sze Tiffany Lam, Lynnwood, WA (US); Wanli Chi, Sammamish, WA (US); Nikolaos Sarafianos, Castro Valley, CA (US); Rakesh Ranjan, Mountain View, CA (US); Alexander Sorkine Hornung, Zurich (CH); Seonghyeon Nam, San Jose, CA (US); Hyunyoung Jung, Redwood City, CA (US); Ruiming Xie, London (GB); Ju Lin, Seattle, WA (US); Niko Moritz, Kingston Upon Thames (GB); Frank Torsten Bernd Seide, Yarrow Point, WA (US)

(21) Appl. No.: 18/787,739

(22) Filed: Jul. 29, 2024

Related U.S. Application Data
(60) Provisional application No. 63/516,289, filed on Jul. 28, 2023.
(60) Provisional application No. 63/593,612, filed on Oct. 27, 2023.
(60) Provisional application No. 63/594,403, filed on Oct. 30, 2023.
(60) Provisional application No. 63/616,444, filed on Dec. 29, 2023.
(60) Provisional application No. 63/551,661, filed on Feb. 9, 2024.
(60) Provisional application No. 63/560,849, filed on Mar. 4, 2024.
(60) Provisional application No. 63/575,440, filed on Apr. 5, 2024.

(51) Int. Cl. G10L 15/16; G02B 6/26; G02B 6/27; G02B 6/34; G06F 40/40; G10L 15/02; G10L 15/18; H10K 59/12

(52) U.S. Cl. CPC G10L 15/16; G02B 6/262; G02B 6/2726; G02B 6/34; G10L 15/02; G10L 15/18; G06F 40/40; H10K 59/12

(57) ABSTRACT

A display device includes a diffusion layer providing a single well, an optical element configured to receive light and output the received image light including a concentric series of lens segments made up of active facets, and a waveguide having an in-coupling grating and a waveguide body optically coupled to the image light, where a polarizing component is disposed over an output surface of the optical element. A method to improve a yield of silicon backplane displays includes connecting a diode having a resolution to a backplane and repairing a defect on a pixel display area by dividing the pixel display area into at least one subcircuit, while improving geometry stylization transfer for 3D models of real-world environments. A method for suppressing crosstalk for user conversations includes receiving multiple speech signals captured by multiple microphones and generating directional data for the multiple speech signals based on spatial filtering.

### CROSS-REFERENCE TO RELATED APPLICATIONS

This application claims priority to U.S. Application 63/516,289, filed 28 Jul. 2023, U.S. Application No. 63/593,612, filed 27 Oct. 2023, U.S. Application No. 63/594,403, filed 30 Oct. 2023, U.S. Application No. 63/616,444, filed 29 Dec. 2023, U.S. Application No. 63/551,661, filed 9 Feb. 2024, U.S. Application No. 63/560,849, filed 4 Mar. 2024, U.S. Application No. 63/575,440, filed 5 Apr. 2024, and the disclosures of each of which are incorporated, in their entirety, by this reference.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is an illustration of an exemplary pixel architecture of a single well including devices that utilize a PMOS design for driving a current of a pixel, according to some embodiments.

FIG. 2 is an illustration of an exemplary device including multiple pixel drivers configured to successively drive a single diode, according to certain embodiments.

FIG. 3 is an illustration of exemplary defective sub-circuits in a low resolution pixel area, according to certain embodiments.

FIG. 4 is an illustration of exemplary defective sub-circuits in a low resolution pixel area that are repaired by cutting the cathodes from the defective sub-circuits, according to various embodiments.

FIG. 5 is a schematic diagram showing the back-reflection of image light in a liquid crystal on silicon (LCoS) display according to some embodiments.

FIGS. 6A and 6B illustrate the integration of a polarizing component with the polarizing beam splitter (PBS) of the LCoS display of FIG. 5 according to some embodiments.

FIGS. 7A and 7B illustrate the integration of a polarizing component with both the polarizing beam splitter (PBS) and the input grating of the waveguide combiner of the LCoS display of FIG. 5 and the attendant impact on back-reflected image light according to some embodiments.

FIGS. 8A and 8B illustrate the integration of polarizing components with the polarizing beam splitter (PBS) and with opposing surfaces of the waveguide combiner of the LCoS display of FIG. 5 according to further embodiments.

FIGS. 9A and 9B illustrate the integration of polarizing components and an antireflective coating with the polarizing beam splitter (PBS) and waveguide combiner of the LCoS display of FIG. 5 according to certain embodiments.

FIGS. 10A and 10B illustrate the integration of polarizing components with the polarizing beam splitter (PBS) and with opposing surfaces of the waveguide combiner of the LCoS display of FIG. 5 according to still further embodiments.

FIGS. 11A and 11B are an illustration of an LCoS architecture including a high efficiency compact illuminator and a volumetric Bragg grating (VBG) beam expander according to some embodiments.

FIG. 12 illustrates the integration of polarizing components with both the illuminator and the waveguide of the LCoS display of FIGS. 11A and 11B and the resulting impact on back-reflected image light according to some embodiments.

FIG. 13 illustrates the integration of polarizing components with both the illuminator and the waveguide of the LCoS display of FIGS. 11A and 11B according to further embodiments.

FIG. 14 shows cross-sectional views of a comparative convex lens and a Fresnel lens according to some embodiments.

FIG. 15 illustrates a cross-section of a Fresnel lens according to various embodiments.

FIGS. 16A and 16B are a perspective view of the draft profiles for example Fresnel lens structures according to certain embodiments.

FIGS. 17A-17C depict draft profile architectures for a Fresnel lens according to particular embodiments.

FIGS. 18A and 18B show a light intensity map for an example Fresnel lens according to some embodiments.

FIGS. 19A and 19B show a light intensity map for an example Fresnel lens according to further embodiments.

FIG. 20 illustrates an example network environment associated with an augmented-reality (AR)/virtual-reality (VR) system.

FIG. 21 illustrates an example architecture of directional speech recognition.

FIG. 22 illustrates an example data simulation diagram.

FIG. 23 illustrates an example process for multi-talker simulation.

FIG. 24 illustrates examples of adding distractor to the simulation.

FIG. 25 illustrates an example pipeline for multi-channel data simulation.

FIG. 26 illustrates an example simulation of 7-channel data associated with AR glasses.

FIG. 27 illustrates example training configuration of spatial positions of the conversation partner and bystander.

FIG. 28 illustrates example beam patterns of the super-directive beamformer at frequency of 2 kHz.

FIG. 29 illustrates an example chart showing our best results.

FIG. 30 illustrates an example method for suppressing crosstalk.

FIG. 31 illustrates an example computer system.

FIG. 32 is an illustration of exemplary augmented-reality glasses that may be used in connection with embodiments of this disclosure.

FIG. 33 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown byway of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

An organic light-emitting diode (OLED), also known as organic electroluminescent (organic EL) diode, is a light-emitting diode (LED) in which the emissive electroluminescent layer is a film of organic compound that emits light in response to an electric current. This organic layer is situated between two electrodes; typically, at least one of these electrodes is transparent. OLEDs are used to create digital displays in devices such as television screens, computer monitors, and portable systems such as smartphones and handheld game consoles.

A micro-OLED is an OLED on silicon. Not only are the pixels themselves smaller, but the entire “panels” are smaller. This is possible thanks to advancements in manufacturing, including mounting the display-making segments in each pixel directly to a silicon chip, which enables pixels to be much smaller.

Micro-OLED displays feature much smaller pixels, enabling micro-OLED displays to achieve much higher resolutions than traditional OLED displays. For example, 4K resolution can be achieved on chips the size of postage stamps. Until recently, the technology has been used in things like electronic viewfinders in cameras, but the latest versions are larger and even higher resolution, making them perfect for augmented reality (AR) and virtual reality (VR) headsets.

For these reasons, micro-OLED displays may be a significant component and enabling factor for mixed reality (MR), AR, and VR applications. For example, the silicon backplane available with micro-OLED displays may make smaller pitch pixels than may be possible with traditional thin film transistor (TFT) options. Additionally, a drive transistor may be a significant component for controlling emission brightness of a pixel. Also, besides uniform performance, the capability to tolerate high voltage may become another significant feature with the introduction of tandem OLED devices that generally require 10V or higher driving voltage. On one hand, uniform performance may benefit from a thinner gate oxide so that the gate electrode can better control channel current. On the other hand, high voltage operation may benefit from a thicker gate oxide to meet reliability criteria. Gate oxide selection for the drive transistor faces a dilemma that both of these options cannot be satisfied simultaneously.

High resolution displays may be highly sought after in VR displays to remove visual artifacts and stay competitive. However, OLED diodes may only be operable with high voltages requiring long channel devices that are not compatible with other channel lengths. Furthermore, these long channel devices may introduce significant amounts of wasted space between devices and non-uniform layouts that result in degrading overall silicon yield.

In accordance with the above, a display device may include a diffusion layer providing a single well. The display device may also include one or more devices formed in an area of the diffusion layer corresponding to the single well. The one or more devices may additionally be configured to supply a driving current to a pixel of the display device. In some implementations, the one or more devices may correspond to one or more p-channel metal-oxide-semiconductor devices. Alternatively or additionally, a length of the pixel per color may be no greater than 3.3 microns and a width of the pixel per color may be no greater than 3.5 microns.

The term “display device,” as used herein, may generally refer to an output device for presentation of information in visual form. For example, and without limitation, a display device may correspond to an electronic display, a liquid crystal display (LCD), a light emitting diode (LED) display (e.g., OLED display, an active matrix OLED (AMOLED) display, super AMLOLED display, etc.

The term “diffusion layer,” as used herein, may generally refer to one or more semiconductor layers in which impurities may be diffused in order to create one or more active regions in which transistors may be formed. For example, and without limitation, a diffusion layer may provide an anode and a cathode and include a backing layer (e.g., carbon cloth, carbon paper, etc.) and a microporous layer (MPL). In this context, the MPL may be comprised of hydrophobic polymer, such as polytetrafluoroethylene (PTFE) and carbon powder (e.g., Vulcan XC-72).

The term “well,” as used herein, may generally refer to a potential well having only discreet energy values. For example, and without limitation, a well may correspond to an Nwell or a Pwell, either of which may correspond to an anode, or a cathode provided by a diffusion layer. In this context, a diffusion layer that provides a single well may provide more than one well, possibly including more than one anode and/or more than one cathode. However, the single well may correspond to only one anode or only one cathode of the diffusion layer, and devices can share a single well by being formed in a same active region corresponding to either the anode or the cathode of the diffusion layer.

The term “device,” as used herein may generally refer to a circuit formed in an active region of a diffusion layer. For example, a device may correspond to a pixel driver and/or one or more components of a pixel driver, such as a transistor, a collection of transistors, one or more gates, one or more capacitors, etc.

The term “driving current,” as used herein, may generally refer to an electrical current supplied to a current driven pixel by a pixel driver. For example, and without limitation, a driving current may be supplied by setting a gate voltage of a driver transistor based on a current data signal while a corresponding current is applied to a driver transistor.

The term “pixel,” as used herein, may generally refer to a light emitting element of a display device. For example, and without limitation, a pixel may correspond to a diode, a light emitting diode (LED), and organic light emitting diode (OLED), a micro-OLED, etc.

In some implementations, the display device may also include one or more additional devices formed in the area of the diffusion layer corresponding to the single well, and the one or more additional devices may be configured to supply an additional driving current to an additional pixel of the display device. For example, the one or more devices and the one or more additional devices may have a uniform channel length. Additionally or alternatively, the one or more devices may correspond to one or more p-channel metal-oxide-semiconductor devices and the one or more additional devices may correspond to one or more additional p-channel metal-oxide-semiconductor devices. In some implementations, the one or more devices and the one or more additional devices may share a continuous diffusion without any white spaces therebetween in at least one direction (e.g., in a horizontal direction). Additionally or alternatively, the pixel and the additional pixel may have a uniform layout. In some implementations, a length of the pixel per color may be no greater than 3.3 microns and a width of the pixel per color may be no greater than 3.5 microns. In some of these implementations, a length of the additional pixel per color may also be no greater than 3.3 microns and a width of the additional pixel per color may also be no greater than 3.5 microns. Alternatively or additionally, the pixel and the additional pixel may abut one another and continue a single diffusion.

The term “white space,” as used herein, may generally refer to one or more sections of a semiconductor chip area having no physical structures in the area. For example, and without limitation, white space regions in semiconductor chip design may occur in areas in the corners of a semiconductor chip, between bond pads, under signal bond pads, under power bond pads, under busses or wiring bays, and/or between power domains.

A pixel driver may function as a programmable current source to control color and/or brightness of individual pixels on a silicon backplane display. The current may be programmed by operating a series of switches directed from incoming data stored on a capacitor. However, voltage provided by the capacitor may be inconsistent or corrupted due to process issues such as leakage, charge injection, and fabrication issues. This corruption may lead to bright dots and dark dots, causing yield loss of the silicon backplane display and increased costs in production to replenish the lost displays.

By connecting a diode having a resolution to a backplane and configuring two or more pixel drivers of the backplane to drive the diode at a resolution higher than the resolution of the diode, the disclosed systems and methods can achieve numerous benefits. For example, configuring the two or more pixel drivers to drive the diode with an average current that is a time domain average of two or more individual currents supplied to the diode by the two or more pixel drivers may reduce the perceptibility of bright dots and/or dark dots. This benefit may be achieved because bright dots and dark dots are only perceptible if they are about fifty percent brighter or darker than adjacent pixels. Thus, configuring two or more pixel drivers to supply two or more individual currents to the diode for two or more different (e.g., non-overlapping) periods of time (e.g., having a total duration less than or equal to a resolution of the diode) may average the currents in a manner that effectively reduces error currents. Driving the diode with multiple pixel drivers configured to drive the diode in succession may achieve a reduction in error currents by a factor of a number of individual currents that are averaged (e.g., a number of pixel drivers configured to drive the diode in succession), aiding in recovery of yield. Stated differently, if one of the pixel drivers has an erroneous current, the average current flowing into the diode over time may still be closer to a correct value. The higher the time domain multiplexing, the closer the current may become to the correct value, resulting in a bright dot becoming darker (e.g., closer to the correct value) and a dark dot becoming brighter (e.g., closer to the correct value). In the event of no defects, the current conforms to the correct value, resulting in no changes to the actual brightness or darkness. The disclosed systems and methods may also achieve these benefits without any complicated detection or rectification of errors, effectively simplifying testing and passing of devices. Avoiding any need for feedback of pass/fail to each pixel in this manner also significantly reduces routing resource requirements.

The term “resolution,” as used herein, may generally refer to the ability of an electronic component to detect and/or produce a difference in an electrical property (e.g., voltage, current, etc.). For example, and without limitation, a resolution of a diode may correspond to an ability of the diode to detect a difference in a current supplied to the diode, and a resolution of a backplane and/or pixel driver may correspond to an ability to produce a difference in current supplied to the diode. In this context, a backplane may drive a diode at a higher resolution than a resolution of the diode when pixel drivers of the backplane can change the current supplied to the diode at a rate faster than that change in current is detectable by the diode. Thus, when multiple pixel drivers successively drive such a diode, the diode may see a time domain average of individual currents supplied by the pixel drivers.

Virtual reality and augmented reality devices and headsets typically include an optical system having a micro display and imaging optics. The micro display is configured to provide an image to be viewed either directly or indirectly using, for example, a micro OLED display or by illuminating a liquid-crystal based display such as a liquid crystal on silicon (LCoS) micro display. Display light may be projected to the eyes of a user using a waveguide where the light is in-coupled into the waveguide, transported therethrough by total internal reflection (TIR), and out-coupled when reaching the position of a viewer's eye.

In some systems, the imaging optics may include a geometric waveguide. With a geometric waveguide, light from the optical engine is in-coupled typically through a reflective mirror or prism, and then transported by TIR to an array of transflective surfaces that are configured to reflect a portion of the light to the eye of a user and transmit a remaining portion of the light for further propagation. Transmitted light may encounter another transflective surface where the reflection and transmission paradigm is repeated.

A variety of challenges are associated with the design and manufacture of an optical system for a heads-up display. In an augmented reality waveguide display utilizing a LCoS engine, for example, back-reflected image light from the waveguide surface may represent a significant source of stray light that may re-enter the LCoS polarizing beam splitter (PBS) and reflect to the user as a ghost image that disrupts display fidelity, which may diminish the user experience.

Various optical elements, including lenses, filters, polarizers, and the like, may be implemented to influence the properties of image light in an augmented reality display system. Fresnel lenses, for instance, are commonly used in light gathering applications, such as condenser systems or emitter/detector systems. They can also be used as magnifiers or projection lenses in illumination systems and image formulation. By way of example, a Fresnel lens may be incorporated into the imaging optics of an augmented reality display, such as an augmented reality device or headset.

In a Fresnel lens, a series of concentric grooves replace the curved surface of a traditional optical lens element. These contours act as individual refracting surfaces, which may be configured to bend parallel light rays to a common focal length, for example. As a result, a Fresnel lens, while characterized by a physically narrow cross-section, is capable of focusing light in a manner comparable to other lens designs.

Relative to comparative optical lenses, a Fresnel lens may be configured to provide improved focusing performance. In addition, a high groove density may be used to create high quality images, while a low groove density yields improved efficiency, such as with light gathering applications. Moreover, Fresnel lenses may provide additional advantages over comparative spherical or aspherical lenses, including reductions in weight, production costs, or transmission loss.

In some applications, such as in an AR display, the grooved architecture of a Fresnel lens may contribute undesirably to the formation of unwanted ghost images, which may negatively impact the viewing experience of a user. Notwithstanding recent developments, it would be advantageous to provide a Fresnel lens suitable for use in the display of an augmented reality system, and more particularly to a Fresnel lens configured to provide improved visual acuity without creating transmitted or reflected ghost images.

In accordance with some embodiments, a lens includes an optically transparent substrate having a first lens surface and a second lens surface opposite to the first lens surface. The first lens surface includes a plurality of Fresnel structures. Each respective Fresnel structure of the plurality of Fresnel structures includes a sloped facet and a draft facet.

Whereas a comparative Fresnel lens may have a plurality of flat draft surfaces that form concentric circles, such a configuration may transmit or reflect incident rays along a common direction that may lead to constructive interference and a strong ghost image or an unwanted pattern.

In particular embodiments, a multi-channel automatic speech recognition (ASR) system may use directional information to identify and eliminate cross-talking speech signals and transcribe only the speech signals coming from the user wearing a head-mounted device (e.g., smart glasses) and a target person the user is having a conversation with. The multi-channel ASR system may rely on speech signals coming from different directions that are captured by multiple microphones of the head-mounted device. The multi-channel ASR system may use spatial filters (e.g., the beamformer) to attenuate sounds from other directions but the target direction. Instead of using a single target direction, the multi-channel ASR system may apply such spatial filters for multiple target directions and provide multiple of such outputs to an ASR model. In particular embodiments, the multi-channel ASR system may perform beamforming on the speech signals into multiple directions simultaneously. The beamformed audio outputs may be then provided to an ASR model, which uses the beamformed audio outputs to disambiguate speech from different directions. The multi-channel ASR system may determine which person the user is talking with and filter out any crosstalk, thus only transcribing that person and the user themselves. Although this disclosure describes suppressing particular speech signals by particular systems in a particular manner, this disclosure contemplated suppressing any suitable speech signal by any suitable system in any suitable manner.

In particular embodiments, a client system associated with a first user may receive, at the client system, a plurality of speech signals captured by a plurality of microphones of the client system. The plurality of speech signals may comprise one or more cross-talking speech signals, in addition to general background noise. In particular embodiments, the client system may generate, based on applying spatial filtering steered to a plurality of directions to the plurality of speech signals, directional data for the plurality of speech signals. The directional data may comprise output from the spatial filtering for the plurality of directions. The client system may then identify, based on the directional data by one or more machine-learning models, one or more target speech signals and the one or more cross-talking speech signals from the plurality of speech signals. In particular embodiments, the client system may generate one or more transcriptions for the one or more target speech signals. The client system may further present, at the client system, one or more of the transcriptions to the first user.

Certain technical challenges exist for suppressing crosstalk. One technical challenge may include classifying and separating speech signals arriving from different directions. The solution presented by the embodiments disclosed herein to address this challenge may be a multi-channel directional ASR system that utilizes the differences in the directional outputs from the beamformers, allowing it to classify and separate speech signals arriving from different directions. Another technical challenge may be detecting speaker changes between a wearer of the head-mounted device and a target speaker. The solution presented by the embodiments disclosed herein to address this challenge may be incorporating serialized output training when training the ASR model, as the serialized output training may enable the model to learn to intersperse ASR transcripts with markup to indicate whether the speech came from self (the wearer) or from other (the conversational partner opposite to the wearer).

The present disclosure is generally directed to a display device including a diffusion layer providing a single well that may include all devices using an all p-channel metal oxide semiconductor field effect transistor (PMOS) design to create a more uniform layout for high resolution displays. As will be explained in greater detail below, embodiments of the present disclosure may further minimize white spaces between devices to create a single continuous compact layout. For example, two-pixel driver circuits may abut each other and share a continuous diffusion, sharing a source and drain electrode, while still having an independent gate to control the amount of current needed. In this manner, the high pixel density created by all devices utilizing a PMOS design in a single well may create a resolution that is three times greater than layouts including PMOS and NMOS designs. Furthermore, the compact layout may improve the silicon yield for display devices. The present disclosure is also directed to improving the yield of display devices by using a series of pixel drivers to supply current for a single diode. For example, a set of pixel driver circuits for driving the current of a single OLED diode may be used for improving the resolution of a silicon backplane display panel to improve the yield of defective display devices. The current supplied to the diode may be the average of two or more individual currents supplied by two or more pixel driver circuits, thus reducing the impact of any single faulty driver circuit. The present disclosure is also directed to systems and methods for detecting and repairing dot defects on fixed foveated displays. The inventive concept suggests dividing a pixel area of a low-resolution display region (e.g., peripheral display region) into multiple subcircuits to selectively repair dot defects via laser repair. The laser repair cuts off the area of the dot defect and enables the surrounding pixels to illuminate with the same average brightness in the pixel area. Further, utilizing this method can avoid costly repair operations such as shutting down the entire system in order to repair the dot defect. In accordance with various embodiments, one or more polarizing components may be incorporated into the LCoS optics or waveguide display to block, attenuate, or redirect back-reflected light. In particular embodiments, polarizing components are incorporated into both the LCoS optics and the waveguide display, which may improve polarization coupling of linearly polarized light into the waveguide. A polarizing component may include a linear polarizer or a waveplate, such as a quarter waveplate or a half waveplate, for example, as well as multi-component combinations thereof. By way of example, a first polarizing component may be disposed over an output of a polarizing beam splitter and a second polarizing component may be disposed over the in-coupling grating of the waveguide. In a further example, a third polarizing component may be located over a back surface of the waveguide. Example polarizing components include a reflective polarizer and a quarter waveplate, which may be used individually or in combination. As disclosed herein, the draft surfaces of an improved Fresnel lens are configured to form wavy concentric circles. Without wishing to be bound by theory, the oscillatory geometry of the draft surfaces may be configured to diverge a portion of incident rays, which leads to a weaker ghost image intensity. In accordance with some embodiments, a display device includes a lens described herein and an array of light emitting devices coupled with the lens for outputting light through the lens. The present disclosure is also directed to systems and methods for improved geometric stylization using geometry information (e.g., depth maps, normals, etc.) as a stylistic guide for modifying the geometry of radiance fields. At a high level, the present disclosure employs geometry information for scene stylization by innovatively employing deformation fields to achieve coherent alteration of both shape and appearance in 3D scenes. Additionally, this disclosure implements novel RGB-D stylization techniques leveraging geometric deformation and geometric cues to enhance aesthetic expressiveness and more accurately reflect intended styles at a quality that have not been achieved by any traditional works. This geometry-based stylization approach can straightforwardly be extended to stylize 3D objects (e.g., chairs, tables in a living room). Certain embodiments disclosed herein may provide one or more technical advantages. A technical advantage of the embodiments may include effectively generating speaker-attributed transcription while simultaneously suppressing bystander crosstalk, as the multi-channel ASR system may use an end-to-end modeling approach that utilizes the smart glasses' microphone array to get directional information of speech signals. Another technical advantage of the embodiments may include no need for explicitly extracting speaker characteristics as the multi-channel ASR system may perform speech separation and suppression implicitly, by using directional information, effectively learning to compare the different beamformer outputs. Certain embodiments disclosed herein may provide none, some, or all of the above technical advantages. One or more other technical advantages may be readily apparent to one skilled in the art in view of the figures, descriptions, and claims of the present disclosure.

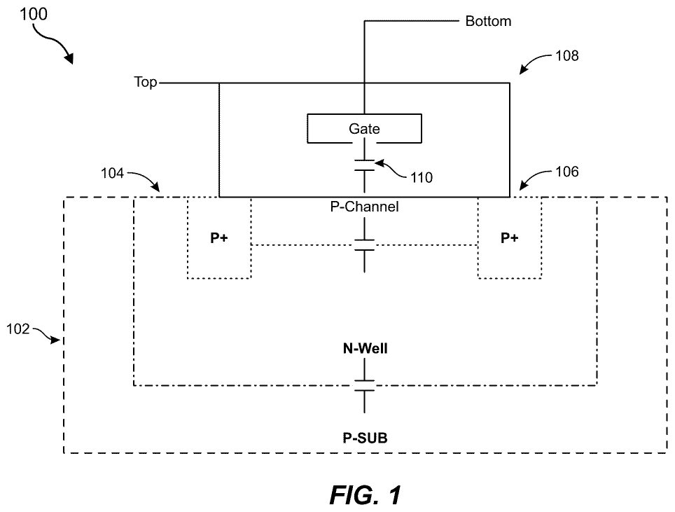

Features from any of the embodiments described herein may be used in combination with one another in accordance with the general principles described herein. These and other embodiments, features, and advantages will be more fully understood upon reading the following detailed description in conjunction with the accompanying drawings and claims. The following will provide, with reference to FIG. 1, detailed descriptions of a pixel architecture for a single well including devices that utilize a PMOS design for driving a current of a pixel.

### Single Well PMOS Designs

FIG. 1 is an illustration of a display device 100 including a diffusion layer providing a single well 104 and a pixel driver 108 for driving a current of a pixel. A PMOS design may include a p-substrate 102 that is doped with positive charge carriers. As used herein, a PMOS design may generally refer to an electronic circuit or component design that predominantly uses PMOS transistors. Single well 104 may be a region of p-substrate 102 that is doped with negative charge carriers to support a gate of the PMOS transistor in the pixel driver 108. Within single well 104, a set of p-contacts 106 may be heavily doped with p-type impurities to support the source and drain of the PMOS transistor in pixel driver 108. Single well 104 may support all devices in pixel driver 108 because the devices in pixel driver 108, such as a capacitor 110, may adopt a PMOS design. As used herein, a device may generally refer to active components in an integrated circuit.

In some embodiments, capacitor 110 may have an NMOS design that may not be compatible with other PMOS devices such as the PMOS transistor in pixel driver 108. For example, capacitor 110 may need to be part of another well for compatibility with a different doping type. However, as illustrated in FIG. 1, the PMOS design of capacitor 110 may enable the single well 104 to include all other devices in pixel driver 108. In doing so, the pixel architecture may enable a uniform layout with unified channel lengths and minimized white spaces. In some embodiments, a uniform layout may enable sharing of a source and drain electrode between two pixel drivers while still having an independent gate to control the amount of current needed.

In some embodiments, display device 100 may enable a length of the pixel per color to be 3.3 microns and a width of the pixel per color to be 3.5 microns. In this manner, there may be an improvement in a resolution by a factor of three due to increased pixel density enabled by single well 104. Furthermore, the new layout may improve yield of silicon displays and save production costs.

As set forth above, the disclosed display device may include a diffusion layer providing a single well and one or more devices formed in an area of the diffusion layer corresponding to the single well. The one or more devices may be configured to supply a driving current to a pixel of the display device. In some implementations, the display device may also include one or more additional devices formed in the area of the diffusion layer corresponding to the single well, and the one or more additional devices may be configured to supply an additional driving current to an additional pixel of the display device. Benefits achieved by the disclosed display device may include smaller fabrication (e.g., smaller pixel size), a uniform layout with a continuous diffusion without any white spaces between devices (e.g., in a horizontal direction), ability for pixels to abut one another and continue a single diffusion for enhanced area savings, improved yield of a display panel due to the uniform layout, improvement of pixel resolution by a factor of three, and applicability to smaller pixel architectures, such as 3T-1C.

### Pixel Drivers for a Single Diode

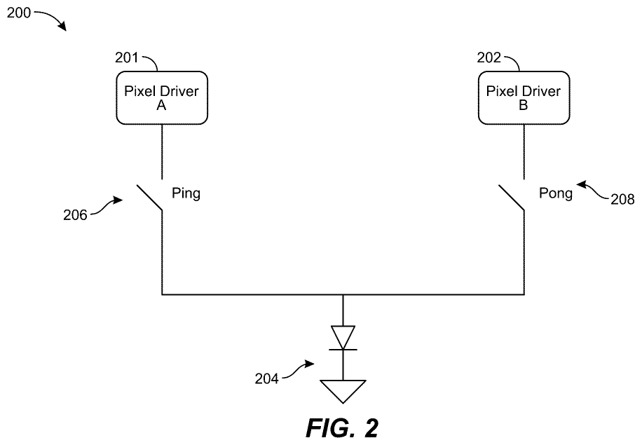

FIG. 2 is an exemplary diagram of a device 200 including a backplane that includes a pixel driver 201 and a pixel driver 202 configured to supply a current to a diode 204. As used herein, a pixel driver may generally refer to a programmable current source for controlling individual pixels in a display. Pixel driver 201 may include a first capacitor, a second capacitor, a transistor associated with the first capacitor, a transistor associated with the second capacitor, and a gate. As used herein, a capacitor may generally refer to a component used to store electrical energy in an electric field. As used herein, a transistor may generally refer to a switch capable of carrying a current. Furthermore, to track the current of the incoming data for driving diode 204, data may be stored on the first capacitor. In this manner, the transistor associated with the second capacitor, may be closed to change the gate to source voltage to the transistor, associated with the first capacitor, for providing current to diode 204.

In some embodiments, pixel driver 202 may operate similarly to pixel driver 201 with the corresponding capacitors, transistors, and switches. In some embodiments, the current driving diode 204 may switch between pixel driver 201 and pixel driver 202. For example, pixel driver 201 may have a switch 206 that is open for a first period of time and pixel driver 202 may have a switch 208 that is open for a second period of time. In some embodiments, the current driving diode 204 may switch off between a series of pixel drivers. In this manner, the current driving diode 204 may be a time domain average of the individual currents produced from pixel driver 201 and pixel driver 202.

In some embodiments, averaging the current may improve the yield of silicon backplane display devices. Even if pixel driver 201 produced an erroneous current, the average current between pixel driver 201 and pixel driver 202 may lessen a defect produced by the erroneous current and render the display device still operable. For example, bright spots and dark spots that may be produced by erroneous current may be dimmed and/or brightened because the light emitted by diode 204 is a time domain average between an erroneous current and a correct current. In doing so, because defects make up for majority of yield loss with respect to display devices, recovering the yield of display devices may save production costs.

As set forth above, if any of the drive currents is erroneous, the erroneous drive current may affect the luminance of the pixel. For example, a high current may cause a bright dot and a low current may cause a dark dot. However, a time domain average of the individual drive currents of several pixel drivers may be represented as:

$$Iavg ( t ) = \frac{I 1 ( t 1 ) + I 2 ( t 2 ) + … + IN ( tn )}{N}$$

where Iavg(t) is the time domain average current seen by the diode, I1(t1)+I2(t2)++IN(tn) are the individual drive currents supplied in succession to the diode, and N is the number of individual currents and, thus, the number of pixel drivers configured to successively drive the diode. If all individual drive currents are correct, then they are all the same. Thus, the time domain average current will be the same as each of the individual drive currents. However, if one of the pixel drivers has a defect, then it may inject an error current Ierr, but this error current will be averaged with the other individual drive currents as follows:

$$Iavg ( t ) = \frac{Ierr + I 1 ( t 1 ) + I 2 ( t 2 ) + … + IN ( tn )}{N}$$

Due to this time domain averaging effect, the error current effectively reduces by 1/N as follows:

$$Iavg ( t ) = \frac{I err}{N} + \frac{I 1 ( t 1 ) + I 2 ( t 2 ) + … + IN ( tn )}{N}$$

and hence, Ierr_effective=Ierr/N

As set forth above, the disclosed systems and methods can achieve numerous benefits by connecting a diode having a resolution to a backplane and configuring two or more pixel drivers of the backplane to drive the diode at a resolution higher than the resolution of the diode. For example, configuring the two or more pixel drivers to drive the diode with an average current that is a time domain average of two or more individual currents supplied to the diode by the two or more pixel drivers may reduce the perceptibility of bright dots and/or dark dots. This benefit may be achieved because bright dots and dark dots are only perceptible if they are about fifty percent brighter or darker than adjacent pixels. Thus, configuring two or more pixel drivers to supply two or more individual currents to the diode for two or more different (e.g., non-overlapping) periods of time (e.g., having a total duration less than or equal to a resolution of the diode) may average the currents in a manner that effectively reduces error currents. Driving the diode with multiple pixel drivers configured to drive the diode in succession may achieve a reduction in error currents by a factor of a number of individual currents that are averaged (e.g., a number of pixel drivers configured to drive the diode in succession), aiding in recovery of yield. Stated differently, if one of the pixel drivers has an erroneous current, the average current flowing into the diode over time may still be closer to a correct value. The higher the time domain multiplexing, the closer the current may become to the correct value, resulting in a bright dot becoming darker (e.g., closer to the correct value) and a dark dot becoming brighter (e.g., closer to the correct value). In the event of no defects, the current conforms to the correct value, resulting in no changes to the actual brightness or darkness. The disclosed systems and methods may also achieve these benefits without any complicated detection or rectification of errors, effectively simplifying testing and passing of devices. Avoiding any need for feedback of pass/fail to each pixel in this manner also significantly reduces routing resource requirements.

### Improving Defective Pixel Areas

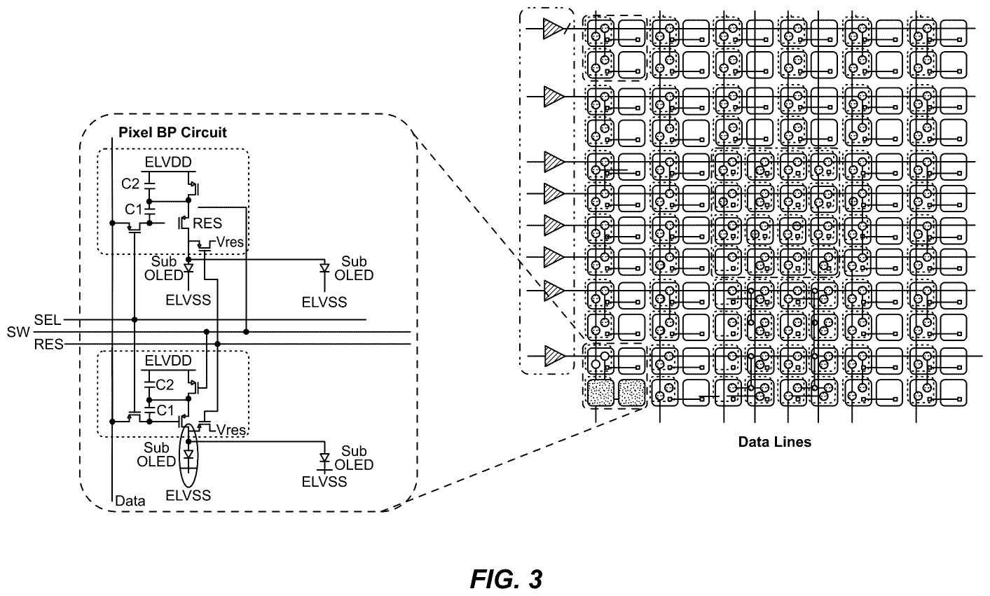

FIG. 3 is an illustration of exemplary defective sub-circuits in a low resolution pixel area, according to certain embodiments. In some embodiments, a method for detecting and repairing dot defects on fixed foveated displays may include a pixel display and pixel repair system. The pixel display may include a variable pixel structure that may enable a distribution of various circuit regions and organic light emitting diode (OLED) regions. In some examples, the pixel structure may be divided into various sub-circuits and sub-OLEDS in a peripheral region and a central region of the pixel display. In other examples, the sub-circuits on the pixel display may share common data lines and gate driving lines, where the sub-circuits are interconnected in terms of data and control signals. The data lines may carry pixel data that determines the color or intensity of each pixel, while the gate driving lines may control the selective activation or deactivation of the pixels in a pixel area. In further examples, the sub-circuit region(s) may include a defect (e.g., dot defect).

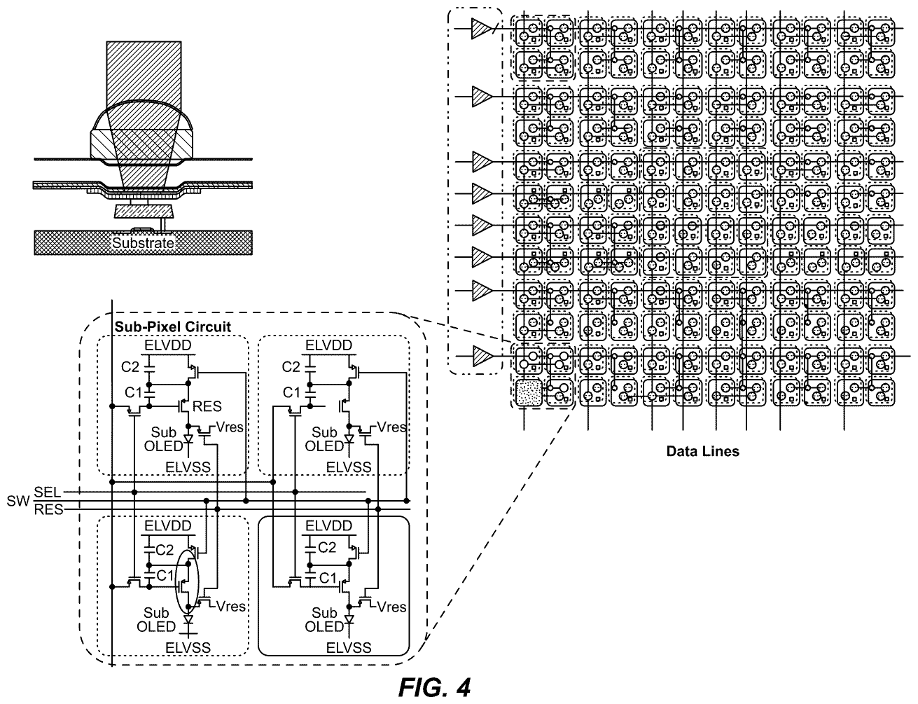

FIG. 4 is an illustration of example defective sub-circuits in a low resolution pixel area that are repaired by cutting the cathodes from the defective sub-circuits. In some embodiments, the repair pixel system may include a laser device that may repair the defective sub-circuit region(s) in the peripheral region of the pixel display. The laser device may cut-off a cathode of the sub-OLED in the sub-circuit region using a source of thermal energy (e.g., laser, photon emitter, etc.). In other embodiments, the pixel repair system may terminate the sub-OLED using the laser device. In some methods, the voltage data of the sub-circuits surrounding the defective sub-circuit region may be modified to inhibit power that may be supplied to the terminated sub-OLED. The modified voltage data may execute the sub-OLED(s) surrounding the defective sub-OLED to increase in brightness and reach an average luminance in the sub-circuit region. In further examples, a register may be used to dynamically control the data of the sub-circuit region to alter a threshold of a sub-OLED dead point.

### Waveguide Polarization Control

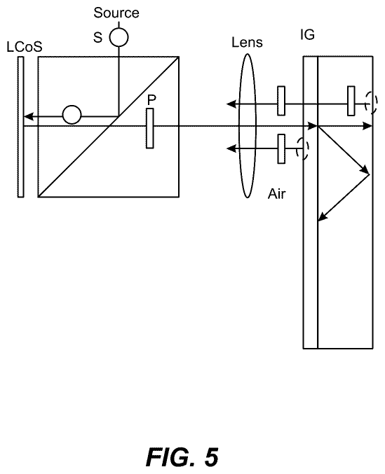

Referring to FIG. 5, shown is a schematic view of a portion of an example AR display. The display includes a light source such as a light-emitting diode, a polarizing beam splitter (PBS), and a waveguide combiner (WG). During operation, linearly polarized light from the light source (e.g., s-polarized light) enters the polarizing beam splitter where it is redirected toward an LCoS back plane. The s-polarized incident light is reflected from ON pixels of the LCoS panel as p-polarized image light whereas the s-polarized incident light is reflected from OFF pixels of the LCoS panel as s-polarized light. The reflected light is filtered by the beam splitter. To the exclusion of s-polarized reflected light, only p-polarized image light passes through the beam splitter where it is directed through a projection lens and toward the input grating (IG) of the waveguide (WG).

Image light that is incident upon the input grating may be in-coupled into the waveguide and transmitted therethrough by total internal reflection. However, portions of the image light reaching the waveguide may be back-reflected as stray light that reenters the beam splitter before being re-directed to the waveguide where it may interfere with the quality of an image formed by the waveguide. As shown schematically, back reflection may be due to Fresnel reflections from the back surface of the waveguide and/or from 0^{th} order diffraction from the input grating/air interface. Applicants have shown that the incorporation of various polarizing components into the display engine may be effective to mitigate both the generation of stray light and its reentry into the beam splitter.

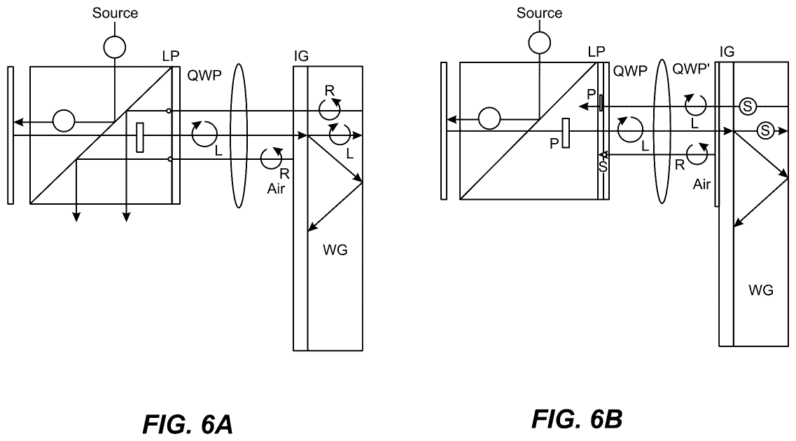

Turning to FIGS. 6A and 6B, one or more polarizing components may be integrated with the polarizing beam splitter (PBS). Referring to FIG. 6A, a combined linear polarizer (LP) and quarter waveplate (QWP) (i.e., a circular polarizer) may be co-integrated with the output surface of the beam splitter. A circular polarizer produces circularly-polarized image light and in the embodiment of FIG. 6A, the display engine is configured to direct circularly-polarized image light into the waveguide.

By way of example, p-polarized image light exiting the beam splitter may be transformed by the quarter waveplate (QWP) into left-handed circularly polarized light, and this left-handed circularly polarized light may be directed via the projection lens to the waveguide (WG). A portion of this image light may be in-coupled into the waveguide and transmitted therethrough by total internal reflection. However, left-handed circularly polarized image light reflected by either the waveguide back surface or the input grating/air interface may be transformed to right-handed circularly polarized light that is directed back to the PBS. In some embodiments, the reflected right-handed circularly polarized light may be converted by the quarter wave plate (QWP) to s-polarized light and absorbed by the linear polarizer (LP), thus eliminating this source of back-reflected stray light.

Referring to FIG. 6B, a quarter waveplate (without a linear polarizer) may be located over the output surface of the beam splitter. The quarter waveplate produces circularly polarized image light and contributes to the redirection (beam dump) of back-reflected light. That is, light reflecting from the waveguide back to the beam splitter may be removed from the optical path such that it does not reenter the waveguide as stray light.

In an example embodiment, p-polarized image light exiting the beam splitter will be transformed by the quarter waveplate (QWP) into left-handed circularly polarized light, which will be incident on the waveguide (WG) where a portion of this image light may be in-coupled into the waveguide and transmitted therethrough by total internal reflection. As in the example of FIG. 6A, left-handed circularly polarized image light reflected by either the waveguide back surface or the input grating/air interface may be transformed to right-handed circularly polarized light. The reflected right-handed circularly polarized light may be converted by the quarter wave plate to s-polarized light and redirected by the beam splitter.

Notwithstanding the foregoing benefits of integrating one or more polarizing components with the polarizing beam splitter, the transformation of linearly-polarized image light to circularly-polarized image light may result in the inefficient in-coupling of image light into the waveguide insomuch as exemplary coupling technologies (e.g., surface relief gratings, volumetric Bragg gratings, geometric waveguides, and the like) naturally perform better with linearly polarized light.

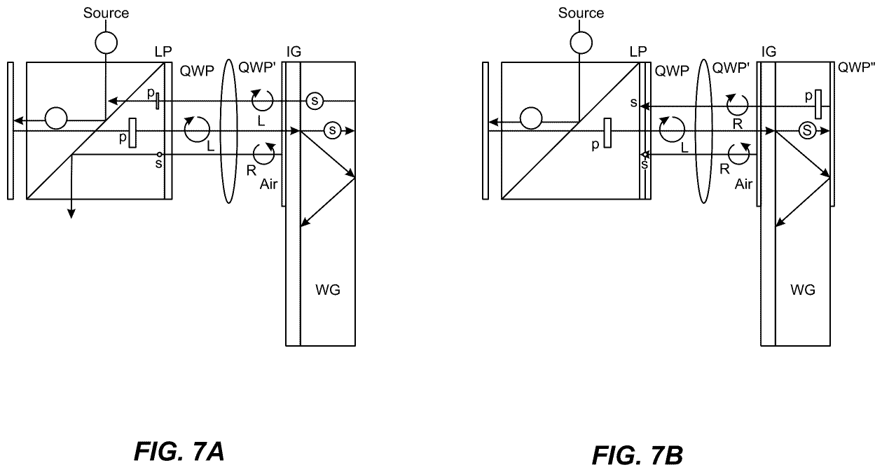

Referring to FIGS. 7A and 7B, one or more polarizing components may be integrated with a front surface of the waveguide (WG). Further to the architectures illustrated in FIGS. 6A and 6B, an additional quarter waveplate (QWP′) may be located over the input grating (IG). The additional quarter waveplate (QWP′) may be suitably aligned with the structure of the input grating and configured to transform the image light entering the waveguide (WG) into linearly polarized light (e.g., s-polarized light).

With reference to FIGS. 7A and 7B, stray light may be formed by reflections from the waveguide back surface. In an example mode of operation, incident left-handed circularly polarized image light passing through the additional quarter waveplate (QWP′) may be converted to s-polarized light and this linearly-polarized image light may reflect from the back surface of the waveguide still as s-polarized light that will be transformed back to left-handed circularly polarized image light as it exits the waveguide and traverses the additional quarter waveplate (QWP′) a second time. This left-handed circularly polarized light may be converted to p-polarized light by the quarter waveplate (QWP) and reenter the polarizing beam splitter (PBS) as stray light.

Incident left-handed circularly polarized image light reflecting from the surface of the input grating, on the other hand, may be converted to right-handed circularly polarized light. As shown in FIG. 7A, this reflected right-handed circularly polarized light may be converted by the quarter wave plate (QWP) to s-polarized light and absorbed by the linear polarizer (LP), thus blocking this source of stray light. Turning to FIG. 7B, incident left-handed circularly polarized image light reflecting from the surface of the input grating as right-handed circularly polarized light may be converted by the quarter wave plate (QWP) to s-polarized light and redirected by the beam splitter, thus removing this source of stray light from the optical path.

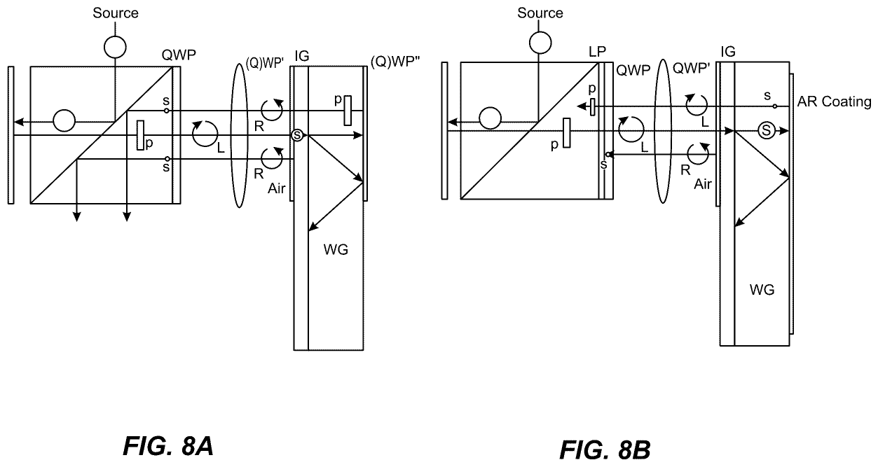

According to some embodiments, and with reference to FIGS. 8A and 8B, a still further quarter waveplate may be formed over a back surface of the waveguide. The addition of quarter waveplate (QWP″) may be effective to attenuate the back-reflected stray light originating from the waveguide back surface, as described above with reference to FIGS. 7A and 7B.

Referring to FIG. 8A, according to some embodiments, incident left-handed circularly polarized image light passing through the quarter waveplate (QWP′) may reach the back surface of the waveguide as s-polarized light where it will be converted to p-polarized light by quarter waveplate (QWP″). This reflected light may be transformed to right-handed circularly polarized image light as it exits the waveguide and traverses the quarter waveplate (QWP′) a second time. This right-handed circularly polarized light may be converted to s-polarized light by the quarter waveplate (QWP) and absorbed by the linear polarizer (LP).

Referring to FIG. 8B, as in the example of FIG. 8A, incident left-handed circularly polarized image light passing through the quarter waveplate (QWP′) may reach the back surface of the waveguide as s-polarized light where it may be converted to p-polarized light by quarter waveplate (QWP″). This reflected light may be transformed to right-handed circularly polarized image light as it exits the waveguide and traverses the quarter waveplate (QWP′) a second time. This right-handed circularly polarized light may be converted to s-polarized light by quarter waveplate (QWP) and redirected by the beam splitter, thus removing this source of stray light from the optical path.

The orientation and retardance magnitude of QWP′ may be configured to maximize the in-coupling efficiency of linearly polarized image light into the waveguide. Furthermore, QWP″ may be configured to provide one-way retardance for the full reflected path from the back of the waveguide. In some examples, such as in connection with achromatic operation, zero-wave retardance may be achieved by orienting the polarization axes of QWP′ and QWP″ to be mutually orthogonal.

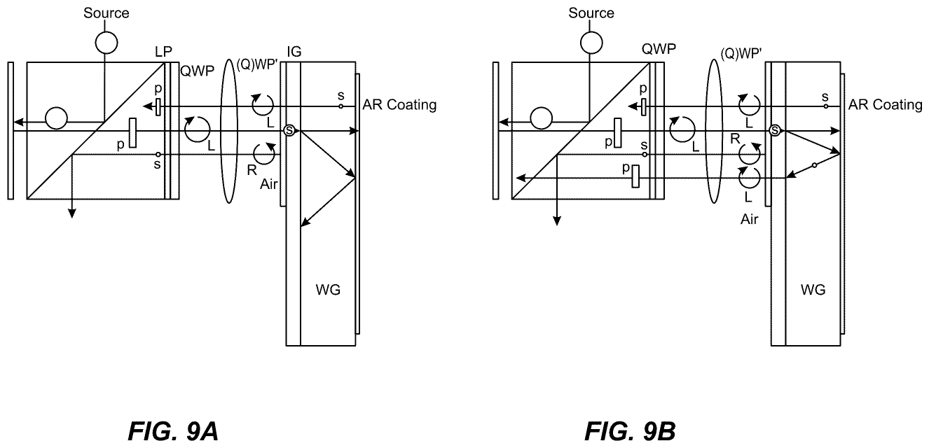

With reference to FIGS. 9A and 9B, according to further embodiments, an antireflective (AR) coating may be formed over a back surface of the waveguide. An antireflective coating may be integrated with a back surface of the waveguide in a display engine having a linear polarizer and a quarter waveplate disposed over the PBS output, as shown in FIG. 9A, or in a display engine having only a quarter waveplate disposed over the PBS output, as shown in FIG. 9B. An antireflective coating may be configured to decrease the intensity of light reflecting from the waveguide back surface and accordingly mitigate this source of stray light reentering the polarizing beam splitter (PBS), as discussed above with reference to FIGS. 7A and 7B.

An antireflective coating (ARC) may have any suitable composition and thickness and may include a single layer or a multilayer architecture. For instance, an antireflective coating may include a stack of alternating dielectric layers. An antireflective coating may be disposed over a portion of the waveguide back surface or over substantially the entire waveguide back surface.

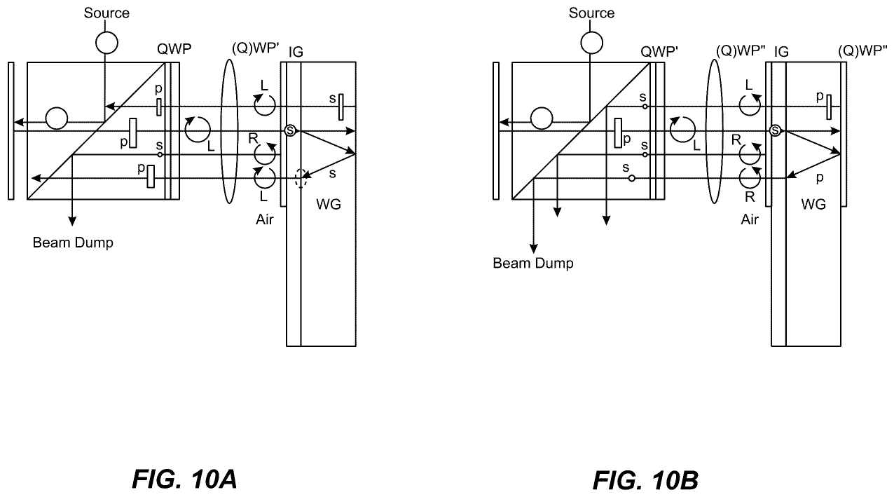

As will be appreciated, an additional source of stray light may derive from within the waveguide as back-reflected TIR light. Referring to FIG. 9B, in one example, s-polarized image light propagating within the waveguide may reflect from the AR coating and out-couple through QWP′ as left-handed circularly polarized image light that is converted by QWP to p-polarized light that enters the PBS as stray light. This interaction is illustrated again in FIG. 10A. Referring to FIG. 10B, and in accordance with further embodiments, by incorporating further quarter waveplate (QWP″) over the back surface of the waveguide, s-polarized image light propagating within the waveguide and that is converted into p-polarized light by quarter waveplate (QWP″) may out-couple through the input grating where it may be converted to right-handed circularly polarized light by quarter waveplate (QWP′). This right-handed circularly polarized light may be converted to s-polarized light by quarter waveplate (QWP) and redirected by the beam splitter, thus removing this source of stray light from the optical path.

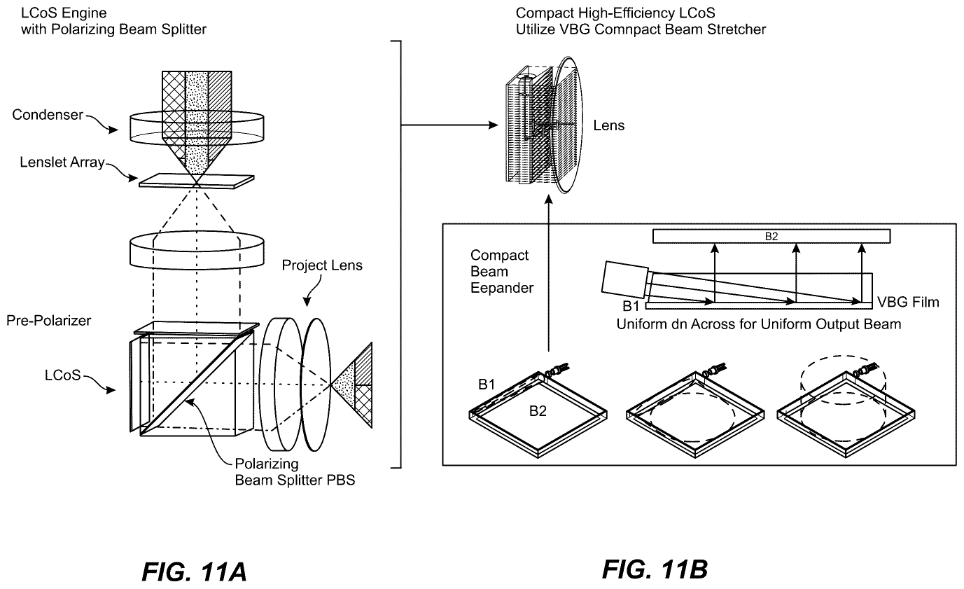

Referring now to FIGS. 11A-13B, Applicants have shown that the above-described co-integration of one or more polarizing components with an AR light engine may be extended to further AR light engine architectures. Exemplary LCoS displays are illustrated schematically in FIGS. 11A and 11B. As will be appreciated by comparing the LCoS display configuration of FIG. 11A with the configuration of FIG. 11B, in the further AR light engine architecture of FIG. 11B, the polarizing beam splitter may be replaced by a pair of volumetric Bragg gratings that are configured to expand and relay source light to the LCoS backplane.

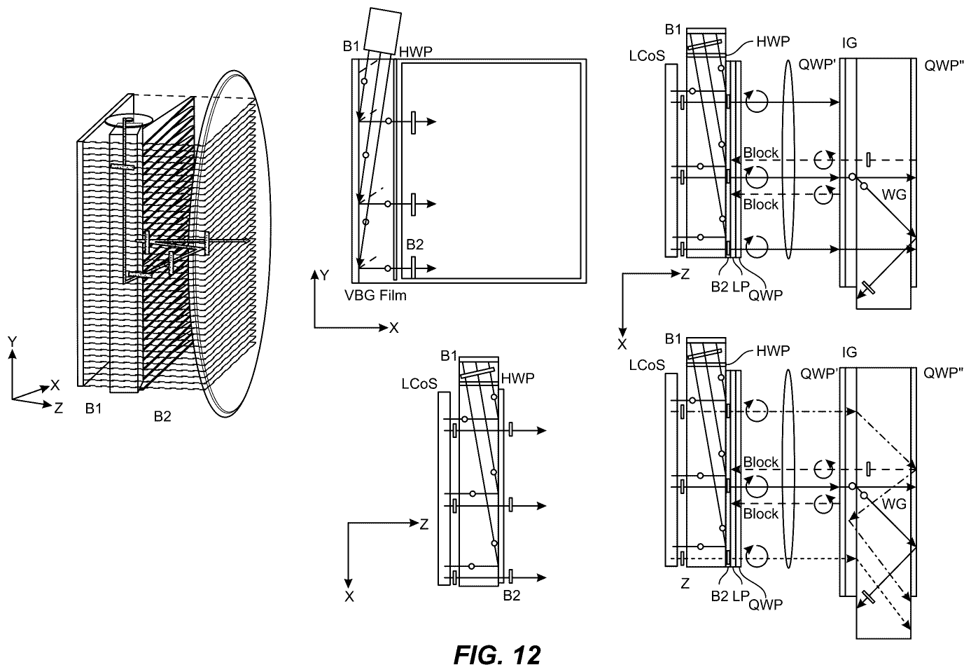

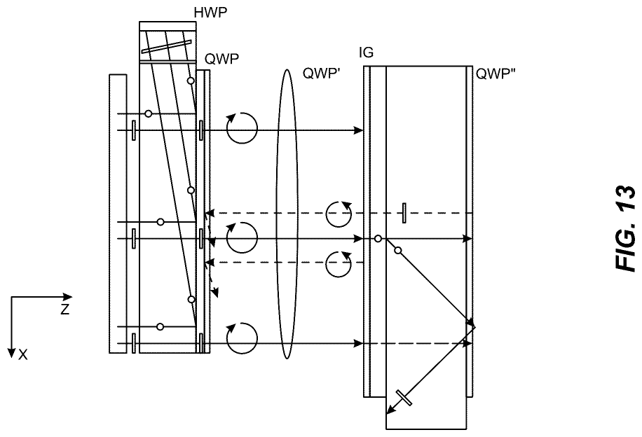

As shown in FIGS. 12 and 13, one or more polarizing components may be co-integrated with the compact and high-efficiency LCoS engine of FIG. 11B in a manner effective to block, attenuate, or redirect back-reflected light. The stray light mitigation approaches detailed in FIGS. 12 and 13 are analogous to those described with reference to FIGS. 6A-10B.

Disclosed is an optical display, such as an optical display for augmented reality applications, that is arranged to provide a high quality image to a user. The optical display includes an image source and imaging optics for generating and projecting image light. In accordance with various embodiments, the display is configured to attenuate or redirect image light that is back-reflected from the imaging optics and accordingly prevent unintentional stray light, such as light capable of generating ghost images, from reaching the eyes of a user. The back-reflection of image light from a geometric waveguide, for example, may be caused by Fresnel reflections or 0^{th} order grating diffraction from the waveguide's air/input grating interface.

According to some embodiments, in an optical display having a polarizing beam splitter (PBS) and a waveguide combiner, a linear polarizer and a quarter waveplate may be co-integrated with the PBS to absorb image light that is back-reflected from the waveguide. Alternatively, a quarter waveplate (without a linear polarizer) may be co-integrated with the PBS to redirect image light that is back-reflected from the waveguide.

According to further embodiments, in an optical display including a compact illuminator and a VBG LCoS architecture, a linear polarizer, and a quarter waveplate may be co-integrated with the illuminator to absorb image light that is back-reflected from the VBG LCoS architecture. Alternatively, a quarter waveplate (without a linear polarizer) may be co-integrated with the illuminator to redirect image light that is back-reflected from the VBG LCoS architecture.

Additional quarter waveplates may be located over the in-coupling grating of the waveguide and/or over a back surface of the waveguide to improve coupling efficiency and decrease the intensity of stray light reflecting from the waveguide and reaching the imaging optics. In still further embodiments, an antireflective (AR) coating may be disposed over the in-coupling grating of the waveguide and/or over a back surface of the waveguide to decrease the intensity of stray light that is back-reflected from the waveguide.

### Draft Surface Structure For Fresnel Lens

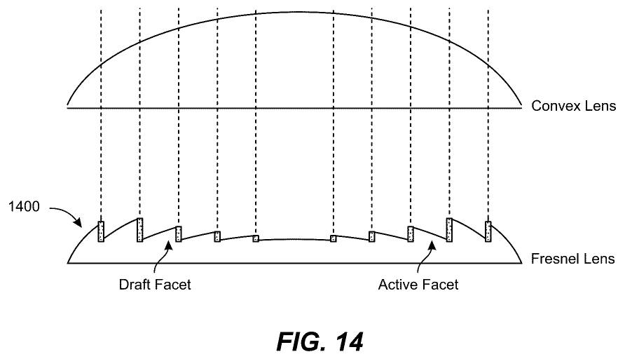

Referring to FIG. 14, shown is a side profile comparison of a plano-convex lens and a Fresnel lens. The upper surface of the Fresnel lens 1400 includes a concentric series of simple lens sections made up of a plurality of active facets that are set off from each other by an alternating plurality of draft facets.

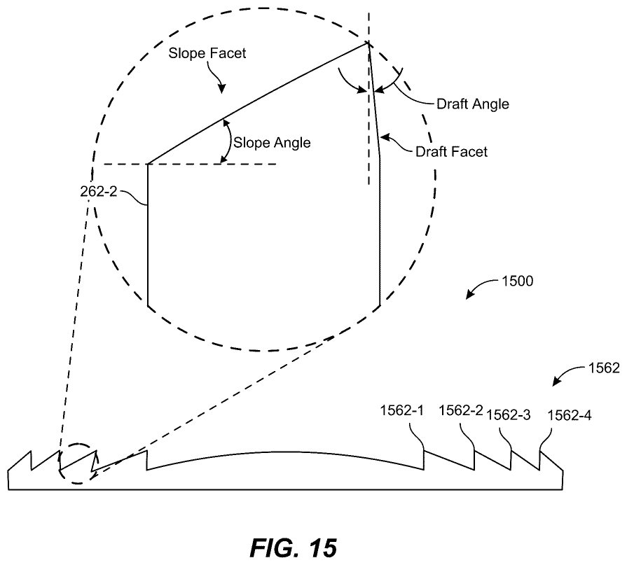

FIG. 15 illustrates a cross-section of Fresnel lens 1500. In some embodiments, a Fresnel lens, such as Fresnel lens 1500, includes a plurality of Fresnel structures 1562 (e.g., a plurality of annular rings 1562-1, 1562-2, 1562-3, and 1562-4). Each Fresnel structure 1562 (e.g., Fresnel structure 1562-2) has a sloped or active facet and a draft facet. The draft facet may be characterized by a representative draft angle (i.e., the draft facet is tilted by the representative draft angle from a reference axis). In some embodiments, the draft facet is a flat surface. In some embodiments, the draft facet is a curved surface, and the representative draft angle is an average draft angle for the draft facet.

In some embodiments, the active facet may be characterized by a representative active angle (e.g., tilted by the representative slope angle from a reference axis). In some embodiments, the sloped facet is a flat surface. In some embodiments, the sloped facet is a curved surface, and the representative slope angle is an average slope angle for the sloped facet. In Fresnel lens 1500, Fresnel structures 1562 (e.g., 1562-1, 1562-2, 1562-3, and 1562-4) have an equivalent draft angle, although a Fresnel lens where Fresnel structure 1562 have an unequal draft angle is also contemplated.

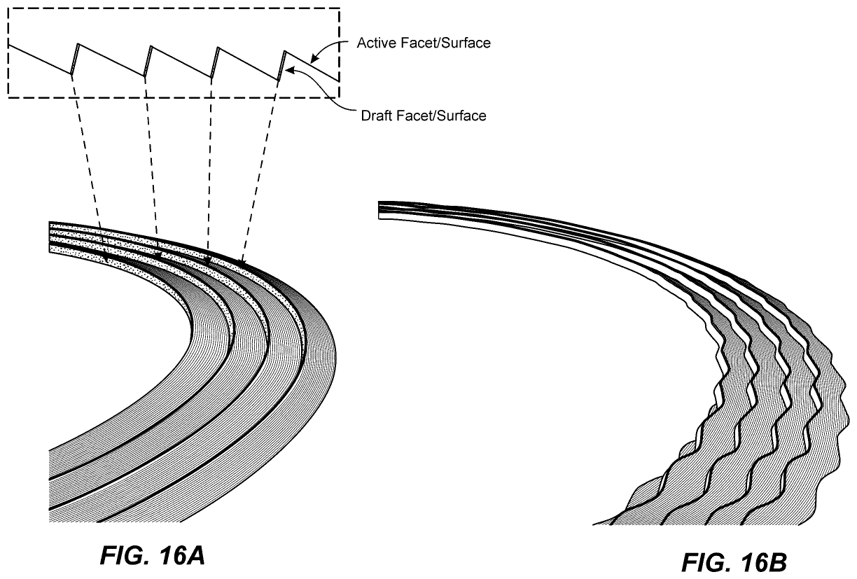

Turning to FIGS. 16A and 16B, and in accordance with particular embodiments, each of a plurality of draft facets may be configured with a wavy circular profile. That is, in contrast to a comparative Fresnel architecture where the draft facets are disposed along a constant radius from a center of the lens (FIG. 16A), disclosed are Fresnel architectures where the draft facets are disposed at an undulating radius with respect to the lens center (FIG. 16B).

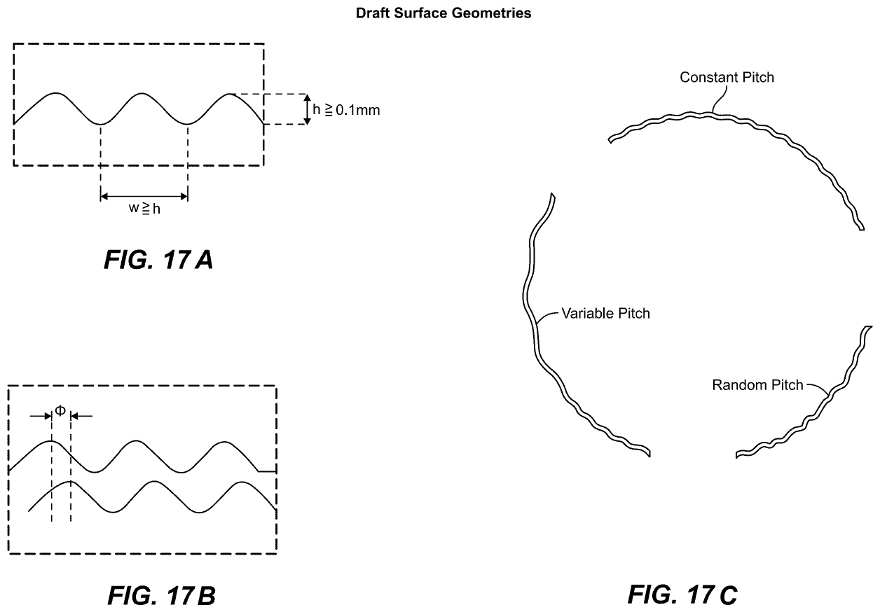

The draft facets may be configured with any suitable azimuthally-varying structure. Both inter-facet and intra-facet characteristics including, but not limited to, absolute height, and periodic amplitude and pitch, may be constant or variable, for example. Referring to FIGS. 17A-17C, and initially to FIG. 17A, a draft facet with a periodic circumferential geometry may be characterized by an amplitude (h) and a periodicity or pitch (w).

According to some embodiments, adjacent draft structures may be aligned, i.e., in phase or, as illustrated in FIG. 17B, offset circumferentially, e.g., out of phase by an angle (D. Moreover, as depicted in FIG. 17C, the periodicity of any given draft surface may be constant or variable. The disruption of a purely circular draft surface symmetry may effectively disperse light emanated from the Fresnel structure and decrease the intensity of ghost images.

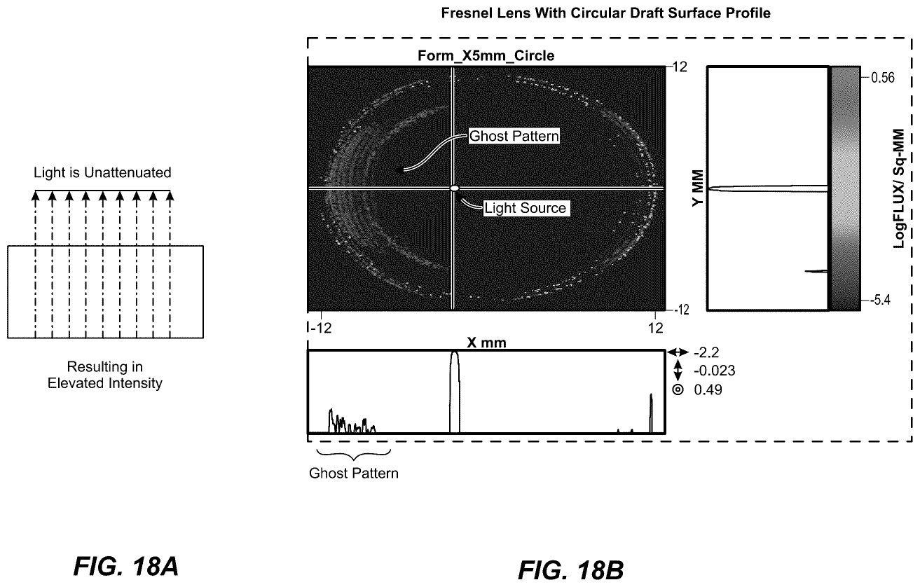

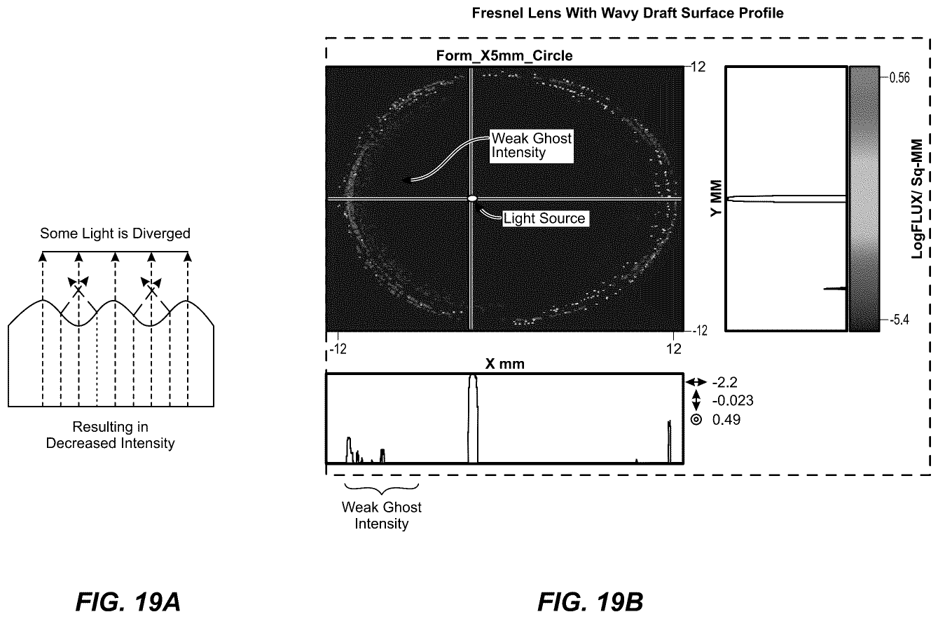

Referring to FIGS. 18A-18B and 19A-19B, shown are simulated light intensity maps at a selected image plane for both a comparative Fresnel lens having a circular draft surface profile and for a Fresnel lens having a wavy draft surface profile, respectively. As shown schematically in FIGS. 18A and 19A, light incident on the wavy draft surface may be diverged, which can decrease the intensity of refracted ghost image light. As will be appreciated with reference to FIGS. 18B and 19B, the intensity of image light contributing to a ghost pattern is substantially less in the example of a wavy draft surface profile.

A Fresnel lens includes a pseudo-concentric series of lens segments made up of active facets that are set off from each other by draft facets. The draft facets extend circumferentially with an undulating or periodic form. The periodic nature of the draft surface may disrupt or diffuse diffracted light emanating from the lens and decrease the intensity of light contributing to unwanted image light, including ghost images.

### Geometric Style Transfers

In one example, the disclosed systems and methods for improved geometric stylization may include receiving 3D models (e.g. 3D scenes and objects) reflecting real-world environments and a depth map serving as a style reference for alteration of the 3D models. The geometric stylization may include a 3D style transfer method using a Red Green Blue-Depth (RGB-D) paired with a depth map as a style image (e.g., RGB style image) that may achieve a more expressive stylization that may reflect a given style in terms of both shape and appearance. In some methods, a geometry-aware matching system may enhance the diversity of stylization while preserving local geometry through a patch-wise scheme. The patch-wise scheme may broaden the receptive fields, which may capture the spatial and temporal dependencies between pixels and geometry of the output image. In some embodiments, the geometric stylization method may include a geometry transfer method that may extract a style guide from a depth map to stylize the geometry of radiance fields. In some embodiments, the methods can be seamlessly incorporated into existing Panoptic Radiance Fields, enabling partial stylization of scenes, e.g. stylizing the target objects and classes, for more practical applicability. Further, color values in the color grid (e.g., appearance grid) may be updated in coherence with the corresponding locations of the surface distribution in the density grid, which may lead to the stylization of precise surfaces with accurate appearance. In other embodiments, a deformation network may be used to stylize shape of radiance fields and enable synchronous modifications of both shape and appearance.

In some embodiments, the style images may be selected with distinct patterns. Selecting distinct patterns may aid in the clearer identification of their geometric style. To enhance diversity and the perception of depth, the style image may be augmented into various sizes, and may be applied differently to surfaces based on their distance from the camera.

### Suppressing Crosstalk for User Conversations

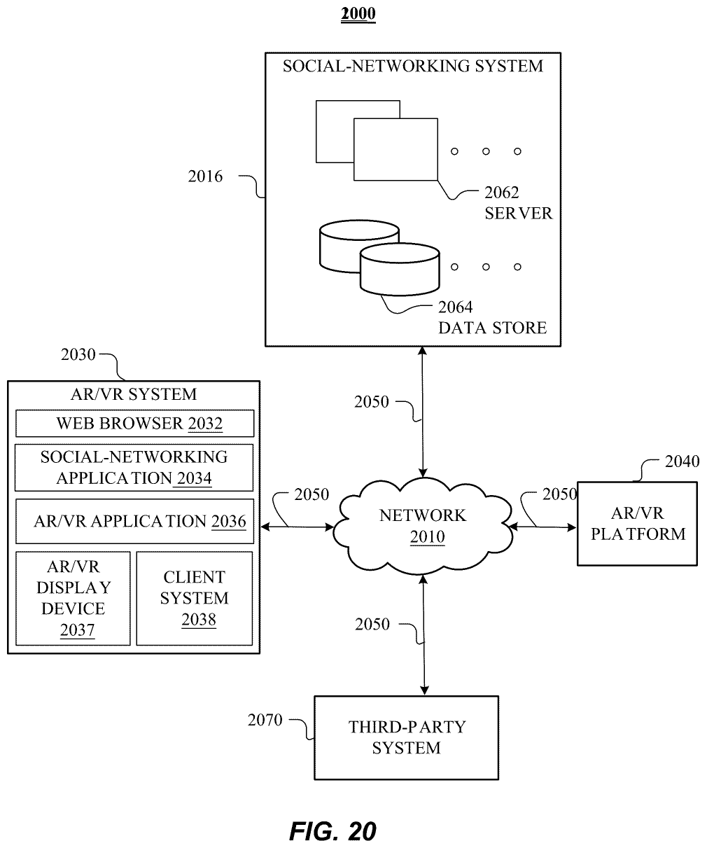

FIG. 20 illustrates an example network environment 2000 associated with an augmented-reality (AR)/virtual-reality (VR) system 2030. Network environment 2000 includes the AR/VR system 2030, an AR/VR platform 2040, a social-networking system 2060, and a third-party system 2070 connected to each other by a network 2010. Although FIG. 20 illustrates a particular arrangement of an AR/VR system 2030, an AR/VR platform 2040, a social-networking system 2060, a third-party system 2070, and a network 2010, this disclosure contemplates any suitable arrangement of an AR/VR system 2030, an AR/VR platform 2040, a social-networking system 2060, a third-party system 2070, and a network 2010. As an example and not by way of limitation, two or more of an AR/VR system 2030, a social-networking system 2060, an AR/VR platform 2040, and a third-party system 2070 may be connected to each other directly, bypassing a network 2010. As another example, two or more of an AR/VR system 2030, an AR/VR platform 2040, a social-networking system 2060, and a third-party system 2070 may be physically or logically co-located with each other in whole or in part. Moreover, although FIG. 20 illustrates a particular number of AR/VR systems 2030, AR/VR platforms 2040, social-networking systems 2060, third-party systems 2070, and networks 2010, this disclosure contemplates any suitable number of AR/VR systems 2030, AR/VR platforms 2040, social-networking systems 2060, third-party systems 2070, and networks 2010. As an example and not by way of limitation, network environment 2000 may include multiple AR/VR systems 2030, AR/VR platforms 2040, social-networking systems 2060, third-party systems 2070, and networks 2010.

This disclosure contemplates any suitable network 2010. As an example and not by way of limitation, one or more portions of a network 2010 may include an ad hoc network, an intranet, an extranet, a virtual private network (VPN), a local area network (LAN), a wireless LAN (WLAN), a wide area network (WAN), a wireless WAN (WWAN), a metropolitan area network (MAN), a portion of the Internet, a portion of the Public Switched Telephone Network (PSTN), a cellular technology-based network, a satellite communications technology-based network, another network 2010, or a combination of two or more such networks 2010.

Links 2050 may connect an AR/VR system 2030, an AR/VR platform 2040, a social-networking system 2060, and a third-party system 2070 to a communication network 2010 or to each other. This disclosure contemplates any suitable links 2050. In particular embodiments, one or more links 2050 include one or more wireline (such as for example Digital Subscriber Line (DSL) or Data Over Cable Service Interface Specification (DOCSIS)), wireless (such as for example Wi-Fi or Worldwide Interoperability for Microwave Access (WiMAX)), or optical (such as for example Synchronous Optical Network (SONET) or Synchronous Digital Hierarchy (SDH)) links. In particular embodiments, one or more links 2050 each include an ad hoc network, an intranet, an extranet, a VPN, a LAN, a WLAN, a WAN, a WWAN, a MAN, a portion of the Internet, a portion of the PSTN, a cellular technology-based network, a satellite communications technology-based network, another link 2050, or a combination of two or more such links 2050. Links 2050 need not necessarily be the same throughout a network environment 2000. One or more first links 2050 may differ in one or more respects from one or more second links 2050.

In particular embodiments, an AR/VR system 2030 may be any suitable electronic device including hardware, software, or embedded logic components, or a combination of two or more such components, and may be capable of carrying out the functionalities implemented or supported by an AR/VR system 2030. As an example and not by way of limitation, the AR/VR system 2030 may include a computer system such as a desktop computer, notebook or laptop computer, netbook, a tablet computer, e-book reader, GPS device, camera, personal digital assistant (PDA), handheld electronic device, cellular telephone, smartphone, smart speaker, smart watch, smart glasses, augmented-reality (AR) smart glasses, virtual-reality (VR) headset, other suitable electronic device, or any suitable combination thereof. This disclosure contemplates any suitable AR/VR systems 2030. In particular embodiments, an AR/VR system 2030 may enable a network user at an AR/VR system 2030 to access a network 2010. The AR/VR system 2030 may also enable the user to communicate with other users at other AR/VR systems 2030.

In particular embodiments, an AR/VR system 2030 may include a web browser 2032, and may have one or more add-ons, plug-ins, or other extensions. A user at an AR/VR system 2030 may enter a Uniform Resource Locator (URL) or other address directing a web browser 2032 to a particular server (such as server 2062, or a server associated with a third-party system 2070), and the web browser 2032 may generate a Hyper Text Transfer Protocol (HTTP) request and communicate the HTTP request to server. The server may accept the HTTP request and communicate to an AR/VR system 2030 one or more Hyper Text Markup Language (HTML) files responsive to the HTTP request. The AR/VR system 2030 may render a web interface (e.g. a webpage) based on the HTML files from the server for presentation to the user. This disclosure contemplates any suitable source files. As an example and not by way of limitation, a web interface may be rendered from HTML files, Extensible Hyper Text Markup Language (XHTML) files, or Extensible Markup Language (XML) files, according to particular needs. Such interfaces may also execute scripts, combinations of markup language and scripts, and the like. Herein, reference to a web interface encompasses one or more corresponding source files (which a browser may use to render the web interface) and vice versa, where appropriate.

In particular embodiments, an AR/VR system 2030 may include a social-networking application 2034 installed on the AR/VR system 2030. A user at an AR/VR system 2030 may use the social-networking application 2034 to access on online social network. The user at the AR/VR system 2030 may use the social-networking application 2034 to communicate with the user's social connections (e.g., friends, followers, followed accounts, contacts, etc.). The user at the AR/VR system 2030 may also use the social-networking application 2034 to interact with a plurality of content objects (e.g., posts, news articles, ephemeral content, etc.) on the online social network. As an example and not by way of limitation, the user may browse trending topics and breaking news using the social-networking application 2034.

In particular embodiments, an AR/VR system 2030 may include an AR/VR application 2036. As an example and not by way of limitation, an AR/VR application 2036 may be able to incorporate AR/VR renderings of real-world objects from the real-world environment into an AR/VR environment. A user at an AR/VR system 2030 may use the AR/VR applications 2036 to interact with the AR/VR platform 2040. In particular embodiments, the AR/VR application 2036 may comprise a stand-alone application. In particular embodiments, the AR/VR application 2036 may be integrated into the social-networking application 2034 or another suitable application (e.g., a messaging application). In particular embodiments, the AR/VR application 2036 may be also integrated into the AR/VR system 2030, an AR/VR hardware device, or any other suitable hardware devices. In particular embodiments, the AR/VR application 2036 may be also part of the AR/VR platform 2040. In particular embodiments, the AR/VR application 2036 may be accessed via the web browser 2032. In particular embodiments, the user may interact with the AR/VR platform 2040 by providing user input to the AR/VR application 2036 via various modalities (e.g., audio, voice, text, vision, image, video, gesture, motion, activity, location, orientation). The AR/VR application 2036 may communicate the user input to the AR/VR platform 2040. Based on the user input, the AR/VR platform 2040 may generate responses. The AR/VR platform 2040 may send the generated responses to the AR/VR application 2036. The AR/VR application 2036 may then present the responses to the user at the AR/VR system 2030 via various modalities (e.g., audio, text, image, video, and VR/AR rendering). As an example and not by way of limitation, the user may interact with the AR/VR platform 2040 by providing a user input (e.g., a verbal request for information of an object in the AR/VR environment) via a microphone of the AR/VR system 2030. The AR/VR application 2036 may then communicate the user input to the AR/VR platform 2040 over network 2010. The AR/VR platform 2040 may accordingly analyze the user input, generate a response based on the analysis of the user input, and communicate the generated response back to the AR/VR application 2036. The AR/VR application 2036 may then present the generated response to the user in any suitable manner (e.g., displaying a text-based push notification and/or AR/VR rendering(s) illustrating the information of the object on a display of the AR/VR system 2030).

In particular embodiments, an AR/VR system 2030 may include an AR/VR display device 2037 and, optionally, a client system 2038. The AR/VR display device 2037 may be configured to render outputs generated by the AR/VR platform 2040 to the user. The client system 2038 may comprise a companion device. The client system 2038 may be configured to perform computations associated with particular tasks (e.g., communications with the AR/VR platform 2040) locally (i.e., on-device) on the client system 2038 in particular circumstances (e.g., when the AR/VR display device 2037 is unable to perform said computations). In particular embodiments, the AR/VR system 2030, the AR/VR display device 2037, and/or the client system 2038 may each be a suitable electronic device including hardware, software, or embedded logic components, or a combination of two or more such components, and may be capable of carrying out, individually or cooperatively, the functionalities implemented or supported by the AR/VR system 2030 described herein. As an example and not by way of limitation, the AR/VR system 2030, the AR/VR display device 2037, and/or the client system 2038 may each include a computer system such as a desktop computer, notebook or laptop computer, netbook, a tablet computer, e-book reader, GPS device, camera, personal digital assistant (PDA), handheld electronic device, cellular telephone, smartphone, smart speaker, virtual-reality (VR) headset, augmented-reality (AR) smart glasses, other suitable electronic device, or any suitable combination thereof. In particular embodiments, the AR/VR display device 2037 may comprise a VR headset and the client system 2038 may comprise a smart phone. In particular embodiments, the AR/VR display device 2037 may comprise AR smart glasses and the client system 2038 may comprise a smart phone.

In particular embodiments, a user may interact with the AR/VR platform 2040 using the AR/VR display device 2037 or the client system 2038, individually or in combination. In particular embodiments, an application on the AR/VR display device 2037 may be configured to receive user input from the user, and a companion application on the client system 2038 may be configured to handle user inputs (e.g., user requests) received by the application on the AR/VR display device 2037. In particular embodiments, the AR/VR display device 2037 and the client system 2038 may be associated with each other (i.e., paired) via one or more wireless communication protocols (e.g., Bluetooth).

The following example workflow illustrates how an AR/VR display device 2037 and a client system 2038 may handle a user input provided by a user. In this example, an application on the AR/VR display device 2037 may receive a user input comprising a user request directed to the VR display device 2037. The application on the AR/VR display device 2037 may then determine a status of a wireless connection (i.e., tethering status) between the AR/VR display device 2037 and the client system 2038. If a wireless connection between the AR/VR display device 2037 and the client system 2038 is not available, the application on the AR/VR display device 2037 may communicate the user request (optionally including additional data and/or contextual information available to the AR/VR display device 2037) to the AR/VR platform 2040 via the network 2010. The AR/VR platform 2040 may then generate a response to the user request and communicate the generated response back to the AR/VR display device 2037. The AR/VR display device 2037 may then present the response to the user in any suitable manner. Alternatively, if a wireless connection between the AR/VR display device 2037 and the client system 2038 is available, the application on the AR/VR display device 2037 may communicate the user request (optionally including additional data and/or contextual information available to the AR/VR display device 2037) to the companion application on the client system 2038 via the wireless connection. The companion application on the client system 2038 may then communicate the user request (optionally including additional data and/or contextual information available to the client system 2038) to the AR/VR platform 2040 via the network 2010. The AR/VR platform 2040 may then generate a response to the user request and communicate the generated response back to the client system 2038. The companion application on the client system 2038 may then communicate the generated response to the application on the AR/VR display device 2037. The AR/VR display device 2037 may then present the response to the user in any suitable manner. In the preceding example workflow, the AR/VR display device 2037 and the client system 2038 may each perform one or more computations and/or processes at each respective step of the workflow. In particular embodiments, performance of the computations and/or processes disclosed herein may be adaptively switched between the AR/VR display device 2037 and the client system 2038 based at least in part on a device state of the AR/VR display device 2037 and/or the client system 2038, a task associated with the user input, and/or one or more additional factors. As an example and not by way of limitation, one factor may be signal strength of the wireless connection between the AR/VR display device 2037 and the client system 2038. For example, if the signal strength of the wireless connection between the AR/VR display device 2037 and the client system 2038 is strong, the computations and processes may be adaptively switched to be substantially performed by the client system 2038 in order to, for example, benefit from the greater processing power of the CPU of the client system 2038. Alternatively, if the signal strength of the wireless connection between the AR/VR display device 2037 and the client system 2038 is weak, the computations and processes may be adaptively switched to be substantially performed by the AR/VR display device 2037 in a standalone manner. In particular embodiments, if the AR/VR system 2030 does not comprise a client system 2038, the aforementioned computations and processes may be performed solely by the AR/VR display device 2037 in a standalone manner.

In particular embodiments, the AR/VR platform 2040 may comprise a backend platform or server for the AR/VR system 2030. The AR/VR platform 2040 may interact with the AR/VR system 2030, and/or the social-networking system 2060, and/or the third-party system 2070 when executing tasks.

In particular embodiments, the social-networking system 2060 may be a network-addressable computing system that can host an online social network. The social-networking system 2060 may generate, store, receive, and send social-networking data, such as, for example, user profile data, concept-profile data, social-graph information, or other suitable data related to the online social network. The social-networking system 2060 may be accessed by the other components of network environment 2000 either directly or via a network 2010. As an example and not byway of limitation, an AR/VR system 2030 may access the social-networking system 2060 using a web browser 2032 or a native application associated with the social-networking system 2060 (e.g., a mobile social-networking application, a messaging application, another suitable application, or any combination thereof) either directly or via a network 2010. In particular embodiments, the social-networking system 2060 may include one or more servers 2062. Each server 2062 may be a unitary server or a distributed server spanning multiple computers or multiple datacenters. As an example and not by way of limitation, each server 2062 may be a web server, a news server, a mail server, a message server, an advertising server, a file server, an application server, an exchange server, a database server, a proxy server, another server suitable for performing functions or processes described herein, or any combination thereof. In particular embodiments, each server 2062 may include hardware, software, or embedded logic components or a combination of two or more such components for carrying out the appropriate functionalities implemented or supported by server 2062. In particular embodiments, the social-networking system 2060 may include one or more data stores 2064. Data stores 2064 may be used to store various types of information. In particular embodiments, the information stored in data stores 2064 may be organized according to specific data structures. In particular embodiments, each data store 2064 may be a relational, columnar, correlation, or other suitable database. Although this disclosure describes or illustrates particular types of databases, this disclosure contemplates any suitable types of databases. Particular embodiments may provide interfaces that enable an AR/VR system 2030, a social-networking system 2060, an AR/VR platform 2040, or a third-party system 2070 to manage, retrieve, modify, add, or delete, the information stored in data store 2064.

In particular embodiments, the social-networking system 2060 may store one or more social graphs in one or more data stores 2064. In particular embodiments, a social graph may include multiple nodes-which may include multiple user nodes (each corresponding to a particular user) or multiple concept nodes (each corresponding to a particular concept)—and multiple edges connecting the nodes. The social-networking system 2060 may provide users of the online social network the ability to communicate and interact with other users. In particular embodiments, users may join the online social network via the social-networking system 2060 and then add connections (e.g., relationships) to a number of other users of the social-networking system 2060 whom they want to be connected to. Herein, the term “friend” may refer to any other user of the social-networking system 2060 with whom a user has formed a connection, association, or relationship via the social-networking system 2060.

In particular embodiments, the social-networking system 2060 may provide users with the ability to take actions on various types of items or objects, supported by the social-networking system 2060. As an example and not by way of limitation, the items and objects may include groups or social networks to which users of the social-networking system 2060 may belong, events or calendar entries in which a user might be interested, computer-based applications that a user may use, transactions that allow users to buy or sell items via the service, interactions with advertisements that a user may perform, or other suitable items or objects. A user may interact with anything that is capable of being represented in the social-networking system 2060 or by an external system of a third-party system 2070, which is separate from the social-networking system 2060 and coupled to the social-networking system 2060 via a network 2010.

In particular embodiments, the social-networking system 2060 may be capable of linking a variety of entities. As an example and not by way of limitation, the social-networking system 2060 may enable users to interact with each other as well as receive content from third-party systems 2070 or other entities, or to allow users to interact with these entities through an application programming interfaces (API) or other communication channels.

In particular embodiments, a third-party system 2070 may include one or more types of servers, one or more data stores, one or more interfaces, including but not limited to APIs, one or more web services, one or more content sources, one or more networks, or any other suitable components, e.g., that servers may communicate with. A third-party system 2070 may be operated by a different entity from an entity operating the social-networking system 2060. As an example and not by way of limitation, the entity operating the third-party system 2070 may be a developer for one or more AR/VR applications 2036. In particular embodiments, however, the social-networking system 2060 and third-party systems 2070 may operate in conjunction with each other to provide social-networking services to users of the social-networking system 2060 or third-party systems 2070. In this sense, the social-networking system 2060 may provide a platform, or backbone, which other systems, such as third-party systems 2070, may use to provide social-networking services and functionality to users across the Internet.

In particular embodiments, a third-party system 2070 may include a third-party content object provider. As an example and not by way of limitation, the third-party content object provider may be a developer for one or more AR/VR applications 2036. A third-party content object provider may include one or more sources of content objects, which may be communicated to an AR/VR system 2030. As an example and not byway of limitation, content objects may include information regarding things or activities of interest to the user, such as, for example, movie show times, movie reviews, restaurant reviews, restaurant menus, product information and reviews, or other suitable information. As another example and not by way of limitation, content objects may include incentive content objects, such as coupons, discount tickets, gift certificates, or other suitable incentive objects. As yet another example and not by way of limitation, content objects may include one or more AR/VR applications 2036. In particular embodiments, a third-party content provider may use one or more third-party agents to provide content objects and/or services. A third-party agent may be an implementation that is hosted and executing on the third-party system 2070.

In particular embodiments, the social-networking system 2060 also includes user-generated content objects, which may enhance a user's interactions with the social-networking system 2060. User-generated content may include anything a user can add, upload, send, or “post” to the social-networking system 2060. As an example and not byway of limitation, a user communicates posts to the social-networking system 2060 from an AR/VR system 2030. Posts may include data such as status updates or other textual data, location information, photos, videos, links, music or other similar data or media. Content may also be added to the social-networking system 2060 by a third-party through a “communication channel,” such as a newsfeed or stream.

In particular embodiments, the social-networking system 2060 may include a variety of servers, sub-systems, programs, modules, logs, and data stores. In particular embodiments, the social-networking system 2060 may include one or more of the following: a web server, action logger, API-request server, relevance-and-ranking engine, content-object classifier, notification controller, action log, third-party-content-object-exposure log, inference module, authorization/privacy server, search module, advertisement-targeting module, user-interface module, user-profile store, connection store, third-party content store, or location store. The social-networking system 2060 may also include suitable components such as network interfaces, security mechanisms, load balancers, failover servers, management-and-network-operations consoles, other suitable components, or any suitable combination thereof. In particular embodiments, the social-networking system 2060 may include one or more user-profile stores for storing user profiles. A user profile may include, for example, biographic information, demographic information, behavioral information, social information, or other types of descriptive information, such as work experience, educational history, hobbies or preferences, interests, affinities, or location. Interest information may include interests related to one or more categories. Categories may be general or specific. As an example and not by way of limitation, if a user “likes” an article about a brand of shoes the category may be the brand, or the general category of “shoes” or “clothing.” A connection store may be used for storing connection information about users. The connection information may indicate users who have similar or common work experience, group memberships, hobbies, educational history, or are in any way related or share common attributes. The connection information may also include user-defined connections between different users and content (both internal and external). A web server may be used for linking the social-networking system 2060 to one or more AR/VR systems 2030 or one or more third-party systems 2070 via a network 2010. The web server may include a mail server or other messaging functionality for receiving and routing messages between the social-networking system 2060 and one or more AR/VR systems 2030. An API-request server may allow, for example, an AR/VR platform 2040 or a third-party system 2070 to access information from the social-networking system 2060 by calling one or more APIs. An action logger may be used to receive communications from a web server about a user's actions on or off the social-networking system 2060. In conjunction with the action log, a third-party-content-object log may be maintained of user exposures to third-party-content objects. A notification controller may provide information regarding content objects to an AR/VR system 2030. Information may be pushed to an AR/VR system 2030 as notifications, or information may be pulled from an AR/VR system 2030 responsive to a user input comprising a user request received from an AR/VR system 2030. Authorization servers may be used to enforce one or more privacy settings of the users of the social-networking system 2060. A privacy setting of a user may determine how particular information associated with a user can be shared. The authorization server may allow users to opt in to or opt out of having their actions logged by the social-networking system 2060 or shared with other systems (e.g., a third-party system 2070), such as, for example, by setting appropriate privacy settings. Third-party-content-object stores may be used to store content objects received from third parties, such as a third-party system 2070. Location stores may be used for storing location information received from AR/VR systems 2030 associated with users. Advertisement-pricing modules may combine social information, the current time, location information, or other suitable information to provide relevant advertisements, in the form of notifications, to a user.

FIG. 20 illustrates an example network environment 2000 associated with an augmented-reality (AR)/virtual-reality (VR) system 2030. Network environment 2000 includes the AR/VR system 2030, an AR/VR platform 2040, a social-networking system 2060, and a third-party system 2070 connected to each other by a network 2010. Although FIG. 20 illustrates a particular arrangement of an AR/VR system 2030, an AR/VR platform 2040, a social-networking system 2060, a third-party system 2070, and a network 2010, this disclosure contemplates any suitable arrangement of an AR/VR system 2030, an AR/VR platform 2040, a social-networking system 2060, a third-party system 2070, and a network 2010. As an example and not by way of limitation, two or more of an AR/VR system 2030, a social-networking system 2060, an AR/VR platform 2040, and a third-party system 2070 may be connected to each other directly, bypassing a network 2010. As another example, two or more of an AR/VR system 2030, an AR/VR platform 2040, a social-networking system 2060, and a third-party system 2070 may be physically or logically co-located with each other in whole or in part. Moreover, although FIG. 20 illustrates a particular number of AR/VR systems 2030, AR/VR platforms 2040, social-networking systems 2060, third-party systems 2070, and networks 2010, this disclosure contemplates any suitable number of AR/VR systems 2030, AR/VR platforms 2040, social-networking systems 2060, third-party systems 2070, and networks 2010. As an example and not by way of limitation, network environment 2000 may include multiple AR/VR systems 2030, AR/VR platforms 2040, social-networking systems 2060, third-party systems 2070, and networks 2010.

This disclosure contemplates any suitable network 2010. As an example and not by way of limitation, one or more portions of a network 2010 may include an ad hoc network, an intranet, an extranet, a virtual private network (VPN), a local area network (LAN), a wireless LAN (WLAN), a wide area network (WAN), a wireless WAN (WWAN), a metropolitan area network (MAN), a portion of the Internet, a portion of the Public Switched Telephone Network (PSTN), a cellular technology-based network, a satellite communications technology-based network, another network 2010, or a combination of two or more such networks 2010.

Links 2050 may connect an AR/VR system 2030, an AR/VR platform 2040, a social-networking system 2060, and a third-party system 2070 to a communication network 2010 or to each other. This disclosure contemplates any suitable links 2050. In particular embodiments, one or more links 2050 include one or more wireline (such as for example Digital Subscriber Line (DSL) or Data Over Cable Service Interface Specification (DOCSIS)), wireless (such as for example Wi-Fi or Worldwide Interoperability for Microwave Access (WiMAX)), or optical (such as for example Synchronous Optical Network (SONET) or Synchronous Digital Hierarchy (SDH)) links. In particular embodiments, one or more links 2050 each include an ad hoc network, an intranet, an extranet, a VPN, a LAN, a WLAN, a WAN, a WWAN, a MAN, a portion of the Internet, a portion of the PSTN, a cellular technology-based network, a satellite communications technology-based network, another link 2050, or a combination of two or more such links 2050. Links 2050 need not necessarily be the same throughout a network environment 2000. One or more first links 2050 may differ in one or more respects from one or more second links 2050.

In particular embodiments, an AR/VR system 2030 may be any suitable electronic device including hardware, software, or embedded logic components, or a combination of two or more such components, and may be capable of carrying out the functionalities implemented or supported by an AR/VR system 2030. As an example and not by way of limitation, the AR/VR system 2030 may include a computer system such as a desktop computer, notebook or laptop computer, netbook, a tablet computer, e-book reader, GPS device, camera, personal digital assistant (PDA), handheld electronic device, cellular telephone, smartphone, smart speaker, smart watch, smart glasses, augmented-reality (AR) smart glasses, virtual-reality (VR) headset, other suitable electronic device, or any suitable combination thereof. This disclosure contemplates any suitable AR/VR systems 2030. In particular embodiments, an AR/VR system 2030 may enable a network user at an AR/VR system 2030 to access a network 2010. The AR/VR system 2030 may also enable the user to communicate with other users at other AR/VR systems 2030.

In particular embodiments, an AR/VR system 2030 may include a web browser 2032, and may have one or more add-ons, plug-ins, or other extensions. A user at an AR/VR system 2030 may enter a Uniform Resource Locator (URL) or other address directing a web browser 2032 to a particular server (such as server 2062, or a server associated with a third-party system 2070), and the web browser 2032 may generate a Hyper Text Transfer Protocol (HTTP) request and communicate the HTTP request to server. The server may accept the HTTP request and communicate to an AR/VR system 2030 one or more Hyper Text Markup Language (HTML) files responsive to the HTTP request. The AR/VR system 2030 may render a web interface (e.g. a webpage) based on the HTML files from the server for presentation to the user. This disclosure contemplates any suitable source files. As an example and not by way of limitation, a web interface may be rendered from HTML files, Extensible Hyper Text Markup Language (XHTML) files, or Extensible Markup Language (XML) files, according to particular needs. Such interfaces may also execute scripts, combinations of markup language and scripts, and the like. Herein, reference to a web interface encompasses one or more corresponding source files (which a browser may use to render the web interface) and vice versa, where appropriate.

In particular embodiments, an AR/VR system 2030 may include a social-networking application 2034 installed on the AR/VR system 2030. A user at an AR/VR system 2030 may use the social-networking application 2034 to access on online social network. The user at the AR/VR system 2030 may use the social-networking application 2034 to communicate with the user's social connections (e.g., friends, followers, followed accounts, contacts, etc.). The user at the AR/VR system 2030 may also use the social-networking application 2034 to interact with a plurality of content objects (e.g., posts, news articles, ephemeral content, etc.) on the online social network. As an example and not by way of limitation, the user may browse trending topics and breaking news using the social-networking application 2034.

In particular embodiments, an AR/VR system 2030 may include an AR/VR application 2036. As an example and not by way of limitation, an AR/VR application 2036 may be able to incorporate AR/VR renderings of real-world objects from the real-world environment into an AR/VR environment. A user at an AR/VR system 2030 may use the AR/VR applications 2036 to interact with the AR/VR platform 2040. In particular embodiments, the AR/VR application 2036 may comprise a stand-alone application. In particular embodiments, the AR/VR application 2036 may be integrated into the social-networking application 2034 or another suitable application (e.g., a messaging application). In particular embodiments, the AR/VR application 2036 may be also integrated into the AR/VR system 2030, an AR/VR hardware device, or any other suitable hardware devices. In particular embodiments, the AR/VR application 2036 may be also part of the AR/VR platform 2040. In particular embodiments, the AR/VR application 2036 may be accessed via the web browser 2032. In particular embodiments, the user may interact with the AR/VR platform 2040 by providing user input to the AR/VR application 2036 via various modalities (e.g., audio, voice, text, vision, image, video, gesture, motion, activity, location, orientation). The AR/VR application 2036 may communicate the user input to the AR/VR platform 2040. Based on the user input, the AR/VR platform 2040 may generate responses. The AR/VR platform 2040 may send the generated responses to the AR/VR application 2036. The AR/VR application 2036 may then present the responses to the user at the AR/VR system 2030 via various modalities (e.g., audio, text, image, video, and VR/AR rendering). As an example and not by way of limitation, the user may interact with the AR/VR platform 2040 by providing a user input (e.g., a verbal request for information of an object in the AR/VR environment) via a microphone of the AR/VR system 2030. The AR/VR application 2036 may then communicate the user input to the AR/VR platform 2040 over network 2010. The AR/VR platform 2040 may accordingly analyze the user input, generate a response based on the analysis of the user input, and communicate the generated response back to the AR/VR application 2036. The AR/VR application 2036 may then present the generated response to the user in any suitable manner (e.g., displaying a text-based push notification and/or AR/VR rendering(s) illustrating the information of the object on a display of the AR/VR system 2030).

In particular embodiments, an AR/VR system 2030 may include an AR/VR display device 2037 and, optionally, a client system 2038. The AR/VR display device 2037 may be configured to render outputs generated by the AR/VR platform 2040 to the user. The client system 2038 may comprise a companion device. The client system 2038 may be configured to perform computations associated with particular tasks (e.g., communications with the AR/VR platform 2040) locally (i.e., on-device) on the client system 2038 in particular circumstances (e.g., when the AR/VR display device 2037 is unable to perform said computations). In particular embodiments, the AR/VR system 2030, the AR/VR display device 2037, and/or the client system 2038 may each be a suitable electronic device including hardware, software, or embedded logic components, or a combination of two or more such components, and may be capable of carrying out, individually or cooperatively, the functionalities implemented or supported by the AR/VR system 2030 described herein. As an example and not by way of limitation, the AR/VR system 2030, the AR/VR display device 2037, and/or the client system 2038 may each include a computer system such as a desktop computer, notebook or laptop computer, netbook, a tablet computer, e-book reader, GPS device, camera, personal digital assistant (PDA), handheld electronic device, cellular telephone, smartphone, smart speaker, virtual-reality (VR) headset, augmented-reality (AR) smart glasses, other suitable electronic device, or any suitable combination thereof. In particular embodiments, the AR/VR display device 2037 may comprise a VR headset and the client system 2038 may comprise a smart phone. In particular embodiments, the AR/VR display device 2037 may comprise AR smart glasses and the client system 2038 may comprise a smart phone.

In particular embodiments, a user may interact with the AR/VR platform 2040 using the AR/VR display device 2037 or the client system 2038, individually or in combination. In particular embodiments, an application on the AR/VR display device 2037 may be configured to receive user input from the user, and a companion application on the client system 2038 may be configured to handle user inputs (e.g., user requests) received by the application on the AR/VR display device 2037. In particular embodiments, the AR/VR display device 2037 and the client system 2038 may be associated with each other (i.e., paired) via one or more wireless communication protocols (e.g., Bluetooth).

The following example workflow illustrates how an AR/VR display device 2037 and a client system 2038 may handle a user input provided by a user. In this example, an application on the AR/VR display device 2037 may receive a user input comprising a user request directed to the VR display device 2037. The application on the AR/VR display device 2037 may then determine a status of a wireless connection (i.e., tethering status) between the AR/VR display device 2037 and the client system 2038. If a wireless connection between the AR/VR display device 2037 and the client system 2038 is not available, the application on the AR/VR display device 2037 may communicate the user request (optionally including additional data and/or contextual information available to the AR/VR display device 2037) to the AR/VR platform 2040 via the network 2010. The AR/VR platform 2040 may then generate a response to the user request and communicate the generated response back to the AR/VR display device 2037. The AR/VR display device 2037 may then present the response to the user in any suitable manner. Alternatively, if a wireless connection between the AR/VR display device 2037 and the client system 2038 is available, the application on the AR/VR display device 2037 may communicate the user request (optionally including additional data and/or contextual information available to the AR/VR display device 2037) to the companion application on the client system 2038 via the wireless connection. The companion application on the client system 2038 may then communicate the user request (optionally including additional data and/or contextual information available to the client system 2038) to the AR/VR platform 2040 via the network 2010. The AR/VR platform 2040 may then generate a response to the user request and communicate the generated response back to the client system 2038. The companion application on the client system 2038 may then communicate the generated response to the application on the AR/VR display device 2037. The AR/VR display device 2037 may then present the response to the user in any suitable manner. In the preceding example workflow, the AR/VR display device 2037 and the client system 2038 may each perform one or more computations and/or processes at each respective step of the workflow. In particular embodiments, performance of the computations and/or processes disclosed herein may be adaptively switched between the AR/VR display device 2037 and the client system 2038 based at least in part on a device state of the AR/VR display device 2037 and/or the client system 2038, a task associated with the user input, and/or one or more additional factors. As an example and not by way of limitation, one factor may be signal strength of the wireless connection between the AR/VR display device 2037 and the client system 2038. For example, if the signal strength of the wireless connection between the AR/VR display device 2037 and the client system 2038 is strong, the computations and processes may be adaptively switched to be substantially performed by the client system 2038 in order to, for example, benefit from the greater processing power of the CPU of the client system 2038. Alternatively, if the signal strength of the wireless connection between the AR/VR display device 2037 and the client system 2038 is weak, the computations and processes may be adaptively switched to be substantially performed by the AR/VR display device 2037 in a standalone manner. In particular embodiments, if the AR/VR system 2030 does not comprise a client system 2038, the aforementioned computations and processes may be performed solely by the AR/VR display device 2037 in a standalone manner.

In particular embodiments, the AR/VR platform 2040 may comprise a backend platform or server for the AR/VR system 2030. The AR/VR platform 2040 may interact with the AR/VR system 2030, and/or the social-networking system 2060, and/or the third-party system 2070 when executing tasks.

In particular embodiments, the social-networking system 2060 may be a network-addressable computing system that can host an online social network. The social-networking system 2060 may generate, store, receive, and send social-networking data, such as, for example, user profile data, concept-profile data, social-graph information, or other suitable data related to the online social network. The social-networking system 2060 may be accessed by the other components of network environment 2000 either directly or via a network 2010. As an example and not byway of limitation, an AR/VR system 2030 may access the social-networking system 2060 using a web browser 2032 or a native application associated with the social-networking system 2060 (e.g., a mobile social-networking application, a messaging application, another suitable application, or any combination thereof) either directly or via a network 2010. In particular embodiments, the social-networking system 2060 may include one or more servers 2062. Each server 2062 may be a unitary server or a distributed server spanning multiple computers or multiple datacenters. As an example and not by way of limitation, each server 2062 may be a web server, a news server, a mail server, a message server, an advertising server, a file server, an application server, an exchange server, a database server, a proxy server, another server suitable for performing functions or processes described herein, or any combination thereof. In particular embodiments, each server 2062 may include hardware, software, or embedded logic components or a combination of two or more such components for carrying out the appropriate functionalities implemented or supported by server 2062. In particular embodiments, the social-networking system 2060 may include one or more data stores 2064. Data stores 2064 may be used to store various types of information. In particular embodiments, the information stored in data stores 2064 may be organized according to specific data structures. In particular embodiments, each data store 2064 may be a relational, columnar, correlation, or other suitable database. Although this disclosure describes or illustrates particular types of databases, this disclosure contemplates any suitable types of databases. Particular embodiments may provide interfaces that enable an AR/VR system 2030, a social-networking system 2060, an AR/VR platform 2040, or a third-party system 2070 to manage, retrieve, modify, add, or delete, the information stored in data store 2064.

In particular embodiments, the social-networking system 2060 may store one or more social graphs in one or more data stores 2064. In particular embodiments, a social graph may include multiple nodes-which may include multiple user nodes (each corresponding to a particular user) or multiple concept nodes (each corresponding to a particular concept)—and multiple edges connecting the nodes. The social-networking system 2060 may provide users of the online social network the ability to communicate and interact with other users. In particular embodiments, users may join the online social network via the social-networking system 2060 and then add connections (e.g., relationships) to a number of other users of the social-networking system 2060 whom they want to be connected to. Herein, the term “friend” may refer to any other user of the social-networking system 2060 with whom a user has formed a connection, association, or relationship via the social-networking system 2060.

In particular embodiments, the social-networking system 2060 may provide users with the ability to take actions on various types of items or objects, supported by the social-networking system 2060. As an example and not by way of limitation, the items and objects may include groups or social networks to which users of the social-networking system 2060 may belong, events or calendar entries in which a user might be interested, computer-based applications that a user may use, transactions that allow users to buy or sell items via the service, interactions with advertisements that a user may perform, or other suitable items or objects. A user may interact with anything that is capable of being represented in the social-networking system 2060 or by an external system of a third-party system 2070, which is separate from the social-networking system 2060 and coupled to the social-networking system 2060 via a network 2010.

In particular embodiments, the social-networking system 2060 may be capable of linking a variety of entities. As an example and not by way of limitation, the social-networking system 2060 may enable users to interact with each other as well as receive content from third-party systems 2070 or other entities, or to allow users to interact with these entities through an application programming interfaces (API) or other communication channels.

In particular embodiments, a third-party system 2070 may include one or more types of servers, one or more data stores, one or more interfaces, including but not limited to APIs, one or more web services, one or more content sources, one or more networks, or any other suitable components, e.g., that servers may communicate with. A third-party system 2070 may be operated by a different entity from an entity operating the social-networking system 2060. As an example and not by way of limitation, the entity operating the third-party system 2070 may be a developer for one or more AR/VR applications 2036. In particular embodiments, however, the social-networking system 2060 and third-party systems 2070 may operate in conjunction with each other to provide social-networking services to users of the social-networking system 2060 or third-party systems 2070. In this sense, the social-networking system 2060 may provide a platform, or backbone, which other systems, such as third-party systems 2070, may use to provide social-networking services and functionality to users across the Internet.

In particular embodiments, a third-party system 2070 may include a third-party content object provider. As an example and not by way of limitation, the third-party content object provider may be a developer for one or more AR/VR applications 2036. A third-party content object provider may include one or more sources of content objects, which may be communicated to an AR/VR system 2030. As an example and not by way of limitation, content objects may include information regarding things or activities of interest to the user, such as, for example, movie show times, movie reviews, restaurant reviews, restaurant menus, product information and reviews, or other suitable information. As another example and not by way of limitation, content objects may include incentive content objects, such as coupons, discount tickets, gift certificates, or other suitable incentive objects. As yet another example and not by way of limitation, content objects may include one or more AR/VR applications 2036. In particular embodiments, a third-party content provider may use one or more third-party agents to provide content objects and/or services. A third-party agent may be an implementation that is hosted and executing on the third-party system 2070.

In particular embodiments, the social-networking system 2060 also includes user-generated content objects, which may enhance a user's interactions with the social-networking system 2060. User-generated content may include anything a user can add, upload, send, or “post” to the social-networking system 2060. As an example and not byway of limitation, a user communicates posts to the social-networking system 2060 from an AR/VR system 2030. Posts may include data such as status updates or other textual data, location information, photos, videos, links, music or other similar data or media. Content may also be added to the social-networking system 2060 by a third-party through a “communication channel,” such as a newsfeed or stream.

In particular embodiments, the social-networking system 2060 may include a variety of servers, sub-systems, programs, modules, logs, and data stores. In particular embodiments, the social-networking system 2060 may include one or more of the following: a web server, action logger, API-request server, relevance-and-ranking engine, content-object classifier, notification controller, action log, third-party-content-object-exposure log, inference module, authorization/privacy server, search module, advertisement-targeting module, user-interface module, user-profile store, connection store, third-party content store, or location store. The social-networking system 2060 may also include suitable components such as network interfaces, security mechanisms, load balancers, failover servers, management-and-network-operations consoles, other suitable components, or any suitable combination thereof. In particular embodiments, the social-networking system 2060 may include one or more user-profile stores for storing user profiles. A user profile may include, for example, biographic information, demographic information, behavioral information, social information, or other types of descriptive information, such as work experience, educational history, hobbies or preferences, interests, affinities, or location. Interest information may include interests related to one or more categories. Categories may be general or specific. As an example and not by way of limitation, if a user “likes” an article about a brand of shoes the category may be the brand, or the general category of “shoes” or “clothing.” A connection store may be used for storing connection information about users. The connection information may indicate users who have similar or common work experience, group memberships, hobbies, educational history, or are in any way related or share common attributes. The connection information may also include user-defined connections between different users and content (both internal and external). A web server may be used for linking the social-networking system 2060 to one or more AR/VR systems 2030 or one or more third-party systems 2070 via a network 2010. The web server may include a mail server or other messaging functionality for receiving and routing messages between the social-networking system 2060 and one or more AR/VR systems 2030. An API-request server may allow, for example, an AR/VR platform 2040 or a third-party system 2070 to access information from the social-networking system 2060 by calling one or more APIs. An action logger may be used to receive communications from a web server about a user's actions on or off the social-networking system 2060. In conjunction with the action log, a third-party-content-object log may be maintained of user exposures to third-party-content objects. A notification controller may provide information regarding content objects to an AR/VR system 2030. Information may be pushed to an AR/VR system 2030 as notifications, or information may be pulled from an AR/VR system 2030 responsive to a user input comprising a user request received from an AR/VR system 2030. Authorization servers may be used to enforce one or more privacy settings of the users of the social-networking system 2060. A privacy setting of a user may determine how particular information associated with a user can be shared. The authorization server may allow users to opt in to or opt out of having their actions logged by the social-networking system 2060 or shared with other systems (e.g., a third-party system 2070), such as, for example, by setting appropriate privacy settings. Third-party-content-object stores may be used to store content objects received from third parties, such as a third-party system 2070. Location stores may be used for storing location information received from AR/VR systems 2030 associated with users. Advertisement-pricing modules may combine social information, the current time, location information, or other suitable information to provide relevant advertisements, in the form of notifications, to a user. Multi-channel Directional ASR

To begin with, the multi-channel ASR system may get speech signals from different directions. In particular embodiments, the client system 2038 may generate directional data associated with the plurality of speech signals. Instead of feeding the raw audio channels into an ASR model, the multi-channel ASR system may use beamforming to generate multi-channel input data first. Thus, the directional data may include the output from the beamforming signal processing algorithm for multiple directions. In particular embodiments, generating the directional data based on the beamforming signal processing algorithm may comprise mapping temporal differences associated with the plurality of speech signals to intensity differences and inputting the intensity differences to the multi-channel ASR model. The multi-channel ASR system may then extract log-Mel features for each direction and integrate them together. Some conventional methods and systems may extract log-Mel features directly from the captured microphone channels. However, such conventional approach may not work well because log-Mel processing removes the most important clue, i.e., the information that represents differences of arrival delays. The embodiments disclosed herein may solve this issue by the beamforming step which converts the temporal differences to intensity differences. In particular embodiments, the client system 2038 may extract, for each of the plurality of directions, one or more acoustic (e.g., log-Mel) features for one or more of the plurality of speech signals associated with the respective direction. The client system 2038 may further integrate the extracted log-Mel features for each of the plurality of directions.

The multi-channel ASR system may then use a multi-channel ASR model to process the integrated features. The multi-channel ASR system may implicitly determine which speech signal is received from the user direction and which person the user is talking to, and only transcribe these speech signals. In particular embodiments, the client system 2038 may identify, based on an analysis of the integrated features by a multi-channel automatic-speech-recognition (ASR) model, one or more speech signals corresponding to one or more utterances from the first user. The client system 2038 may also identify, based on an analysis of the integrated features by a multi-channel automatic-speech-recognition (ASR) model, the one or more target speech signals from among the plurality of speech signals as corresponding to one or more utterances from one or more second users. The one or more second users may be in a conversation with the first user. In particular embodiments, the client system 2038 may additionally identify, based on an analysis of the integrated features by a multi-channel automatic-speech-recognition (ASR) model, the one or more cross-talking speech signals from among the plurality of speech signals. In particular embodiments, generating the directional data may be based on relative phase and intensity differences between the plurality of microphones.

In particular embodiments, the client system 2038 may generate one or more translations for one or more speech signals corresponding to one or more utterances from the first user. The presented one or more transcriptions may be of the one or more translations. Because different speakers speak different languages, the directionality may also help transcribe the correct language (which otherwise would cause severe ASR errors). In particular embodiments, the one or more transcriptions may comprise one or more of an image file of a text transcription of the one or more target speech signals or an audio file of a text-to-speech conversion of the text transcription. As an example and not by way of limitation, the transcriptions may be presented to the first user as text on a screen display of the head-mounted device. As another example and not by way of limitation, the transcriptions may be read out to the first user as audio transcriptions.

In particular embodiments, the multi-channel ASR system may be used in other scenarios as follows. In once scenario, instead of head-mounted devices (e.g., smart glasses) with a microphone array, multiple users in a room may put their smartphones on the table, and the input to the multi-channel ASR system may include all audio signals from these microphones. Some users may have earphones instead. Instead of applying a beamformer on these inputs, the audio streams from the multiple distributed microphones themselves may act like the beamformed signals that constitute the multi-channel input to the ASR model. In another scenario, the microphone array of a head-mounted device (e.g., smart glasses) may get replaced by a mobile phone that has multiple microphones.

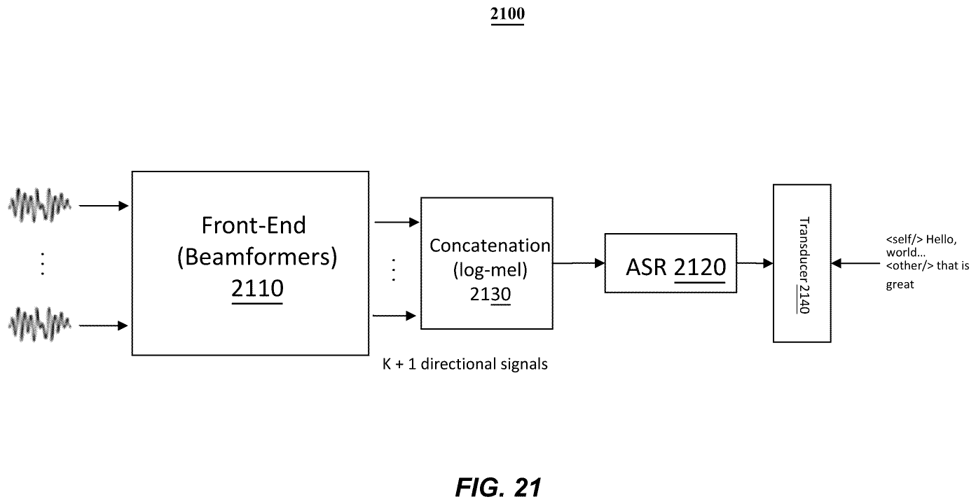

FIG. 21 illustrates an example architecture 2100 of directional speech recognition. It may comprise a front-end 2110 with multiple super-directive beamformers followed by an ASR module 2120. The ASR module 2120 may receive multiple input streams and may be trained via serialized output training [Refs. 13, 14] to detect speech from different directions. Unlike a standard single-channel ASR system, the multi-channel directional ASR system may utilize the differences in the directional outputs from the beamformers, allowing it to classify and separate speech signals arriving from different directions. The multi-channel directional ASR system may be an effective solution for addressing the technical challenge of classifying and separating speech signals arriving from different directions.

A straight-forward way may be to feed all microphones' raw audio into N parallel front-end 2110, hoping that the model may automatically learn to separate speech from different directions. This, however, may not work. The usual ASR feature extractors may remove phase information, but temporal differences may be the most important information for detecting direction of arrival. Instead, in the embodiments disclosed herein, we may pre-process the raw multi-channel audio by beamforming it for K steering directions around the smart-glasses device plus one in the speaker's mouth direction. As an example and not by way of limitation, the steering directions may be horizontal. However, the steering directions may be any suitable directions. For instance, we may find that users raise or lower their head to look at a transcription display, so that we may include tilted planes. In particular embodiments, generating the directional data may be based on a beamforming signal processing algorithm. These beamformers may use predetermined coefficients. The ASR feature extraction front-end 2110 may be then applied to these K+1 beamformed channels, the output of which may be concatenated by a concatenation module 2130 and fed into the ASR 2120 encoder neural network. This may map the problem from comparing phase differences to one of comparing magnitudes and feature characteristics derived from different steering directions.

As seen in FIG. 21, the N channels of raw audio data may be fed into the beamformer front-end 2110, which may then obtain the K+1 directional signals. We may then extract the usual log-Mel features for each beamformer direction and concatenate them together. This concatenated vector may constitute the input of the ASR 2120 encoder.

The beamformers used in the embodiments disclosed herein may include super-directive beamformers [Refs. 15, 16, 17]. A super-directive beamformer may be derived by maximizing the directivity factor, or DF. Specifically, the method may minimize the power output and apply a linear constraint in order to obtain an undistorted output signal. This optimization may maximize the directivity index. The K+1 beamformers may be predetermined. At runtime they may be realized via one-dimensional convolutions or via frequency-domain processing.

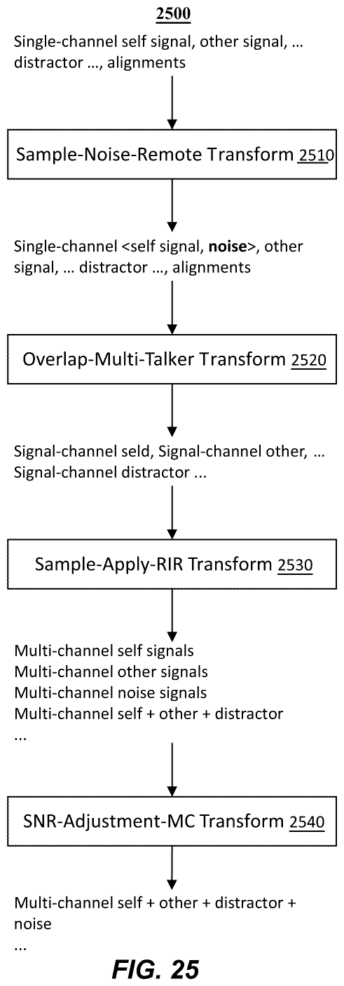

Our ASR model 2120 may be a Neural Transducer [Refs. 18, 19, 20, 21]. This well-known end-to-end ASR architecture may comprise three components: an encoder, a prediction network, and a joiner network. The goal of the transducer model 2140 is to produce a label sequence Y=(y₁, . . . , y_{L}) of length L, which may be a sequence of words or word-pieces, from an input sequence X=(x₁, . . . , x_{N}) of length N typically received in real time, typically a sequence of acoustic features like Mel-spectral energies. As an example and not by way of limitation, the sequence of words or word-pieces may be “<self/> Hello, world . . . <other/> that is great” as illustrated in FIG. 25. The encoder neural network may process the input sequence X and produce a sequence of acoustic representations, denoted as h^{enc}=(h₁^{enc}, . . . , h_{T}^{enc}), of length T, which might differ from N due to sub-sampling. The prediction neural network may act as an internal language model or decoder to generate a representation hᵤ^{dec}, where u represents the decoder state. Generally, u may depend on the previous output labels y_{0:l-1}=(y₀, . . . , yₗ₋₁), where y₀ corresponds to a start of sentence symbol, and l denotes the label index. Lastly, the joiner network may take the output representations from the encoder and prediction network as in-put and create the joint representation h_{t,u}^{joint}, where t denotes the encoder frame index.

What sets our model apart may be that we also incorporate serialized output training, or SOT [Refs. 13, 14]. This is a technique for detecting speaker changes-in our case between the wearer and a target speaker (other)—as well as for recognizing partially overlapping speech. In our SOT implementation, ground-truth transcriptions from multiple speakers may be sorted by the end times of all words. These are then interleaved, where at every speaker change, a special symbol may be inserted. This way, the model may learn to intersperse ASR transcripts with markup to indicate whether the speech came from self (the wearer of the glasses) or from other (the conversational partner opposite to the wearer). Note that compared to [Refs. 13, 14], the availability of multiple input channels as disclosed in the embodiments herein specifically aim to achieve performing this task significantly easier. Incorporating serialized output training when training the ASR model has shown to be an effective solution for addressing the technical challenge of detecting speaker changes between a wearer of the head-mounted device and a target speaker, as the serialized output training may enable the model to learn to intersperse ASR transcripts with markup to indicate whether the speech came from self (the wearer) or from other (the conversational partner opposite to the wearer).

More importantly, what sets our model apart may be also that we feed it with multiple beamformer outputs such that it may better distinguish speech from multiple directions, even when the spatial filtering (done by the beamformer) is not capable to remove speech from unwanted directions sufficiently. The ASR model may leverage the differences between the beamformer outputs to distinguish the target speech from the rest. This is different from other solutions, that typically may only use a single beamformer output steered towards a target speaker only. If multiple speakers are present, such systems may typically also recognize them one after another or in parallel by feeding different beamformer outputs to different ASR streams.

In particular embodiments, the first user may be in a conversation with one or more second users. Correspondingly, the client system 2038 may detect a change from the first user speaking to one of the one or more second users speaking. The client system 2038 may further determine one or more second target speech signals of the target speech signals subsequent to the detected change correspond to one or more second utterances from the one of the second users. Accordingly, the one or more transcriptions may comprise one or more second transcriptions for the one or more second target speech signals. In addition, the one or more of the transcriptions presented to the first user may comprise the one or more second transcriptions.

In particular embodiments, the first user may be in a conversation with one or more second users. The plurality of speech signals may comprise one or more first speech signals corresponding to one or more first utterances from the first user. The plurality of speech signals may comprise one or more second speech signals corresponding to one or more second utterances from one or more of the second users. In particular embodiments, one or more of the first speech signals may overlap with one or more of the second speech signals. The one or more target speech signals may comprise the one or more of the second speech signals overlapping with the one or more of the first speech signals.

Lastly, our model learns to suppress bystanders' speech: The ground truth for training the multi-channel ASR model may include only the transcripts of the self and other speakers. Speech of bystanders, that is, speech simulated from directions other than the target-speaker directions, may be included in the training data as well, but with empty transcripts. This way, the model may learn to ignore crosstalk. Experiments shows that this simple approach works with almost perfect accuracy.

Like [Ref. 18], the embodiments disclosed herein used the alignment-restricted RNN-T (AR-RNN-T) loss, which utilizes prior alignment information, such as forced alignment information from a traditional hybrid acoustic model, to limit the set of alignments to a valid subset. This may result in significant improvements of memory usage and training speed.

In particular embodiments, the multi-channel ASR system may comprise a plurality of multi-channel audio processing models (e.g., ASR, speech enhancement, etc.). Training these models may require a large number of training audio samples. In particular embodiments, data collection and simulation may be two different ways to obtain training data. While data collection may generate real data that leads to better models in practice, simulation may be a cheaper and more scalable solution, and may be the only feasible option.

As discussed previously, head-mounted devices (e.g., AR glasses) may have multiple microphones. To build the multi-channel ASR system based on these microphones, one may need large-scale data. However, such large-scale data may be difficult to collect, given the many variables and permutations involved, such as different microphone configurations for devices or differences in speaker/distractor direction, distance, and positions, etc. Thus, the embodiments disclosed herein created a multi-channel data simulation framework to generate such data.

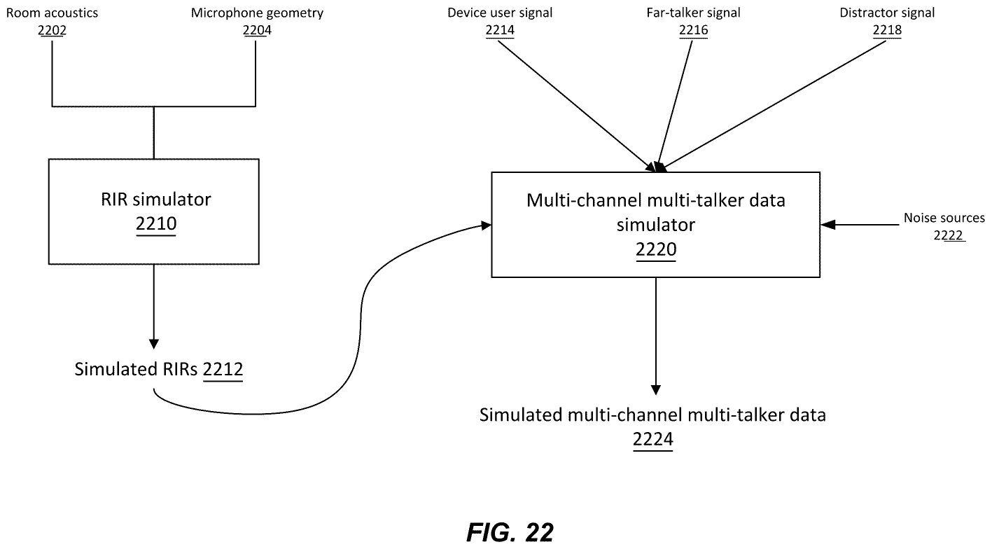

FIG. 22 illustrates an example data simulation diagram 2200. In particular embodiments, the simulation framework may comprise two major components: room impulse response (RIR) simulator 2210 and multi-channel multi-talker data simulator 2220. In particular embodiments, the RIR simulator 2210 may take room acoustics 2202 such as room size as input and all other things that are randomly generated. The process for each RIR simulator 2210 may be as follows. The RIR simulator 2210 may randomly sample a head position in the room. As an example and not by way of limitation, one may set a limit for z-axis to be in [0, 2] meters and get the whole microphone geometry information 604 in terms of mic-geometry. The RIR simulator 2210 may then randomly sample conversation partner (target person) sources, mouth locations (user themselves), distractor locations and noise sources in terms of a distribution. The distribution may be configurable by the corresponding arguments. The RIR simulator 2210 may then calculate a parameter in terms of room size. The RIR simulator 2210 may further compute RIRs and save simulated RIRs 2212. The simulated RIRs 2212 may be provided to the multi-channel multi-talker data simulator 2220.

In particular embodiments, the multi-channel multi-talker data simulator 2220 may additionally take device user signal 2214, far-talker signal 2216, distractor signal 2218, and noise sources 2222 to generate the simulated multi-channel multi-talker data 2224. As an example and not by way of limitation, the simulated multi-channel multi-talker data may comprise conversation audio, far-end audio reference, near-end audio reference, transcripts for the conversation, and meta information (e.g., source locations).

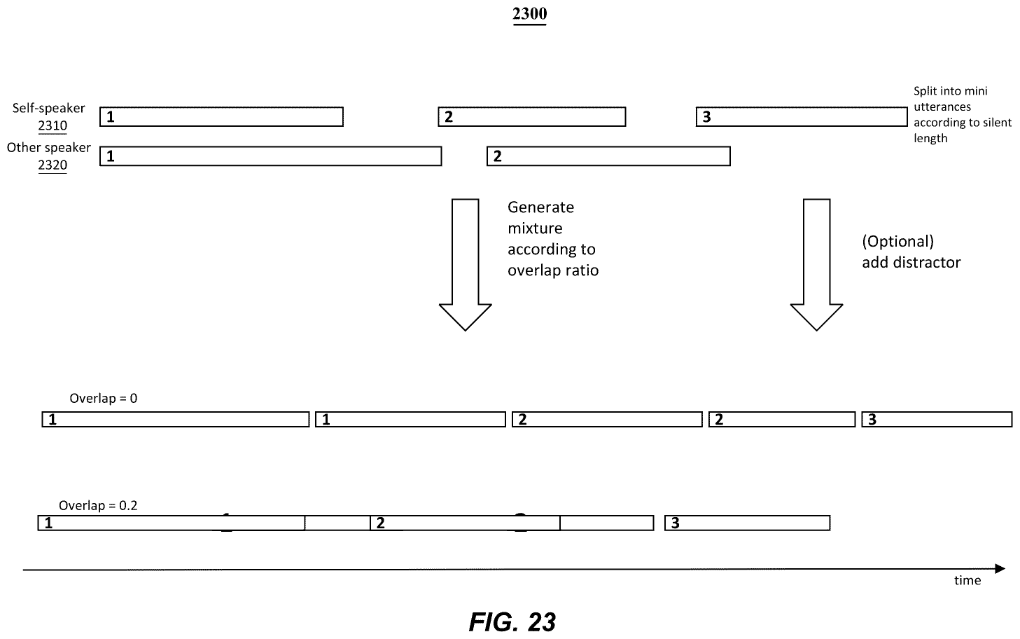

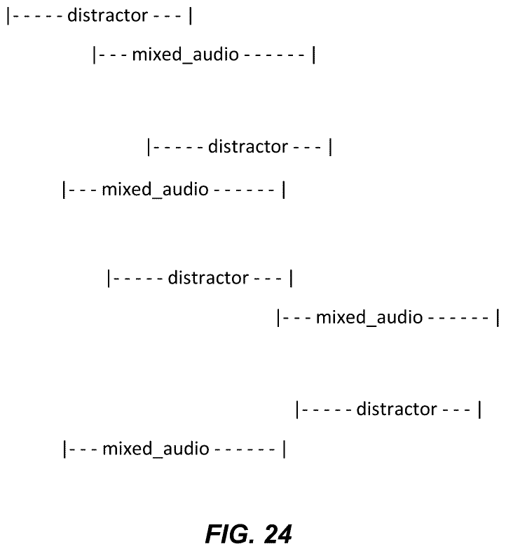

FIG. 23 illustrates an example process 2300 for multi-talker simulation. In the multi-talker simulation, one may assume there are 1-3 speakers as an example: self-speaker 2310, other speaker 2320 and distractor. One may first split one or more utterances into several mini utterances in terms of silent length. Then, we may mimic the conversation by concatenating these small segments. We may also provide an overlap ratio argument to control how we merge these segments. The multi-talker simulation may also take the transcription and word alignments from self/other as input, and then it may sort the output transcription and word alignments by end-time and insert a speaker change token “»” with an optional speaker tag when two consecutive words are from different speakers. In the live transcription scenario, we may use “»0” to represent SELF and “»1” to represent OTHER. Adding the distractor or not may be also configurable. In particular embodiments, the distractor may be added as a single audio that can overlap with the mixed audio. FIG. 24 illustrates examples of adding distractor to the simulation. In particular embodiments, one may simply ignore the transcription from the distractor.

In particular embodiments, the multi-channel data preparation pipeline may be implemented as a data augmentation transformer. This transformer may take in a configuration file that contains a list of front-end augmentation transformers. These front-end transformers may be composed in a pipeline, one after the another, to create a complete data preparation pipeline.

FIG. 25 illustrates an example pipeline 2500 for multi-channel data simulation. In particular embodiments, the multi-channel ASR system may use four transforms to generate the noisy multi-channel data. The embodiments disclosed herein assume that we have device user (SELF) signals, conversation partner (OTHER) signal, distractor signal and noise signal when simulating the conversation scenario. All of them may be single-channel signals.

In particular embodiments, sample-noise-remote transform 2510 may take a desired number of noise datasets and randomly samples noise signals to be added to the raw speech signal. The noise sources may be kept as separate arrays in a list next to the raw speech signal. Overlap-multi-talker transform 2520 may allow us to simulate multi talker scenarios for multi-channel speech. When simulating the multi-talker scenario, alignment information may be used to make speech sound naturally in terms of the phone or word at the boundary when cutting into small segments. Sample-apply-RIR transform 2530 may be used to sample the RIR and then apply the RIR to the clean and noise sources. It may accept multiple RIR datasets, which means one may use the RIR generated by RIR simulator and real RIR recording if we have. SNR-adjustment-MC transform 2540 may randomly select a target output level and SNR level and mix the noise sources with the raw speech signal to generate the final noisy mixture. It may also control if adding distractors and their volume.

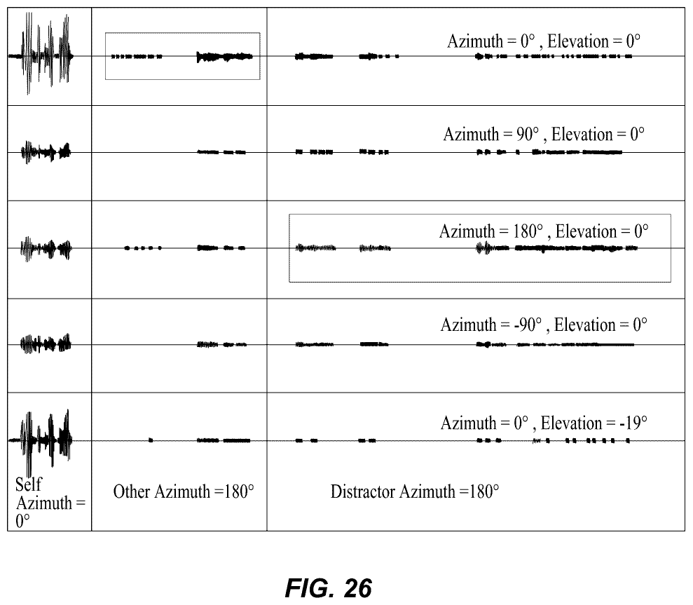

FIG. 26 illustrates an example simulation of 7-channel data associated with AR glasses. The embodiments disclosed herein may use a beamforming signal processing algorithm to verify the simulated data. The audio example in FIG. 26 was processed by the beamforming signal processing algorithm. The input of the beamforming signal processing algorithm may comprise 7 raw channel simulated audio and the output may comprise the 5 directional signals. For example, “Azimuth=0°, Elevation=00” means 12 o'clock direction. In FIG. 26, the other speaker is at 12 o'clock and the distractor is at 6 o'clock. It may be seen that the energy of the other and distractor are stronger in their corresponding direction than other directions.

The embodiments disclosed herein conducted experiments using two datasets: the open-source Librispeech corpus [Ref. 22], which consists of 960 hours of speech from audiobooks in the LibriVox project, and an in-house dataset of de-identified video data publicly shared one-line users. The training and evaluation sets of the in-house video data consist of 40 k and 50 hours, respectively. The experiments show that the multi-channel ASR system is effective in suppressing crosstalk.

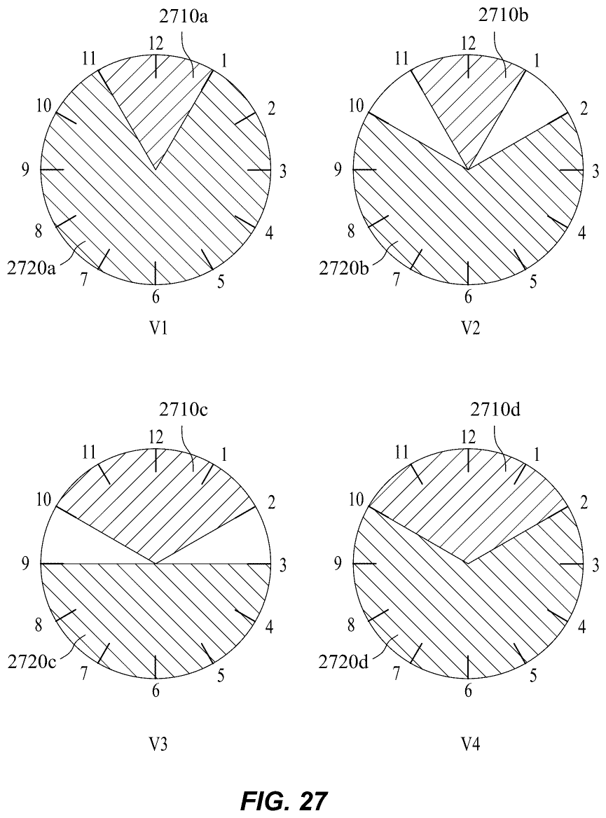

To simulate the training data, the embodiments disclosed herein generated 100,000 multichannel room impulse responses (RIRs) for rooms with sizes ranging from [Refs. 5, 5, 2] to [Refs. 10, 10, 6] meters. The embodiments disclosed herein used the geometry of the smart glasses illustrated in FIG. 24 to simulate multi-channel data, which has 7 microphones. The embodiments disclosed herein generated the multi-channel signals using image-source methods (ISM) [Ref. 23]. To better understand the impact of crosstalk on speech recognition, the embodiments disclosed herein generated four different training sets varying the locations of conversation partners and bystanders. FIG. 27 illustrates example training configuration of spatial positions of the conversation partner and bystander. Areas 2710a-2710d represent the partner areas, while areas 2720a-2720d represent the bystander areas. In the V1 configuration, the conversation partners are located between 1 and 11 o'clock (partner area 2710a), and bystanders are located between 1 and 11 o'clock (bystander area 2720a). The V2 and V3 settings leave a gap between the simulated partner and bystander directions. This is to study whether very close bystander and partner directions, such as in V1 and V4, might confuse the model during training due insufficient spatial resolution of the array.

The baseline systems used for performance comparison are a single-channel ASR system and an inter-channel phase differences (IPDs) system. The single-channel system may take the reference microphone signals (the first microphone) as input. IPDs [Refs. 24, 6] may be calculated as follows:

$${IPD}_{t , f}^{( n )} = ∠ {Y}_{t , f}^{{n}_{1}} - ∠ {Y}_{t , f}^{{n}_{2}}$$

where ∠Y_{t,f}ⁿ^{₁} denotes the angle of the complex representation ∠Y_{t,f}ⁿ^{₁} with t and f representing time and frequency and (n) is the index for the microphone pairs. The substation of the phase signals for a pair of microphone signal, including a target and a reference microphone, may eliminate phase variations inherent in source signals and hence allow room acoustic characteristics to be directly captured. The IPD features may be further augmented with magnitude spectra to leverage both spectral and spatial cues. For the short-term Fourier transform, we may use a Hanning windows of 16 ms and a frame shift of 10 ms. 6 pairs of microphones may be selected for IPD, which may be (0,1), (0,2), (0,3), (0,4), (0,5), (0,6). The total dimension of the input feature after concatenation may be 129*(7+6)=1677.

The baseline systems and the disclosed systems herein are using the same model architecture, except for a different input dimension. For each beamformer direction or raw microphone channel, we extracted 80-dimensional log-Mel filter-bank features. Input features from multiple directions or channels are concatenated. The encoder network's input layer projects this resulting concatenated feature vector to 128 dimensions. Then, four consecutive frames are stacked to form a 512-dimensional vector (reducing the sequence length by 4×). This is followed by 20 Emformer blocks [Ref. 25] with 8 attention heads and 2048-dimensional feed-forward layers. The RNN-T's prediction network contains three 512-dimensional LSTM layers with layer normalization and dropout. Lastly, the encoder and predictor outputs are both projected to 1024 dimensions and passed to an additive joiner network, which contains a linear layer with 4096 output BPE units.

We use an Adam optimizer with a tri-stage learning-rate scheduler. For LibriSpeech, models are trained for 120 epochs, with a base learning rate of 0.001, a warmup of 10,000 iterations, and forced annealing after 60 epochs. For experiments on large-scale in-house data, a similar model architecture and training hyper-parameters were used, with training for 15 epochs.

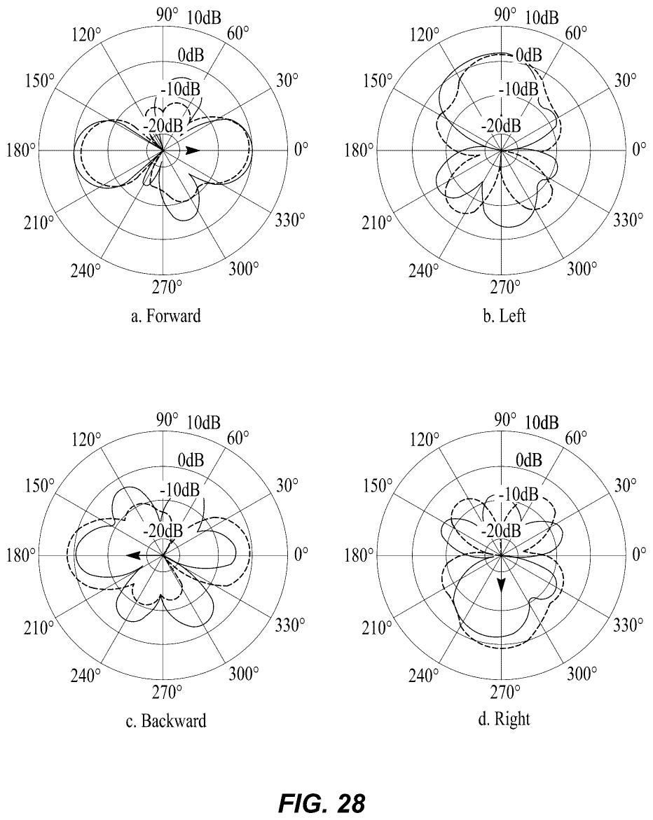

FIG. 28 illustrates example beam patterns of the super-directive beamformer at frequency of 2 kHz. The beam patterns are for 4 different directions, as indicated by the arrows. While beam patterns vary greatly, the gain is 1 in the desired looking directions.

The embodiments disclosed herein compare the disclosed multi-channel directional ASR system (referred to as “D-ASR”) with two baselines. The number of beams used in the ASR model, K+1, was represented by the numbers in brackets after “D-ASR”—[D-ASR-1], [D-ASR-5], and [D-ASR-13]. These numbers denote the number of beams used in the ASR model, with “1” indicating beamformed output at 12 o'clock direction, “5” representing 4 beams for the horizontal plane (at 90-degree increments) plus the self-beam (to the wearer's mouth), and “13” representing 12 beams for the horizontal plane at 30-degree increments plus the self-beam.

Unless otherwise noted, word error rates (WERs) consider speaker attribution by counting self and other tags like words. A missing or incorrect speaker tag counts as one error.

First, Table 1 shows that the single beamformed input system (D-ASR-1) outperforms the single-channel reference-microphone system (SC-Raw mic) in most cases, by significant margins. In other words, using a single directional signal may already provide valuable spatial cues. Compared with the strong IPD baseline systems, which uses explicit spatial cues, our proposed D-ASR with 5 directional signals consistently achieves better performance, demonstrating the effectiveness of our approach.

TABLE 1
WERs (%) for the proposed and baseline systems on Librispeech. C1: bystanders
are located at 3 to 5 o'clock and 7 to 9 o'clock. C2: bystanders are
located at 10 o'clock and 2 o'clock. C3: bystanders are located at 5
o'clock and 7 o'clock. Annotation is same to other tables. The overlap ratio is 0%.

| | Partner [12] | | | Partner [11/1] | | | Partner [10/2] | | |
|---|---|---|---|---|---|---|---|---|---|
| Model | C1 | C2 | C3 | C1 | C2 | C3 | C1 | C2 | C3 |
| D-ASR-5 (V1) | 12.0 | 12.9 | 11.9 | 14.7 | 15.2 | 14.9 | 52.5 | 53.2 | 52.4 |
| D-ASR-5 (V2) | 12.0 | 13.8 | 12.0 | 14.7 | 16.1 | 14.7 | 52.7 | 53.9 | 52.6 |
| D-ASR-5 (V3) | 12.0 | 49.8 | 12.0 | 14.2 | 51.9 | 13.9 | 14.5 | 51.9 | 14.5 |
| D-ASR-5 (V4) | 12.0 | 36.8 | 12.0 | 14.2 | 38.5 | 14.1 | 15.4 | 43.8 | 15.2 |
| IPD (V1) | 15.0 | 15.7 | 14.7 | 15.9 | 16.4 | 16.1 | 53.8 | 54.3 | 53.8 |
| IPD (V2) | 14.9 | 16.8 | 14.7 | 15.2 | 16.8 | 15.3 | 53.7 | 54.8 | 53.7 |
| IPD (V3) | 15.1 | 55.5 | 14.9 | 15.3 | 54.6 | 15.1 | 15.6 | 54.9 | 15.7 |
| D-ASR-1 (V1) | 16.5 | 26.2 | 17.1 | 20.6 | 30.2 | 21.8 | 29.0 | 39.5 | 30.1 |
| D-ASR-1 (V2) | 17.2 | 29.0 | 16.3 | 19.7 | 31.5 | 20.6 | 28.3 | 41.4 | 28.7 |
| D-ASR-1 (V3) | 18.3 | 41.1 | 16.7 | 21.7 | 43.4 | 20.0 | 25.1 | 46.6 | 22.9 |
| SC-Raw mic (V1) | 41.3 | 42.1 | 40.9 | 40.9 | 41.6 | 42.1 | 41.3 | 41.1 | 40.9 |
| SC-Raw mic (V2) | 40.9 | 42.2 | 40.4 | 40.8 | 40.9 | 41.3 | 40.5 | 40.9 | 40.7 |
| SC-Raw mic (V3) | 41.5 | 43.0 | 40.8 | 42.0 | 42.3 | 42.4 | 41.8 | 41.9 | 41.3 |

The embodiments disclosed herein also compare training conditions for different bystander locations. D-ASR may be sensitive to unseen test conditions, similar to IPD-based methods. As an example and not by way of limitation, the performance of D-ASR-5 with V3 training data drops significantly for the partner at 12 o'clock when bystanders are nearby the 10 and 2 o'clock directions (C2). In the V3 training data, bystanders are only located at 3 to 9 o'clock, so C2 is an unseen condition. In contrast, the V4 training condition also includes bystanders close to the 10 and 2 o'clock directions, which results in improvements over V3, although the discrimination between bystander and partner is very narrow at this location.

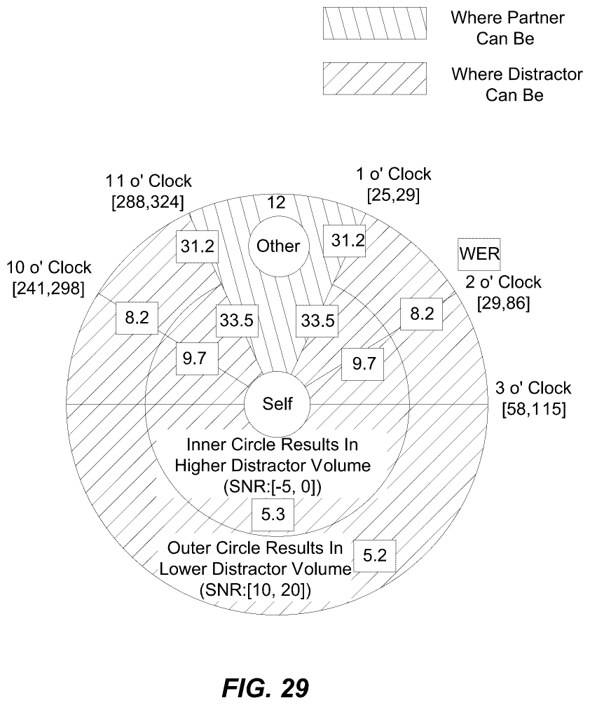

FIG. 29 illustrates an example chart showing our best results. The numbers are word-error rates (WER) for speakers positioned at the respective positions in space. For example, the word-error rate (WER) for speakers positioned between 3 o'clock to 9 o'clock with respect to a user of smart glasses can be as low as 5.2. The WER for speakers positioned between 9 o'clock and 10 o'clock with respect to the user may range from 8.2 to 9.7 depending on how far the speakers are from the user. This is similar for speakers positioned between 2 o'clock and 3 o'clock. The WER for speakers positioned between 10 o'clock and 2 o'clock may be higher, e.g., between 31.2 and 33.5. It may be seen that suppression for distractors from 3 o'clock to 9 o'clock is almost perfect, regardless of their volume. For distractors in the upper circle, we may begin to see accuracy impact, i.e., the closer the distractor is to OTHER the worse the WER (predominantly due to insertions). Volume may also begin to matter, though not as important as position.

The embodiments disclosed herein conduct ablation studies to measure the impact of the number of beams used for model training. Here, we fixed the model training using V4 configuration. Table 2 contains the results for Librispeech comparing four such systems. Comparing D-ASR-5 with D-ASR-1, we see that more beams may reduce the WER significantly on the conditions that bystanders are far away from the partners (C1 and C3). When bystanders are close to the partner (C2), D-ASR-1 performs somewhat better, likely because the spatial resolution of the beamforming may be not sufficient to resolve bystander and partner directions that are very close. Similar to using 13 beams, we also see an improvement in the C1 and C3 conditions. Applying volume perturbation further boosts ASR performance, which may teach the model to not rely on amplitude differences to discriminate speaker directions but on other special and spectral cues instead.

TABLE 2
The impact of the different number beams for the directional
speech recognition. The overlap ratio is 0%.

| | Partner [1/11] | | |
|---|---|---|---|
| Model | C1 | C2 | C3 |
| D-ASR-1 (V4) | 21.1 | 38.5 | 19.7 |
| D-ASR-5 (V4) | 14.2 | 38.5 | 14.1 |
| D-ASR-13 (V4) | 13.4 | 41.8 | 13.5 |
| D-ASR-13 (V4) + | 13.3 | 36.7 | 13.2 |
| vol. Perturb | | | |

Next, the embodiments disclosed herein investigate the impact of performance under different overlap conditions. As presented in Table 3, we initially validated the performance of our D-ASR model under ideal conditions, i.e., no noise and crosstalk, in which it achieved around 5.5% on Librispeech test-clean dataset in all cases. At 0% overlap, the crosstalk speech increases the total amount of speech by approximately 50%-undesired speech that should not be recognized (with crosstalk disabled, audio length still increases by 50%, but of silence or noise). The single-channel model only suppresses some lower-volume crosstalk, while it decodes its majority as insertion errors, pushing the WERs to over 40%. Whereas the D-ASR model suppresses crosstalk almost perfectly at the lower overlap ratios: At 0% overlap, the WER increases from 12.2 to 12.8%, 0.6% absolute, corresponds to only about 1.2% of the crosstalk audio. Accuracy degrades a bit more at 100% overlap, when bystander speech effectively becomes background noise.

TABLE 3
WER (%) at varying ratios of overlap
of cross-talk with self/other speech.

| | Over- | | Cross- | Partner [1/11] | |
|---|---|---|---|---|---|
| Model | lap | Noise | talk | C1 | C3 |
| SC-Raw (V1) | 0% | Y | Y | 40.9 | 42.1 |
| D-ASR-13 (V4) | 0% | N | N | 5.5 | 5.5 |
| | | Y | N | 12.2 | 12.5 |
| | | Y | Y | 12.8 | 13.0 |
| D-ASR-13 (V4) | 50% | N | N | 5.5 | 5.5 |
| | | Y | N | 13.2 | 12.9 |
| | | Y | Y | 14.2 | 14.0 |
| D-ASR-13 (V4) | 100% | N | N | 5.6 | 5.6 |
| | | Y | N | 14.1 | 14.3 |
| | | Y | Y | 16.0 | 15.9 |

The embodiments disclosed herein further use the D-ASR-13 (v4) 0% no crosstalk C3 configuration to look at speaker-attribution accuracy. We split ASR output/ground truth by speaker tags. Now, words attributed to the wrong speaker become insertions or deletions. After this split, the resulting WER increases from 12.5% to 12.7%. Hence, speaker attribution may work almost perfectly as well.

TABLE 4
WER (%) on our in-house data, at overlap ratio 0%

| | Over- | | Cross- | Partner [1/11] | |
|---|---|---|---|---|---|
| Model | lap | Noise | talk | C1 | C3 |
| SC-Raw (V1) | 0% | Y | Y | 40.9 | 42.1 |
| D-ASR-13 (V4) | 0% | N | N | 5.5 | 5.5 |
| | | Y | N | 12.2 | 12.5 |
| | | Y | Y | 12.8 | 13.0 |
| D-ASR-13 (V4) | 50% | N | N | 5.5 | 5.5 |
| | | Y | N | 13.2 | 12.9 |
| | | Y | Y | 14.2 | 14.0 |
| D-ASR-13 (V4) | 100% | N | N | 5.6 | 5.6 |
| | | Y | N | 14.1 | 14.3 |
| | | Y | Y | 16.0 | 15.9 |

Finally, the embodiments disclosed herein conduct experiments on our large-scale in-house dataset. As shown in Table 4, we observed similar tendency on the in-house data. The disclosed multi-channel directional ASR model consistently outperforms the IPD baseline system in all cases.

This disclosure disclosed an ASR modeling approach that uses multi-channel directional input. Besides the usual SNR improvement, multiple audio channels corresponding to multiple beamformer directions may be utilized simultaneously by a single ASR model to distinguish and recognize multiple speakers from different directions and to reliably suppress crosstalk. With this disclosure, our RNN-T based model may be trained to annotate speaker changes and ignore bystander speech in an end-to-end fashion. Comprehensive experiments were conducted for conversational ASR with smart glasses using different bystander and conversational partner conditions. The embodiments disclosed herein have demonstrated that the disclosed multi-channel directional ASR system may disambiguate the wearer's from the conversation partner's speech and suppress bystander speech (from undesired directions) almost perfectly.

### REFERENCES

The following list of references correspond to the citations above:
[1]J. Heymann, L. Drude, C. Boeddeker, P. Hanebrink, and R. Haeb-Umbach, “Beamnet: End-to-end training of a beamformer-supported multi-channel ASR system,” in 2017 IEEE International Conference on Acoustics, Speech and Signal Processing (ICASSP). IEEE, 2017, pp. 5325-5329.
[2] X. Chang, W. Zhang, Y. Qian, J. Le Roux, and S. Watanabe, “End-to-end multi-speaker speech recognition with transformer,” in ICASSP 2020-2020 IEEE International Conference on Acoustics, Speech and Signal Processing (ICASSP). IEEE, 2020, pp. 222034-222038.
[3]T. Ochiai, S. Watanabe, T. Hori, and J. R. Hershey, “Multichannel end-to-end speech recognition,” in International conference on machine learning. PMLR, 2017, pp. 2632-2641.
[4] X. Chang, W. Zhang, Y. Qian, J. Le Roux, and S. Watanabe, “MIMO-speech: End-to-end multi-channel multi-speaker speech recognition,” in 2019 IEEE Automatic Speech Recognition and Understanding Workshop (ASRU). IEEE, 2019, pp. 237-244.
[5] A. S. Subramanian, C. Weng, S. Watanabe, M. Yu, Y. Xu, S.-X. Zhang, and D. Yu, “Directional ASR: A new paradigm for e2e multi-speaker speech recognition with source localization,” in ICASSP 2021-2021 IEEE International Conference on Acoustics, Speech and Signal Processing (ICASSP). IEEE, 2021, pp. 8433-8437.
[6] Z.-Q. Wang, J. Le Roux, and J. R. Hershey, “Multi-channel deep clustering: Discriminative spectral and spatial embeddings for speaker-independent speech separation,” in 2018 IEEE International Conference on Acoustics, Speech and Signal Processing (ICASSP). IEEE, 2018, pp. 1-5.
[7]Y. Shao, S.-X. Zhang, and D. Yu, “Multi-channel multi-speaker ASR using 3D spatial feature,” in ICASSP 2022-2022 IEEE International Conference on Acoustics, Speech and Signal Processing (ICASSP). IEEE, 2022, pp. 6067-6071.
[8]Z. Chen, X. Xiao, T. Yoshioka, H. Erdogan, J. Li, and Y. Gong, “Multi-channel overlapped speech recognition with location guided speech extraction network,” in 2018 IEEE Spoken Language Technology Workshop (SLT). IEEE, 2018, pp. 558-565.
[9]S. Settle, J. Le Roux, T. Hori, S. Watanabe, and J. R. Hershey, “End-to-end multi-speaker speech recognition,” in 2018 IEEE international conference on acoustics, speech and signal processing (ICASSP). IEEE, 2018, pp. 4819-4823.
[10]Z.-Q. Wang, P. Wang, and D. Wang, “Complex spectral mapping for single- and multi-channel speech enhancement and robust ASR,” IEEE/ACM transactions on audio, speech, and language processing, vol. 28, pp. 1778-1787, 2020.
[11]T. Yoshioka, H. Erdogan, Z. Chen, and F. Alleva, “Multi-microphone neural speech separation for far-field multi-talker speech recognition,” in 2018 IEEE International Conference on Acoustics, Speech and Signal Processing (ICASSP). IEEE, 2018, pp. 5739-5743.
[12] https://about.meta.com/realitylabs/projectaria/.
[13]N. Kanda, J. Wu, Y. Wu, X. Xiao, Z. Meng, X. Wang, Y. Gaur, Z. Chen, J. Li, and T. Yoshioka, “Streaming multi-talker ASR with token-level serialized output training,” arXiv preprint arXiv:2202.00842, 2022.
[14]X. Chang, N. Moritz, T. Hori, S. Watanabe, and J. L. Roux, “Extended graph temporal classification for multi-speaker end-to-end ASR,” in 2022 IEEE International Conference on Acoustics, Speech and Signal Processing (ICASSP), 2022, pp. 7322-7326.
[15]G. W. Elko, S. Gay, and J. Benesty, “Superdirectional microphone arrays,” KLUWER INTERNATIONAL SERIES IN ENGINEERING AND COMPUTER SCIENCE, pp. 181-238, 2000.
[16]G. Huang, J. Benesty, and J. Chen, “Superdirective beamforming based on the krylov matrix,” IEEE/ACM Transactions on Audio, Speech, and Language Processing, vol. 24, no. 12, pp. 2531-2543, 2016.
[17]S. Doclo and M. Moonen, “Superdirective beamforming robust against microphone mismatch,” IEEE Transactions on Audio, Speech, and Language Processing, vol. 15, no. 2, pp. 617-631, 2007.
[18]J. Mahadeokar, Y. Shangguan, D. Le, G. Keren, H. Su, T. Le, C.-F. Yeh, C.

Fuegen, and M. L. Seltzer, “Alignment restricted streaming recurrent neural network transducer,” in 2021 IEEE Spoken Language Technology Workshop (SLT). IEEE, 2021, pp. 52-59.
[19]N. Moritz, F. Seide, D. Le, J. Mahadeokar, and C. Fuegen, “An investigation of monotonic transducers for large-scale automatic speech recognition,” arXiv preprint arXiv:2204.08858, 2022.
[20]T. N. Sainath, Y. He, B. Li, A. Narayanan, R. Pang, A. Bruguier, S.-y. Chang, W. Li, R. Alvarez, Z. Chen et al., “A streaming on-device end-to-end model surpassing server-side conventional model quality and latency,” in ICASSP 2020-2020 IEEE International Conference on Acoustics, Speech and Signal Processing (ICASSP). IEEE, 2020, pp. 6059-6063.
[21]J. Li, R. Zhao, Z. Meng, Y. Liu, W. Wei, S. Parthasarathy, V. Mazalov, Z.

Wang, L. He, S. Zhao et al., “Developing rnn-t models surpassing high-performance hybrid models with customization capability,” arXiv preprint arXiv:2007.15188, 2020.
[22]V. Panayotov, G. Chen, D. Povey, and S. Khudanpur, “Lib-riSpeech: An ASR corpus based on public domain audio books,” in 2015 IEEE International Conference on Acoustics, Speech and Signal Processing (ICASSP), April 2015, pp. 21206-5210.
[23]E. A. Lehmann and A. M. Johansson, “Prediction of energy decay in room impulse responses simulated with an image-source model,” The Journal of the Acoustical Society of America, vol. 124, no. 1, pp. 269-277, 2008.
[24]F. Bahmaninezhad, J. Wu, R. Gu, S.-X. Zhang, Y. Xu, M. Yu, and D. Yu, “A comprehensive study of speech separation: Spectrogram vs waveform separation,” arXiv preprint arXiv:1905.07497, 2019.
[25]Y. Shi, Y. Wang, C. Wu, C.-F. Yeh, J. Chan, F. Zhang, D. Le, and M. Seltzer, “Emformer: Efficient memory transformer based acoustic model for low latency streaming speech recognition,” in ICASSP 2021-2021 IEEE International Conference on Acoustics, Speech and Signal Processing (ICASSP). IEEE, 2021, pp. 6783-6787.

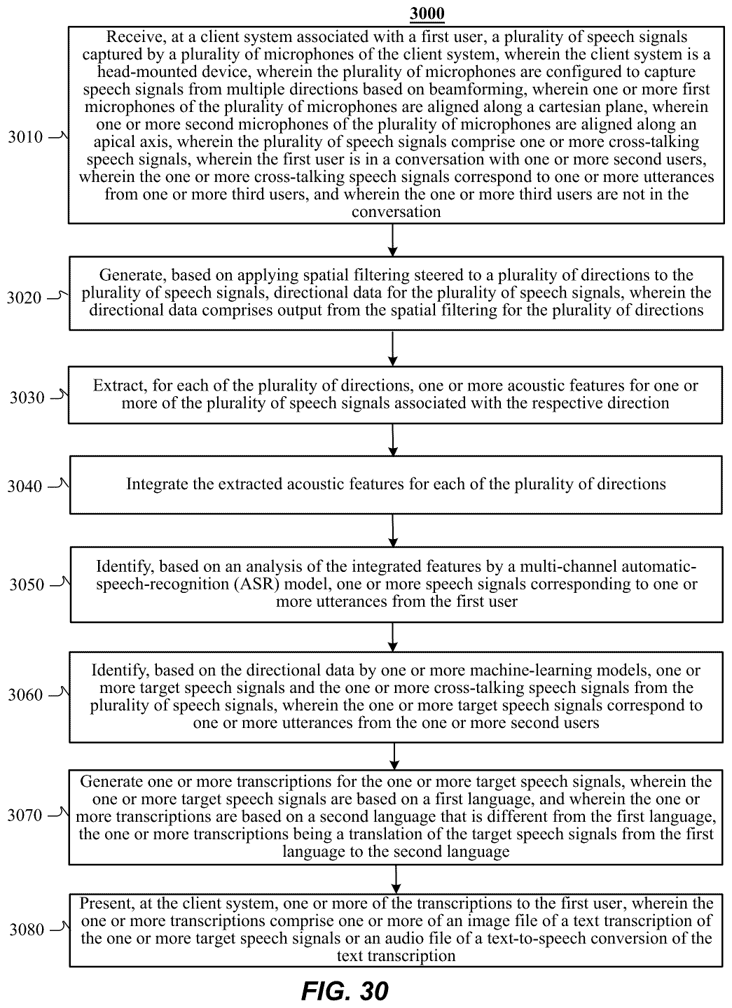

FIG. 30 illustrates an example method 3000 for suppressing crosstalk. The method may begin at step 3010, where one or more computing systems may receive, at a client system 3030 associated with a first user, a plurality of speech signals captured by a plurality of microphones of the client system 3030, wherein the client system 3030 is a head-mounted device, wherein the plurality of microphones are configured to capture speech signals from multiple directions based on beamforming, wherein one or more first microphones of the plurality of microphones are aligned along a cartesian plane, wherein one or more second microphones of the plurality of microphones are aligned along an apical axis, wherein the plurality of speech signals comprise one or more cross-talking speech signals, wherein the first user is in a conversation with one or more second users, wherein the one or more cross-talking speech signals correspond to one or more utterances from one or more third users, and wherein the one or more third users are not in the conversation. At step 3020, the one or more computing systems may generate, based on applying spatial filtering steered to a plurality of directions to the plurality of speech signals, directional data for the plurality of speech signals, wherein the directional data comprises output from the spatial filtering for the plurality of directions. At step 3030, the one or more computing systems may extract, for each of the plurality of directions, one or more acoustic features for one or more of the plurality of speech signals associated with the respective direction. At step 3040, the one or more computing systems may integrate the extracted acoustic features for each of the plurality of directions. At step 3050, the one or more computing systems may identify, based on an analysis of the integrated features by a multi-channel automatic-speech-recognition (ASR) model, one or more speech signals corresponding to one or more utterances from the first user. At step 3060, the one or more computing systems may identify, based on the directional data by one or more machine-learning models, one or more target speech signals and the one or more cross-talking speech signals from the plurality of speech signals, wherein the one or more target speech signals correspond to one or more utterances from the one or more second users. At step 3070, the one or more computing systems may generate one or more transcriptions for the one or more target speech signals, wherein the one or more target speech signals are based on a first language, and wherein the one or more transcriptions are based on a second language that is different from the first language, the one or more transcriptions being a translation of the target speech signals from the first language to the second language. At step 3080, the one or more computing systems may present, at the client system, one or more of the transcriptions to the first user, wherein the one or more transcriptions comprise one or more of an image file of a text transcription of the one or more target speech signals or an audio file of a text-to-speech conversion of the text transcription. Particular embodiments may repeat one or more steps of the method of FIG. 30, where appropriate. Although this disclosure describes and illustrates particular steps of the method of FIG. 30 as occurring in a particular order, this disclosure contemplates any suitable steps of the method of FIG. 30 occurring in any suitable order. Moreover, although this disclosure describes and illustrates an example method for suppressing crosstalk including the particular steps of the method of FIG. 30, this disclosure contemplates any suitable method for suppressing crosstalk including any suitable steps, which may include all, some, or none of the steps of the method of FIG. 30, where appropriate. Furthermore, although this disclosure describes and illustrates particular components, devices, or systems carrying out particular steps of the method of FIG. 30, this disclosure contemplates any suitable combination of any suitable components, devices, or systems carrying out any suitable steps of the method of FIG. 30.

### Systems and Methods

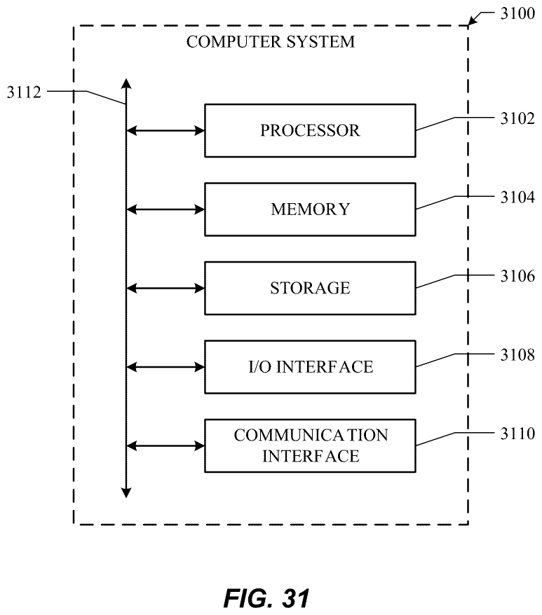

FIG. 31 illustrates an example computer system 3100. In particular embodiments, one or more computer systems 3100 perform one or more steps of one or more methods described or illustrated herein. In particular embodiments, one or more computer systems 3100 provide functionality described or illustrated herein. In particular embodiments, software running on one or more computer systems 3100 performs one or more steps of one or more methods described or illustrated herein or provides functionality described or illustrated herein. Particular embodiments include one or more portions of one or more computer systems 3100. Herein, reference to a computer system may encompass a computing device, and vice versa, where appropriate. Moreover, reference to a computer system may encompass one or more computer systems, where appropriate.

This disclosure contemplates any suitable number of computer systems 3100. This disclosure contemplates computer system 3100 taking any suitable physical form. As example and not by way of limitation, computer system 3100 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, or a combination of two or more of these. Where appropriate, computer system 3100 may include one or more computer systems 3100; be unitary or distributed; span multiple locations; span multiple machines; span multiple data centers; or reside in a cloud, which may include one or more cloud components in one or more networks. Where appropriate, one or more computer systems 3100 may perform without substantial spatial or temporal limitation one or more steps of one or more methods described or illustrated herein. As an example and not by way of limitation, one or more computer systems 3100 may perform in real time or in batch mode one or more steps of one or more methods described or illustrated herein. One or more computer systems 3100 may perform at different times or at different locations one or more steps of one or more methods described or illustrated herein, where appropriate.

In particular embodiments, computer system 3100 includes a processor 3102, memory 3104, storage 3106, an input/output (I/O) interface 3108, a communication interface 3110, and a bus 3112. Although this disclosure describes and illustrates a particular computer system having a particular number of particular components in a particular arrangement, this disclosure contemplates any suitable computer system having any suitable number of any suitable components in any suitable arrangement.

In particular embodiments, processor 3102 includes hardware for executing instructions, such as those making up a computer program. As an example and not by way of limitation, to execute instructions, processor 3102 may retrieve (or fetch) the instructions from an internal register, an internal cache, memory 3104, or storage 3106; decode and execute them; and then write one or more results to an internal register, an internal cache, memory 3104, or storage 3106. In particular embodiments, processor 3102 may include one or more internal caches for data, instructions, or addresses. This disclosure contemplates processor 3102 including any suitable number of any suitable internal caches, where appropriate. As an example and not by way of limitation, processor 3102 may include one or more instruction caches, one or more data caches, and one or more translation lookaside buffers (TLBs). Instructions in the instruction caches may be copies of instructions in memory 3104 or storage 3106, and the instruction caches may speed up retrieval of those instructions by processor 3102. Data in the data caches may be copies of data in memory 3104 or storage 3106 for instructions executing at processor 3102 to operate on; the results of previous instructions executed at processor 3102 for access by subsequent instructions executing at processor 3102 or for writing to memory 3104 or storage 3106; or other suitable data. The data caches may speed up read or write operations by processor 3102. The TLBs may speed up virtual-address translation for processor 3102. In particular embodiments, processor 3102 may include one or more internal registers for data, instructions, or addresses. This disclosure contemplates processor 3102 including any suitable number of any suitable internal registers, where appropriate. Where appropriate, processor 3102 may include one or more arithmetic logic units (ALUs); be a multi-core processor; or include one or more processors 3102. Although this disclosure describes and illustrates a particular processor, this disclosure contemplates any suitable processor.

In particular embodiments, memory 3104 includes main memory for storing instructions for processor 3102 to execute or data for processor 3102 to operate on. As an example and not by way of limitation, computer system 3100 may load instructions from storage 3106 or another source (such as, for example, another computer system 3100) to memory 3104. Processor 3102 may then load the instructions from memory 3104 to an internal register or internal cache. To execute the instructions, processor 3102 may retrieve the instructions from the internal register or internal cache and decode them. During or after execution of the instructions, processor 3102 may write one or more results (which may be intermediate or final results) to the internal register or internal cache. Processor 3102 may then write one or more of those results to memory 3104. In particular embodiments, processor 3102 executes only instructions in one or more internal registers or internal caches or in memory 3104 (as opposed to storage 3106 or elsewhere) and operates only on data in one or more internal registers or internal caches or in memory 3104 (as opposed to storage 3106 or elsewhere). One or more memory buses (which may each include an address bus and a data bus) may couple processor 3102 to memory 3104. Bus 3112 may include one or more memory buses, as described below. In particular embodiments, one or more memory management units (MMUs) reside between processor 3102 and memory 3104 and facilitate accesses to memory 3104 requested by processor 3102. In particular embodiments, memory 3104 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 3104 may include one or more memories 3104, where appropriate. Although this disclosure describes and illustrates particular memory, this disclosure contemplates any suitable memory.

In particular embodiments, storage 3106 includes mass storage for data or instructions. As an example and not by way of limitation, storage 3106 may include a hard disk drive (HDD), a floppy disk drive, flash memory, an optical disc, a magneto-optical disc, magnetic tape, or a Universal Serial Bus (USB) drive or a combination of two or more of these. Storage 3106 may include removable or non-removable (or fixed) media, where appropriate. Storage 3106 may be internal or external to computer system 3100, where appropriate. In particular embodiments, storage 3106 is non-volatile, solid-state memory. In particular embodiments, storage 3106 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 3106 taking any suitable physical form. Storage 20506 may include one or more storage control units facilitating communication between processor 3102 and storage 3106, where appropriate. Where appropriate, storage 3106 may include one or more storages 3106. Although this disclosure describes and illustrates particular storage, this disclosure contemplates any suitable storage.

In particular embodiments, I/O interface 3108 includes hardware, software, or both, providing one or more interfaces for communication between computer system 3100 and one or more I/O devices. Computer system 3100 may include one or more of these I/O devices, where appropriate. One or more of these I/O devices may enable communication between a person and computer system 3100. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 3108 for them. Where appropriate, I/O interface 3108 may include one or more device or software drivers enabling processor 3102 to drive one or more of these I/O devices. I/O interface 3108 may include one or more I/O interfaces 3108, where appropriate. Although this disclosure describes and illustrates a particular I/O interface, this disclosure contemplates any suitable I/O interface.

In particular embodiments, communication interface 3110 includes hardware, software, or both providing one or more interfaces for communication (such as, for example, packet-based communication) between computer system 3100 and one or more other computer systems 3100 or one or more networks. As an example and not by way of limitation, communication interface 3110 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 3110 for it. As an example and not byway of limitation, computer system 3100 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 3100 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. Computer system 3100 may include any suitable communication interface 3110 for any of these networks, where appropriate. Communication interface 3110 may include one or more communication interfaces 3110, where appropriate. Although this disclosure describes and illustrates a particular communication interface, this disclosure contemplates any suitable communication interface.

In particular embodiments, bus 2112 includes hardware, software, or both coupling components of computer system 3100 to each other. As an example and not by way of limitation, bus 3112 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 3112 may include one or more buses 3112, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards ordrives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

### Privacy

In particular embodiments, one or more objects (e.g., content or other types of objects) of a computing system may be associated with one or more privacy settings. The one or more objects may be stored on or otherwise associated with any suitable computing system or application, such as, for example, a social-networking system 2060, an AR/VR system 2030, an AR/VR platform 2040, a third-party system 2070, a social-networking application 2034, an AR/VR application 2036, a messaging application, a photo-sharing application, or any other suitable computing system or application. Although the examples discussed herein are in the context of an online social network, these privacy settings may be applied to any other suitable computing system. Privacy settings (or “access settings”) for an object may be stored in any suitable manner, such as, for example, in association with the object, in an index on an authorization server, in another suitable manner, or any suitable combination thereof. A privacy setting for an object may specify how the object (or particular information associated with the object) can be accessed, stored, or otherwise used (e.g., viewed, shared, modified, copied, executed, surfaced, or identified) within the online social network. When privacy settings for an object allow a particular user or other entity to access that object, the object may be described as being “visible” with respect to that user or other entity. As an example and not by way of limitation, a user of the online social network may specify privacy settings for a user-profile page that identify a set of users that may access work-experience information on the user-profile page, thus excluding other users from accessing that information.

In particular embodiments, privacy settings for an object may specify a “blocked list” of users or other entities that should not be allowed to access certain information associated with the object. In particular embodiments, the blocked list may include third-party entities. The blocked list may specify one or more users or entities for which an object is not visible. As an example and not by way of limitation, a user may specify a set of users who may not access photo albums associated with the user, thus excluding those users from accessing the photo albums (while also possibly allowing certain users not within the specified set of users to access the photo albums). In particular embodiments, privacy settings may be associated with particular social-graph elements. Privacy settings of a social-graph element, such as a node or an edge, may specify how the social-graph element, information associated with the social-graph element, or objects associated with the social-graph element can be accessed using the online social network. As an example and not by way of limitation, a particular photo may have a privacy setting specifying that the photo may be accessed only by users tagged in the photo and friends of the users tagged in the photo. In particular embodiments, privacy settings may allow users to opt in to or opt out of having their content, information, or actions stored/logged by the social-networking system 2060 or VR platform 2040 or shared with other systems (e.g., a third-party system 2070). Although this disclosure describes using particular privacy settings in a particular manner, this disclosure contemplates using any suitable privacy settings in any suitable manner.

In particular embodiments, the social-networking system 2060 or AR/VR platform 2040 may present a “privacy wizard” (e.g., within a webpage, a module, one or more dialog boxes, or any other suitable interface) to the first user to assist the first user in specifying one or more privacy settings. The privacy wizard may display instructions, suitable privacy-related information, current privacy settings, one or more input fields for accepting one or more inputs from the first user specifying a change or confirmation of privacy settings, or any suitable combination thereof. In particular embodiments, the social-networking system 2060 or AR/VR platform 2040 may offer a “dashboard” functionality to the first user that may display, to the first user, current privacy settings of the first user. The dashboard functionality may be displayed to the first user at any appropriate time (e.g., following an input from the first user summoning the dashboard functionality, following the occurrence of a particular event or trigger action). The dashboard functionality may allow the first user to modify one or more of the first user's current privacy settings at any time, in any suitable manner (e.g., redirecting the first user to the privacy wizard).

Privacy settings associated with an object may specify any suitable granularity of permitted access or denial of access. As an example and not by way of limitation, access or denial of access may be specified for particular users (e.g., only me, my roommates, my boss), users within a particular degree-of-separation (e.g., friends, friends-of-friends), user groups (e.g., the gaming club, my family), user networks (e.g., employees of particular employers, students or alumni of particular university), all users (“public”), no users (“private”), users of third-party systems 2070, particular applications (e.g., third-party applications, external websites), other suitable entities, or any suitable combination thereof. Although this disclosure describes particular granularities of permitted access or denial of access, this disclosure contemplates any suitable granularities of permitted access or denial of access.

In particular embodiments, one or more servers 2062 may be authorization/privacy servers for enforcing privacy settings. In response to a request from a user (or other entity) for a particular object stored in a data store 2064, the social-networking system 2060 may send a request to the data store 2064 for the object. The request may identify the user associated with the request and the object may be sent only to the user (or an AR/VR system 2030 of the user) if the authorization server determines that the user is authorized to access the object based on the privacy settings associated with the object. If the requesting user is not authorized to access the object, the authorization server may prevent the requested object from being retrieved from the data store 2064 or may prevent the requested object from being sent to the user. In the search-query context, an object may be provided as a search result only if the querying user is authorized to access the object, e.g., if the privacy settings for the object allow it to be surfaced to, discovered by, or otherwise visible to the querying user. In particular embodiments, an object may represent content that is visible to a user through a newsfeed of the user. As an example and not by way of limitation, one or more objects may be visible to a user's “Trending” page. In particular embodiments, an object may correspond to a particular user. The object may be content associated with the particular user or may be the particular user's account or information stored on the social-networking system 2060, or other computing system. As an example and not by way of limitation, a first user may view one or more second users of an online social network through a “People You May Know” function of the online social network, or by viewing a list of friends of the first user. As an example and not by way of limitation, a first user may specify that they do not wish to see objects associated with a particular second user in their newsfeed or friends list. If the privacy settings for the object do not allow it to be surfaced to, discovered by, or visible to the user, the object may be excluded from the search results. Although this disclosure describes enforcing privacy settings in a particular manner, this disclosure contemplates enforcing privacy settings in any suitable manner.

In particular embodiments, different objects of the same type associated with a user may have different privacy settings. Different types of objects associated with a user may have different types of privacy settings. As an example and not by way of limitation, a first user may specify that the first user's status updates are public, but any images shared by the first user are visible only to the first user's friends on the online social network. As another example and not by way of limitation, a user may specify different privacy settings for different types of entities, such as individual users, friends-of-friends, followers, user groups, or corporate entities. As another example and not by way of limitation, a first user may specify a group of users that may view videos posted by the first user, while keeping the videos from being visible to the first user's employer. In particular embodiments, different privacy settings may be provided for different user groups or user demographics. As an example and not by way of limitation, a first user may specify that other users who attend the same university as the first user may view the first user's pictures, but that other users who are family members of the first user may not view those same pictures.

In particular embodiments, the social-networking system 2060 may provide one or more default privacy settings for each object of a particular object-type. A privacy setting for an object that is set to a default may be changed by a user associated with that object. As an example and not by way of limitation, all images posted by a first user may have a default privacy setting of being visible only to friends of the first user and, for a particular image, the first user may change the privacy setting for the image to be visible to friends and friends-of-friends.

In particular embodiments, privacy settings may allow a first user to specify (e.g., by opting out, by not opting in) whether the social-networking system 2060 or AR/VR platform 2040 may receive, collect, log, or store particular objects or information associated with the user for any purpose. In particular embodiments, privacy settings may allow the first user to specify whether particular applications or processes may access, store, or use particular objects or information associated with the user. The privacy settings may allow the first user to opt in or opt out of having objects or information accessed, stored, or used by specific applications or processes. The social-networking system 2060 or AR/VR platform 2040 may access such information in order to provide a particular function or service to the first user, without the social-networking system 2060 or AR/VR platform 2040 having access to that information for any other purposes. Before accessing, storing, or using such objects or information, the social-networking system 2060 orAR/VR platform 2040 may prompt the user to provide privacy settings specifying which applications or processes, if any, may access, store, or use the object or information prior to allowing any such action. As an example and not by way of limitation, a first user may transmit a message to a second user via an application related to the online social network (e.g., a messaging app), and may specify privacy settings that such messages should not be stored by the social-networking system 2060 or AR/VR platform 2040.

In particular embodiments, a user may specify whether particular types of objects or information associated with the first user may be accessed, stored, or used by the social-networking system 2060 or AR/VR platform 2040. As an example and not by way of limitation, the first user may specify that images sent by the first user through the social-networking system 2060 or AR/VR platform 2040 may not be stored by the social-networking system 2060 or AR/VR platform 2040. As another example and not by way of limitation, a first user may specify that messages sent from the first user to a particular second user may not be stored by the social-networking system 2060 or AR/VR platform 2040. As yet another example and not by way of limitation, a first user may specify that all objects sent via a particular application may be saved by the social-networking system 2060 or AR/VR platform 2040.

In particular embodiments, privacy settings may allow a first user to specify whether particular objects or information associated with the first user may be accessed from particular AR/VR systems 2030 or third-party systems 2070. The privacy settings may allow the first user to opt in or opt out of having objects or information accessed from a particular device (e.g., the phone book on a user's smart phone), from a particular application (e.g., a messaging app), or from a particular system (e.g., an email server). The social-networking system 2060 or AR/VR platform 2040 may provide default privacy settings with respect to each device, system, or application, and/or the first user may be prompted to specify a particular privacy setting for each context. As an example and not by way of limitation, the first user may utilize a location-services feature of the social-networking system 2060 or AR/VR platform 2040 to provide recommendations for restaurants or other places in proximity to the user. The first user's default privacy settings may specify that the social-networking system 2060 or AR/VR platform 2040 may use location information provided from an AR/VR system 2030 of the first user to provide the location-based services, but that the social-networking system 2060 or AR/VR platform 2040 may not store the location information of the first user or provide it to any third-party system 2070. The first user may then update the privacy settings to allow location information to be used by a third-party image-sharing application in order to geo-tag photos.

In particular embodiments, privacy settings may allow a user to specify one or more geographic locations from which objects can be accessed. Access or denial of access to the objects may depend on the geographic location of a user who is attempting to access the objects. As an example and not by way of limitation, a user may share an object and specify that only users in the same city may access or view the object. As another example and not by way of limitation, a first user may share an object and specify that the object is visible to second users only while the first user is in a particular location. If the first user leaves the particular location, the object may no longer be visible to the second users. As another example and not by way of limitation, a first user may specify that an object is visible only to second users within a threshold distance from the first user. If the first user subsequently changes location, the original second users with access to the object may lose access, while a new group of second users may gain access as they come within the threshold distance of the first user.

In particular embodiments, the social-networking system 2060 or AR/VR platform 2040 may have functionalities that may use, as inputs, personal or biometric information of a user for user-authentication or experience-personalization purposes. A user may opt to make use of these functionalities to enhance their experience on the online social network. As an example and not by way of limitation, a user may provide personal or biometric information to the social-networking system 2060 or AR/VR platform 2040. The user's privacy settings may specify that such information may be used only for particular processes, such as authentication, and further specify that such information may not be shared with any third-party system 2070 or used for other processes or applications associated with the social-networking system 2060 or AR/VR platform 2040. As another example and not by way of limitation, the social-networking system 2060 may provide a functionality for a user to provide voice-print recordings to the online social network. As an example and not by way of limitation, if a user wishes to utilize this function of the online social network, the user may provide a voice recording of his or her own voice to provide a status update on the online social network. The recording of the voice-input may be compared to a voice print of the user to determine what words were spoken by the user. The user's privacy setting may specify that such voice recording may be used only for voice-input purposes (e.g., to authenticate the user, to send voice messages, to improve voice recognition in order to use voice-operated features of the online social network), and further specify that such voice recording may not be shared with any third-party system 2070 or used by other processes or applications associated with the social-networking system 2060.

### Miscellaneous

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

### Example Embodiments

Example 1: A display device may include a diffusion layer providing a single well and one or more devices formed in an area of the diffusion layer corresponding to the single well, wherein the one or more devices are configured to supply a driving current to a pixel of the display device.

Example 2: The display device of Example 1, wherein the one or more devices correspond to one or more p-channel metal-oxide-semiconductor devices.

Example 3: The display device of Example 1 or 2, wherein a length of the pixel per color is no greater than 3.3 microns and a width of the pixel per color is no greater than 3.5 microns.

Example 4: The display device of any of Examples 1 to 3, further including one or more additional devices formed in the area of the diffusion layer corresponding to the single well, wherein the one or more additional devices are configured to supply an additional driving current to an additional pixel of the display device.

Example 5: The display device of any of Examples 1 to 4, wherein the one or more devices and the one or more additional devices have a uniform channel length.

Example 6: The display device of any of Examples 1 to 5, wherein the one or more devices correspond to one or more p-channel metal-oxide-semiconductor devices and the one or more additional devices correspond to one or more additional p-channel metal-oxide-semiconductor devices.

Example 7: The display device of any of Examples 1 to 6, wherein the one or more devices and the one or more additional devices share a continuous diffusion without any white spaces therebetween in at least one direction.

Example 8: A display engine comprising an optical element configured to receive light and output the receiving light as image light and a waveguide comprising an in-coupling grating and a waveguide body optically coupled to the image light, where a polarizing component is disposed over an output surface of the optical element.

Example 9: The display engine of any of Example 8, where the optical element comprises a polarizing beam splitter or a beam expander.

Example 10: The display engine of any of Example 8 or 9, further comprising a polarizing component disposed over the in-coupling grating.

Example 11: The display engine of any of Examples 8 to 10, further comprising a polarizing component disposed over a back surface of the waveguide.

Example 12: The display engine of any of Example 8 to 11, further comprising an antireflective coating disposed over a back surface of the waveguide.

Example 13: A method comprising, by a client system associated with a first user (i) receiving, at the client system, a plurality of speech signals captured by a plurality of microphones of the client system, where the plurality of speech signals comprise one or more cross-talking speech signals, (ii) generating, based on applying spatial filtering steered to a plurality of directions to the plurality of speech signals, directional data for the plurality of speech signals, where the directional data comprises output from the spatial filtering for the plurality of directions, (iii) identifying, based on the directional data by one or more machine-learning models, one or more target speech signals and the one or more cross-talking speech signals from the plurality of speech signals, (iv) generating one or more transcriptions for the one or more target speech signals, and (v) presenting, at the client system, one or more of the transcriptions to the user.

Example 14: The method of any of Example 13, further comprising (i) extracting, for each of the plurality of directions, one or more acoustic features for one or more of the plurality of speech signals associated with the respective direction, and integrating the extracted acoustic features for each of the plurality of directions.

Example 15: The method of any of Example 13 or 14 further comprising identifying, based on an analysis of the integrated features by a multi-channel automatic-speech-recognition (ASR) model, one or more speech signals corresponding to one or more utterances from the first user.

Example 16: The method of any of Example 13 to 15 further comprising identifying, based on an analysis of the integrated features by a multi-channel automatic-speech-recognition (ASR) model, the one or more target speech signals from among the plurality of speech signals as corresponding to one or more utterances from one or more second users, where the one or more second users are in a conversation with the first user.

Example 17: The method of any of Example 13 to 16, further comprising identifying, based on an analysis of the integrated features by a multi-channel automatic-speech-recognition (ASR) model, the one or more cross-talking speech signals from among the plurality of speech signals.

Example 18: The method of any of Example 13 to 17, where generating the directional data is based on relative phase and intensity differences between the plurality of microphones.

Example 19: The method of any of Example 13 to 18, where the one or more target speech signals are based on a first language, and where the one or more transcriptions are based on a second language that is different from the first language, the one or more transcriptions being a translation of the target speech signals from the first language to the second language.

Example 20: The method of any of Example 13 to 19, where the one or more target speech signals correspond to one or more utterances from one or more second users in a conversation with the first user.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

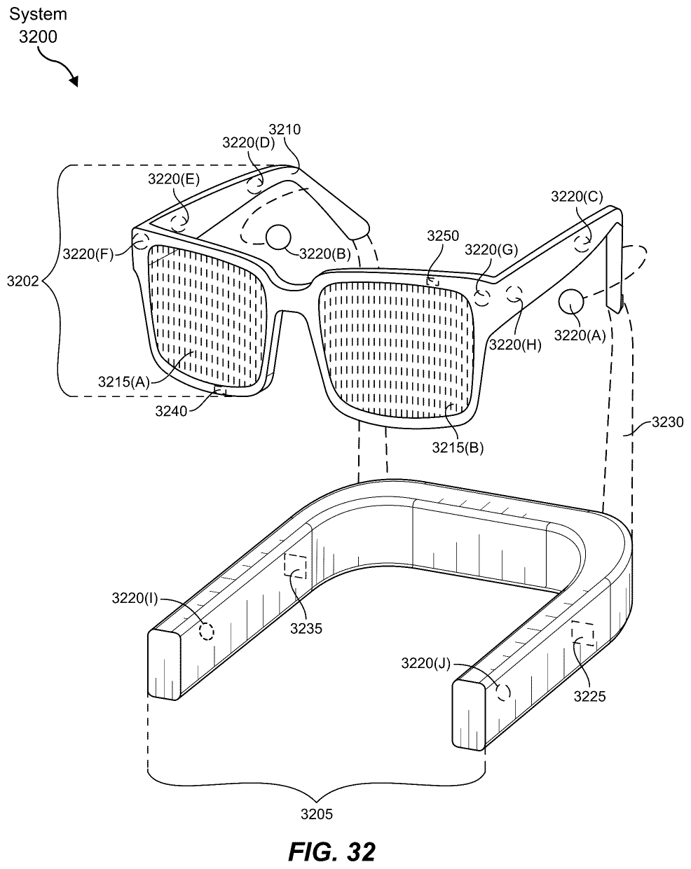

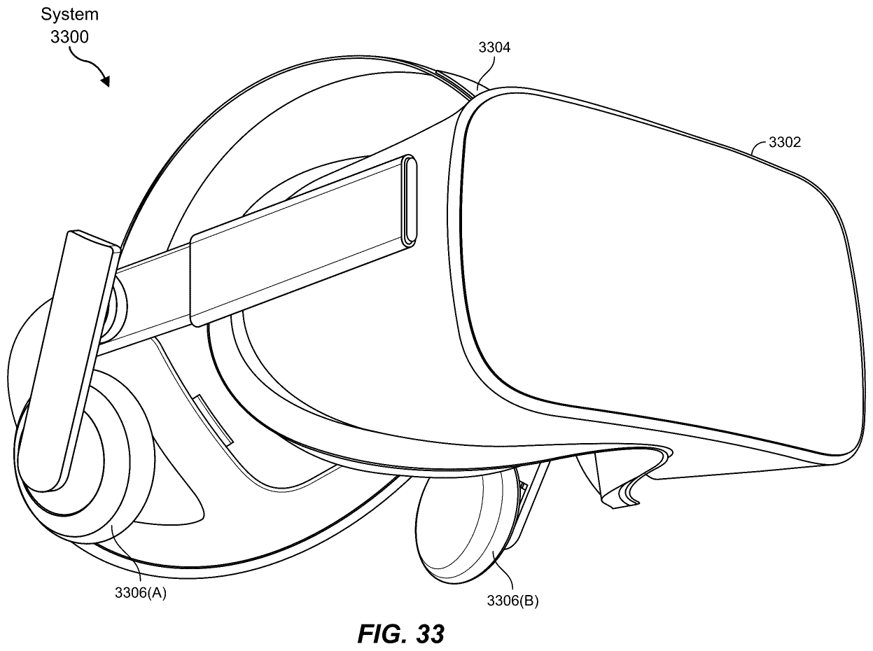

Artificial-reality systems may be implemented in a variety of different form factors and configurations. Some artificial-reality-systems may be designed to work without near-eye displays (NEDs). Other artificial—reality systems may include an NED that also provides visibility into the real world (such as, e.g., augmented-reality system 3200 in FIG. 32) or that visually immerses a user in an artificial reality (such as, e.g., virtual-reality system 3300 in FIG. 33). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 32, augmented-reality system 3200 may include an eyewear device 3202 with a frame 3210 configured to hold a left display device 3215(A) and a right display device 3215(B) in front of a user's eyes. Display devices 3215(A) and 3215(B) may act together or independently to present an image or series of images to a user. While augmented-reality system 3200 includes two displays, embodiments of this disclosure may be implemented in augmented-reality systems with a single NED or more than two NEDs.

In some embodiments, augmented-reality system 3200 may include one or more sensors, such as sensor 3240. Sensor 3240 may generate measurement signals in response to motion of augmented-reality system 3200 and may be located on substantially any portion of frame 3210. Sensor 3240 may represent one or more of a variety of different sensing mechanisms, such as a position sensor, an inertial measurement unit (IMU), a depth camera assembly, a structured light emitter and/or detector, or any combination thereof. In some embodiments, augmented-reality system 3200 may or may not include sensor 3240 or may include more than one sensor. In embodiments in which sensor 3240 includes an IMU, the IMU may generate calibration data based on measurement signals from sensor 3240. Examples of sensor 3240 may include, without limitation, accelerometers, gyroscopes, magnetometers, other suitable types of sensors that detect motion, sensors used for error correction of the IMU, or some combination thereof.

In some examples, augmented-reality system 3200 may also include a microphone array with a plurality of acoustic transducers 3220(A)-3220(J), referred to collectively as acoustic transducers 3220. Acoustic transducers 3220 may represent transducers that detect air pressure variations induced by sound waves. Each acoustic transducer 3220 may be configured to detect sound and convert the detected sound into an electronic format (e.g., an analog or digital format). The microphone array in FIG. 32 may include, for example, ten acoustic transducers: 3220(A) and 3220(B), which may be designed to be placed inside a corresponding ear of the user, acoustic transducers 3220(C), 3220(D), 3220(E), 3220(F), 3220(G), and 3220(H), which may be positioned at various locations on frame 3210, and/or acoustic transducers 3220(I) and 3220(J), which may be positioned on a corresponding neckband 3205.

In some embodiments, one or more of acoustic transducers 3220(A)-(J) may be used as output transducers (e.g., speakers). For example, acoustic transducers 3220(A) and/or 3220(B) may be earbuds or any other suitable type of headphone or speaker.

The configuration of acoustic transducers 3220 of the microphone array may vary. While augmented-reality system 3200 is shown in FIG. 32 as having ten acoustic transducers 3220, the number of acoustic transducers 3220 may be greater or less than ten. In some embodiments, using higher numbers of acoustic transducers 3220 may increase the amount of audio information collected and/or the sensitivity and accuracy of the audio information. In contrast, using a lower number of acoustic transducers 3220 may decrease the computing power required by an associated controller 3250 to process the collected audio information. In addition, the position of each acoustic transducer 3220 of the microphone array may vary. For example, the position of an acoustic transducer 3220 may include a defined position on the user, a defined coordinate on frame 3210, an orientation associated with each acoustic transducer 3220, or some combination thereof.

Acoustic transducers 3220(A) and 3220(B) may be positioned on different parts of the user's ear, such as behind the pinna, behind the tragus, and/or within the auricle or fossa. Or, there may be additional acoustic transducers 3220 on or surrounding the ear in addition to acoustic transducers 3220 inside the ear canal. Having an acoustic transducer 3220 positioned next to an ear canal of a user may enable the microphone array to collect information on how sounds arrive at the ear canal. By positioning at least two of acoustic transducers 3220 on either side of a user's head (e.g., as binaural microphones), augmented-reality device 3200 may simulate binaural hearing and capture a 3D stereo sound field around about a user's head. In some embodiments, acoustic transducers 3220(A) and 3220(B) may be connected to augmented-reality system 3200 via a wired connection 3230, and in other embodiments acoustic transducers 3220(A) and 3220(B) may be connected to augmented-reality system 3200 via a wireless connection (e.g., a BLUETOOTH connection). In still other embodiments, acoustic transducers 3220(A) and 3220(B) may not be used at all in conjunction with augmented-reality system 3200.

Acoustic transducers 3220 on frame 3210 may be positioned in a variety of different ways, including along the length of the temples, across the bridge, above or below display devices 3215(A) and 3215(B), or some combination thereof. Acoustic transducers 3220 may also be oriented such that the microphone array is able to detect sounds in a wide range of directions surrounding the user wearing the augmented-reality system 3200. In some embodiments, an optimization process may be performed during manufacturing of augmented-reality system 3200 to determine relative positioning of each acoustic transducer 3220 in the microphone array.

In some examples, augmented-reality system 3200 may include or be connected to an external device (e.g., a paired device), such as neckband 3205. Neckband 3205 generally represents any type or form of paired device. Thus, the following discussion of neckband 3205 may also apply to various other paired devices, such as charging cases, smart watches, smart phones, wrist bands, other wearable devices, hand-held controllers, tablet computers, laptop computers, other external compute devices, etc.

As shown, neckband 3205 may be coupled to eyewear device 3202 via one or more connectors. The connectors may be wired or wireless and may include electrical and/or non-electrical (e.g., structural) components. In some cases, eyewear device 3202 and neckband 3205 may operate independently without any wired or wireless connection between them. While FIG. 32 illustrates the components of eyewear device 3202 and neckband 3205 in example locations on eyewear device 3202 and neckband 3205, the components may be located elsewhere and/or distributed differently on eyewear device 3202 and/or neckband 3205. In some embodiments, the components of eyewear device 3202 and neckband 3205 may be located on one or more additional peripheral devices paired with eyewear device 3202, neckband 3205, or some combination thereof.

Pairing external devices, such as neckband 3205, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 3200 may be provided by a paired device or shared between a paired device and an eyewear device, thus reducing the weight, heat profile, and form factor of the eyewear device overall while still retaining desired functionality. For example, neckband 3205 may allow components that would otherwise be included on an eyewear device to be included in neckband 3205 since users may tolerate a heavier weight load on their shoulders than they would tolerate on their heads. Neckband 3205 may also have a larger surface area over which to diffuse and disperse heat to the ambient environment. Thus, neckband 3205 may allow for greater battery and computation capacity than might otherwise have been possible on a stand-alone eyewear device. Since weight carried in neckband 3205 may be less invasive to a user than weight carried in eyewear device 3202, a user may tolerate wearing a lighter eyewear device and carrying or wearing the paired device for greater lengths of time than a user would tolerate wearing a heavy standalone eyewear device, thereby enabling users to more fully incorporate artificial—reality environments into their day-to-day activities.

Neckband 3205 may be communicatively coupled with eyewear device 3202 and/or to other devices. These other devices may provide certain functions (e.g., tracking, localizing, depth mapping, processing, storage, etc.) to augmented-reality system 3200. In the embodiment of FIG. 32, neckband 3205 may include two acoustic transducers (e.g., 3220(I) and 3220(J)) that are part of the microphone array (or potentially form their own microphone subarray). Neckband 3205 may also include a controller 3225 and a power source 3235.

Acoustic transducers 3220(I) and 3220(J) of neckband 3205 may be configured to detect sound and convert the detected sound into an electronic format (analog or digital). In the embodiment of FIG. 32, acoustic transducers 3220(I) and 3220(J) may be positioned on neckband 3205, thereby increasing the distance between the neckband acoustic transducers 3220(I) and 3220(J) and other acoustic transducers 3220 positioned on eyewear device 3202. In some cases, increasing the distance between acoustic transducers 3220 of the microphone array may improve the accuracy of beamforming performed via the microphone array. For example, if a sound is detected by acoustic transducers 3220(C) and 3220(D) and the distance between acoustic transducers 3220(C) and 3220(D) is greater than, e.g., the distance between acoustic transducers 3220(D) and 3220(E), the determined source location of the detected sound may be more accurate than if the sound had been detected by acoustic transducers 3220(D) and 3220(E).

Controller 3225 of neckband 3205 may process information generated by the sensors on neckband 3205 and/or augmented-reality system 3200. For example, controller 3225 may process information from the microphone array that describes sounds detected by the microphone array. For each detected sound, controller 3225 may perform a direction-of-arrival (DOA) estimation to estimate a direction from which the detected sound arrived at the microphone array. As the microphone array detects sounds, controller 3225 may populate an audio data set with the information. In embodiments in which augmented-reality system 3200 includes an inertial measurement unit, controller 3225 may compute all inertial and spatial calculations from the IMU located on eyewear device 3202. A connector may convey information between augmented-reality system 3200 and neckband 3205 and between augmented-reality system 3200 and controller 3225. The information may be in the form of optical data, electrical data, wireless data, or any other transmittable data form. Moving the processing of information generated by augmented-reality system 3200 to neckband 3205 may reduce weight and heat in eyewear device 3202, making it more comfortable to the user.

Power source 3235 in neckband 3205 may provide power to eyewear device 3202 and/or to neckband 3205. Power source 3235 may include, without limitation, lithium-ion batteries, lithium-polymer batteries, primary lithium batteries, alkaline batteries, or any other form of power storage. In some cases, power source 3235 may be a wired power source. Including power source 3235 on neckband 3205 instead of on eyewear device 3202 may help better distribute the weight and heat generated by power source 3235.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 3300 in FIG. 33, that mostly or completely covers a user's field of view. Virtual-reality system 3300 may include a front rigid body 3302 and a band 3304 shaped to fit around a user's head. Virtual-reality system 3300 may also include output audio transducers 3306(A) and 3306(B). Furthermore, while not shown in FIG. 33, front rigid body 3302 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 3200 and/or virtual-reality system 3300 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 3200 and/or virtual-reality system 3300 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 3200 and/or virtual-reality system 3300 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial—reality devices, within other artificial—reality devices, and/or in conjunction with other artificial—reality devices.

By providing haptic sensations, audible content, and/or visual content, artificial—reality systems may create an entire virtual experience or enhance a user's real-world experience in a variety of contexts and environments. For instance, artificial—reality systems may assist or extend a user's perception, memory, or cognition within a particular environment. Some systems may enhance a user's interactions with other people in the real world or may enable more immersive interactions with other people in a virtual world. Artificial—reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial—reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A display device comprising:
a diffusion layer providing a single well; and
one or more devices formed in an area of the diffusion layer corresponding to the single well, wherein the one or more devices are configured to supply a driving current to a pixel of the display device.

2. The display device of claim 1, wherein the one or more devices correspond to one or more p-channel metal-oxide-semiconductor devices.

3. The display device of claim 1, wherein a length of the pixel per color is no greater than 3.3 microns and a width of the pixel per color is no greater than 3.5 microns.

4. The display device of claim 1, further comprising:
one or more additional devices formed in the area of the diffusion layer corresponding to the single well, wherein the one or more additional devices are configured to supply an additional driving current to an additional pixel of the display device.

5. The display device of claim 4, wherein the one or more devices and the one or more additional devices have a uniform channel length.

6. The display device of claim 4, wherein the one or more devices correspond to one or more p-channel metal-oxide-semiconductor devices and the one or more additional devices correspond to one or more additional p-channel metal-oxide-semiconductor devices.

7. The display device of claim 4, wherein the one or more devices and the one or more additional devices share a continuous diffusion without any white spaces therebetween in at least one direction.

8. A display engine comprising:
an optical element configured to receive light and output the received light as image light; and
a waveguide comprising an in-coupling grating and a waveguide body optically coupled to the image light, wherein a polarizing component is disposed over an output surface of the optical element.

9. The display engine of claim 8, wherein the optical element comprises a polarizing beam splitter or a beam expander.

10. The display engine of claim 8, further comprising a polarizing component disposed over the in-coupling grating.

11. The display engine of claim 8, further comprising a polarizing component disposed over a back surface of the waveguide.

12. The display engine of claim 8, further comprising an antireflective coating disposed over a back surface of the waveguide.

13. A method comprising, by a client system associated with a first user:
receiving, at the client system, a plurality of speech signals captured by a plurality of microphones of the client system, wherein the plurality of speech signals comprise one or more cross-talking speech signals;
generating, based on applying spatial filtering steered to a plurality of directions to the plurality of speech signals, directional data for the plurality of speech signals, wherein the directional data comprises output from the spatial filtering for the plurality of directions;
identifying, based on the directional data by one or more machine-learning models, one or more target speech signals and the one or more cross-talking speech signals from the plurality of speech signals;
generating one or more transcriptions for the one or more target speech signals; and
presenting, at the client system, one or more of the transcriptions to the first user.

14. The method of claim 13, further comprising:
extracting, for each of the plurality of directions, one or more acoustic features for one or more of the plurality of speech signals associated with the respective direction; and
integrating the extracted acoustic features for each of the plurality of directions.

15. The method of claim 14, further comprising:
identifying, based on an analysis of the integrated features by a multi-channel automatic-speech-recognition (ASR) model, one or more speech signals corresponding to one or more utterances from the first user.

16. The method of claim 14, further comprising:
identifying, based on an analysis of the integrated features by a multi-channel automatic-speech-recognition (ASR) model, the one or more target speech signals from among the plurality of speech signals as corresponding to one or more utterances from one or more second users, wherein the one or more second users are in a conversation with the first user.

17. The method of claim 14, further comprising:
identifying, based on an analysis of the integrated features by a multi-channel automatic-speech-recognition (ASR) model, the one or more cross-talking speech signals from among the plurality of speech signals.

18. The method of claim 13, wherein generating the directional data is based on relative phase and intensity differences between the plurality of microphones.

19. The method of claim 13, wherein the one or more target speech signals are based on a first language, and wherein the one or more transcriptions are based on a second language that is different from the first language, the one or more transcriptions being a translation of the target speech signals from the first language to the second language.

20. The method of claim 13, wherein the one or more target speech signals correspond to one or more utterances from one or more second users in a conversation with the first user.
